(19) United States
(12) Patent Application Publication
(10) Pub. No.: US 2022/0013288 A1
(43) Pub. Date: Jan. 13, 2022

(54) NANOCRYSTALLINE HIGH-K LOW-LEAKAGE THIN FILMS

(71) Applicants: Jonathan E. SPANIER, Bala Cynwyd, PA (US); Iryna S. GOLOVINA, Philadelphia, PA (US); Aleksandr V. PLOKHIKH, Philadelphia, PA (US); Mattias FALMBIGL, Syosset, NY (US)

(72) Inventors: Jonathan E. SPANIER, Bala Cynwyd, PA (US); Iryna S. GOLOVINA, Philadelphia, PA (US); Aleksandr V. PLOKHIKH, Philadelphia, PA (US); Mattias FALMBIGL, Syosset, NY (US)

(21) Appl. No.: 17/293,575

(22) PCT Filed: Nov. 13, 2019
(86) PCT No.: PCT/US2019/061271

§ 371 Date: May 13, 2021

Related U.S. Application Data
(60) Provisional application No. 62/760,132, filed on Nov. 13, 2018.
(60) Provisional application No. 62/907,405, filed on Sep. 27, 2019.
(60) Provisional application No. 62/927,508, filed on Oct. 29, 2019.

(51) Int. Cl. H01G 4/12; H01L 49/02; H01G 4/33; H01G 4/10; H01G 4/30

(52) U.S. Cl. CPC H01G 4/1227; H01L 28/56; H01G 4/008; H01G 4/10; H01G 4/306; H01G 4/33

(57) ABSTRACT

Provided is the dielectric response of atomic layer-deposited and annealed polymorphic BaTiO₃ and BaTiO₃—Al₂O₃ bi-layer thin films based on nanocry stalline BaTiO₃ containing the perovskite and hexagonal polymorphs. Also provided are BaTiO₃ films having tuned Curie temperatures. Further provided are capacitive components, comprising: a plurality of films, the plurality of films comprising: a first grained film component, the first grained film component comprising at least one of SrTiO₃, BaTiO₃, and (Ba, Sr)TiO₃, and the first grained film component being characterized as being at least partially polymorphic crystalline in nature; a second film component contacting the first grained film component, the second film component optionally comprising Al₂O₃, and the first grained film component optionally defining an average grain size of less than about 10 micrometers.

### RELATED APPLICATIONS

The present application claims priority to and the benefit of U.S. Application No. 62/760,132, “High Permittivity And Low Leakage Dielectric Thin Film Materials” (filed Nov. 13, 2018); U.S. Application No. 62/907,405, “Nanocrystalline High-K Low-Leakage Thin Films” (filed Sep. 27, 2019); and U.S. Application No. 62/927,508 (filed Oct. 29, 2019). The entireties of the foregoing applications are incorporated herein by reference for any and all purposes.

### GOVERNMENT RIGHTS

This invention was made with government support under Contract No. N00014-15-11-2170, awarded by the Office of Naval Research. The government has certain rights in the invention.

### TECHNICAL FIELD

The present disclosure relates to the field of thin film capacitors and also to the field of metal-insulator-metal capacitors.

### BACKGROUND

Many capacitor applications demand both high capacitance and low leakage current. Although efforts have been undertaken to decrease the leakage current of metal-insulator-metal (MIM) capacitors and to create materials having comparatively high dielectric constants, such efforts have to date met with only mixed success. Accordingly, there is a need in the art for capacitor components having both a reduced leakage current and also a comparatively high dielectric constant.

### SUMMARY

Provided is the dielectric response of atomic layer-deposited and annealed polymorphic BaTiO₃ and BaTiO₃—Al₂O₃ bi-layer thin films based on nanocrystalline BaTiO₃ containing the perovskite and hexagonal polymorphs. Also provided are BaTiO₃ films having tuned Curie temperatures.

Compared to an individual BaTiO₃ film, a 4-nm thick Al₂O₃ layer in the BaTiO₃—Al₂O₃ stack reduces the leakage current by more than 5 orders of magnitude at 1 MV/cm. Therefore, a 32-nm thick BaTiO₃ film annealed at 700° C. or 750° C. and further combined with a 4-nm thick Al₂O₃ layer located between the BaTiO₃ film and top electrode exhibits dielectric constants of 108 or 130 and leakage currents 2.2×10⁻⁸ A/mm² or 1.3×10⁻⁷ A/mm², respectively, at 1 MV/cm at room temperature. An almost order-of-magnitude difference in leakage current is attributed to the larger grain sizes formed in the film after annealing at 750° C. as compared to the grains formed at 700° C. Comparison to the most common high-k materials reveals the outstanding performance based on the combination of leakage current and dielectric constant for the 32-nm polymorphic BaTiO₃—4-nm Al₂O₃ thin film stacks. X-ray photoemission analysis study of barrier heights for the metal-BaTiO₃—Al₂O₃-metal structure point to using the polymorphic BaTiO₃ interspersed between Al₂O₃ layers in tri-layered dielectric thin film capacitors.

In meeting the described needs in the art, the present disclosure first provides a capacitive component, comprising: a plurality of films, the plurality of films comprising: a first grained film component, the first grained film component comprising at least one of SrTiO₃, BaTiO₃, and (Ba, Sr)TiO₃, and the first grained film component being characterized as being at least partially polymorphic crystalline in nature; a second film component contacting the first grained film component, the second film component optionally comprising Al₂O₃, and the first grained film component optionally defining an average grain size of less than about 10 micrometers.

Also provided are capacitive components, comprising: a plurality of films, the plurality of films optionally being disposed between a first electrode and a second electrode, and the plurality of films comprising: a first grained film component, the first grained film component being characterized as being at least partially crystalline polymorphic; a second film component contacting the first grained film component, the second film component optionally comprising Al₂O₃, and the plurality of films optionally having a dielectric constant, at 0 V, of from about 40 to about 140 and optionally a leakage current, measured at 1 MV/cm and 125 deg. C., of from about 10⁻⁷ A/mm² to about 10⁻⁸ A/mm².

Further provided are articles, the articles comprising a capacitive component according to the present disclosure.

Additionally provided are methods, the methods comprising discharging electrical energy from a capacitive component according to the present disclosure.

Further disclosed are methods, the methods comprising storing electrical energy in a capacitive component according to the present disclosure.

Also provided are methods, the methods comprising energizing an electrical load with energy discharged from a capacitive component according to the present disclosure.

Also provided are components, the components being made according to the disclosed methods.

Further provided are nano-grained films, comprising: a BaTiO3 film component comprising a Ba/Ti ratio of between about 0.8 and 1.06, a transition temperature of the nano-grained film being dependent on the Ba/Ti ratio, and the nano-grained film exhibiting a diffused phase transition, optionally whereby a temperature density of a dielectric constant of the nano-grained film is minimized.

Additionally provided are nano-grained films configured to exhibit a diffused phase transition, whereby a temperature density of a dielectric constant of the nano-grained film is minimized, wherein a transition temperature and the temperature density of the dielectric constant of the nano-grained film is tuned based at least on stoichiometry of one or more materials forming the nano-grained film.

Further provided are methods, comprising forming a nano-grained film according to the present disclosure.

Additionally provided are devices, comprising: one or more electrodes in electronic communication with a nano-grained film according to the present disclosure.

Further provided are methods, comprising operating a device according to the present disclosure.

Also provided are methods, comprising: tuning a Curie transition temperature of a nano-grained film that comprises a BaTiO3 film component comprising a Ba/Ti ratio of between about 0.8 and 1.06, a transition temperature of the nano-grained film being dependent on the Ba/Ti ratio, and the nano-grained film exhibiting a diffused phase transition, optionally whereby a temperature density of a dielectric constant of the nano-grained film is minimized, the tuning comprising modulating the Ba/Ti ratio.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

In the drawings, which are not necessarily drawn to scale, like numerals may describe similar components in different views. Like numerals having different letter suffixes may represent different instances of similar components. The drawings illustrate generally, by way of example, but not by way of limitation, various aspects discussed in the present document. In the drawings:

FIG. 1. Grazing incidence XRD scans of 32-nm thick BTO films on Pt after deposition and annealing steps.

FIG. 2. AFM height image of the topography of 32-nm thick BTO films a) after deposition; after annealing b) at 700° C. in N₂ flow and depositing 4-nm Al₂O₃, and c) at 750° C. in N₂ flow and depositing 4-nm Al₂O₃ for an area of 5×5 μm² each.

FIG. 3. Stacking sequence for a bi-layer structure, a ˜30-nm thick BTO film and a thin (˜4 nm) amorphous Al₂O₃ layer.

FIG. 4. Leakage current density as a function of applied electric field for 27 nm thick BTO thin films with different thickness of the Al₂O₃-layer after annealing at 500° C.

FIG. 5. a) Current density as a function of applied electric field for MIM-capacitors after different processing conditions; b) Current density for the positive bias. The crossover of the dashed black lines marks the maximum allowed value per ITRS requirements.

FIG. 6. a) Dielectric constant as a function of applied electric field for MIM-capacitors with different processing conditions. b) Positive bias for the dielectric constant of the same films.

FIG. 7. a) Dielectric constant of two MIM-structures with a 32 nm thick BTO structure annealed at 700° C. and 750° C. under N₂ flow for 10 min and a 4-nm thick Al₂O₃ top layer. b) Current density as a function of electric field for the same MIM-devices measured at room temperature and at 125° C.

FIG. 8. a) XPS C1s spectra for the Al₂O₃—TiN sample and b) XPS results of the Fermi edges of TiN film on SiO₂/Si (green) and Pt film on SiO2/Si (blue), and valence bands of a 10-nm thick Al₂O₃ film deposited on the TiN/SiO₂/Si substrate (yellow), 10-nm thick BTO film deposited on the TiN/SiO₂/Si substrate (red), BTO-Al₂O₃ composite stack deposited on the TiN/SiO₂/Si substrate (black), 10-nm thick BTO film deposited on the Pt/SiO₂/Si substrate (purple).

FIG. 9. A schematic of band alignment for the TiN-BTO-Al₂O₃—TiN structure.

FIG. 10. Comparison of the dielectric constant at 0 MV/cm and leakage current at 1 MV/cm (or highest electric field measured if below 1 MV/cm) for BTO-Al₂O₃ dielectric stacks to various other high-k thin films and thin film stacks; a particularly desirable material should be located in the top left corner.

FIG. 11. Raman spectra of 32 nm thick polymorphic BTO films on Pt after different processing steps. The position of the most prominent modes corresponding to the tetragonal (t) and the hexagonal (h) BTO polymorphs are indicated. For comparison, a Raman spectrum collected for a 50 nm thick BTO film is included.

FIG. 12. a) Current density for positive bias measured for three different MIM-capacitors (spots) of 32-nm polymorphic BTO—4-nm Al₂O₃ bi-layer structure after annealing at 750° C. at room temperature. b) Dielectric constant for positive bias measured for these three different MIMcapacitors (spots).

FIG. 13. Tauc plot for a direct allowed band gap for data collected on a 27 nm thick polymorphic BTO film annealed at 700° C. for 5 min deposited on a quartz substrate. The dashed black line represents a linear fit to determine the band gap.

FIG. 14. Grazing incidence XRD scans of 28-nm thick BTO films on TiN substrates after RTP annealing procedure at different temperature and/or time.

FIG. 15. AFM images of the topographic height of 28-nm thick BTO films after annealing a) at 850° C. for 3 sec; b) at 850° C. for 20 sec; c) at 900° C. for 3 sec, and d) at 900° C. for 10 sec; for an area of 5×5 μm² each.

FIG. 16. a) Dielectric constant and b) Current density as a function of applied bias for 28-nm thick BTO films annealed at 850° C. for 3 sec. Data were collected at RT and 125° C.

FIG. 17. a) Relative dielectric constant and b) Current density as a function of applied bias for the 28-nm thick BTO films annealed at 900° C. for 3 sec. Data were collected at RT and 125° C.

FIG. 18. Fitting results for the experimental data considering different conduction mechanisms: (a) Schottky emission, (b) Poole-Frenkel (PF) emission and (c) SCLC mechanism.

FIG. 19. Schematic of the deposition and processing sequence for the MIM structure with an Al₂O₃ layer between the BTO film and TiN top electrodes.

FIG. 20. Grazing incidence XRD scans of the 24-nm thick BTO films on TiN substrates after RTP annealing procedure at different temperature.

FIG. 21. AFM height image of the topography of a) 25-nm thick BTO film after annealing at 850° C. for 3 sec; b) 25-nm thick BTO film annealed at 850° C. for 3 sec+2-nm thick Al₂O₃ layer; c) 25-nm thick BTO film annealed at 850° C. for 3 sec+3-nm thick Al₂O₃ layer; for an area of 5×5 μm2 each.

FIG. 22. Relative dielectric constant as a function of applied bias for the 25-nm thick BTO films annealed at 850° C. for 3 sec with a) 2-nm thick Al₂O₃ layer and b) 3-nm thick Al₂O₃ layer. Data were collected at RT and 125° C. Measuring frequency was 100 kHz in all cases.

FIG. 23. Current density as a function of electric field for 25-nm thick BTO films annealed at 850° C. for 3 sec with a) 2-nm thick Al₂O₃ layer and b) 3-nm thick Al₂O₃ layer.

FIG. 24. Fitting results for the experimental data considering different conduction mechanisms in the TiN-BTO-Al₂O₃—TiN MIM-capacitors: (a) Schottky emission, (b) Poole-Frenkel (PF) emission and (c) SCLC mechanism.

FIG. 25. a) Grazing incidence XRD scans of 28-nm thick BTO film on Pt-coated substrate after RTP annealing at 900° C. for 2 min in N2 flow. b) Current density as a function of applied electric field collected for 28-nm BTO—3.5 nm Al2O3 stack on Pt substrate.

FIG. 26. Grazing incidence XRD scans of a) the BTO-seed layers of various thickness deposited on TiN substrates and RTP annealed, and b) the main BTO films deposited over the RTP annealed BTO-seed layer and RTP annealed afterwards at 850° C. for 3 sec in N₂ flow.

FIG. 27. Grazing incidence XRD scans of the BTO-Al₂O₃ stacks deposited over 9-nm thick BTO-seed layer RTP annealed at 900° C. for 3 sec; afterwards, the whole structure was RTP annealed at 900° C. for 3 sec in N₂ flow.

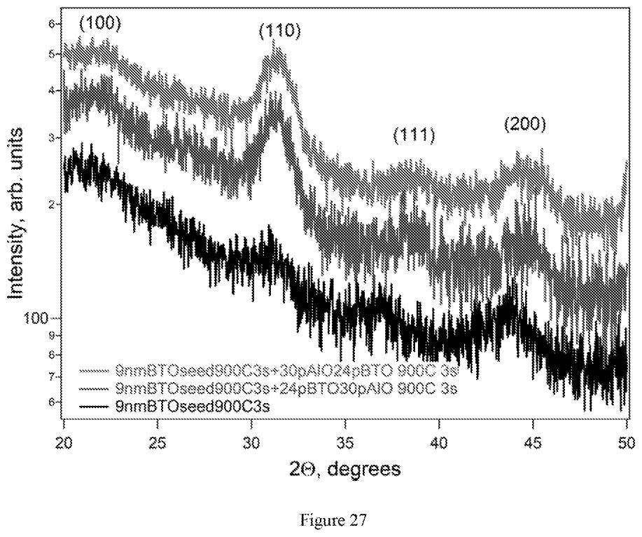

FIG. 28. Schematic of the deposition and processing sequence for the MIM structure with a BTO film sandwiched between Al₂O₃ layers on the TiN-substrate and with TiN top electrodes.

FIG. 29. Grazing incidence XRD scans of ˜30-nm thick Al₂O₃-BTO-Al₂O₃ composite stacks on TiN substrates after RTP annealing procedure at different temperature and/or time.

FIG. 30. a) Dielectric constant and b) Current density as a function of applied bias for the ˜30-nm thick Al₂O₃-BTO-Al₂O₃ composite stacks on TiN substrates after RTP annealing procedure at different temperature and/or time. For comparison, data for the 28-nm thick BTO-Al₂O₃ stack annealed at 850° C. for 3 sec at a heating rate 50° C./sec are also shown. Data were collected at RT.

FIG. 31. BF TEM images amorphous Al₂O₃-BTO films prepared by one-step and two-step process.

FIG. 32. STEM BF and HAADF images of a one-step deposited film.

FIG. 33. SAED of both (one-step and two-step) films.

FIG. 34. EDS line scans of Al₂O₃-BTO stacks.

FIG. 35. Grazing incidence XRD scans of a) the 6-nm thick BTO-seed layer a (black) and the main 24-nm BTO film deposited over the seed layer and RTP annealed at 850° C. for 3 sec (red), and b) the 9-nm thick BTO-seed layer a (black) and the main 2.5 nm Al₂O₃—18 nm BTO stack deposited over the seed layer and RTP annealed at 900° C. for 3 sec (red).

FIG. 36. a) Dielectric constant and b) Current density as a function of applied bias for the main 24-nm thick BTO film deposited on the top of the 6-nm seed BTO layer and RTP annealed at 850° C. for 3 sec.

FIG. 37. a) Dielectric constant and b) Current density as a function of applied bias for the 2.5 nm Al₂O₃—18 nm BTO stack deposited over the 9-nm BTO seed layer and RTP annealed at 900° C. for 3 sec.

FIG. 38. Dielectric constant (black) and losses (red) as a function of measuring frequency collected at RT for a) Pt-BTO-Al₂O₃—TiN MIM-capacitors annealed at 700° C., and b) Pt-BTO-Al₂O₃—TiN MIM-capacitors annealed at 750° C.

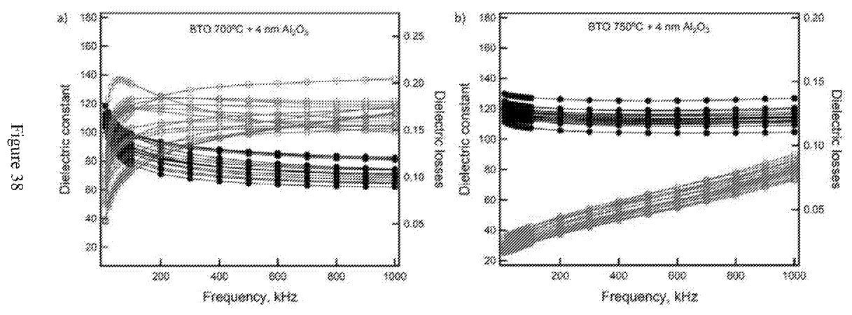

FIG. 39. a) Leakage current density as a function of applied electric field for Pt-BTO-Al₂O₃—TiN MIM-capacitors after different annealing conditions, b) leakage current density for the positive bias.

FIG. 40 illustrates lattice parameters for the pseudo-cubic structure, a_{pc} (from XRD), and average crystallite size (from TEM) as a function of Ba/Ti ratio.

FIG. 41 illustrates BF-TEM cross sections of the MIM-structures after the annealing step for the thin films with Ba/Ti-ratio of 1.01 with top Pt electrodes deposited a) before and b) after the annealing procedure. The yellow dashed lines highlight some crystallites within the cross sections.

FIG. 42 illustrates Temperature dependence (cooling and heating cycles) of a) normalized dielectric constant and b) dielectric loss as a function of the Ba/Ti ratio. Markers—experimental data, lines—fits to equation (1) for the heating cycle.

FIG. 43 illustrates temperature dependences (on heating) of a) dielectric constant and b) losses at three representative measuring frequencies for the stoichiometric sample (Ba/Ti=1.01) with top electrodes deposited after the annealing step. Markers are experimental data; lines are guides to the eye.

FIG. 44 illustrates Polarization behaviour: a) hysteresis loops at 305 K and b) temperature dependence (on heating) of maximum polarization Pₘₐₓ at E=0.545 MV/cm (left) and remnant polarization Pᵣₑₘ at E=0 (right) for samples with various Ba/Ti ratio. The dashed and solid lines are guides for eye.

FIG. 45 illustrates Room-temperature hysteresis loop collected at 1 kHz for the thin film with Ba/Ti-ratio of 1.01 and top electrodes deposited after the annealing step.

FIG. 46 illustrates Strain from theoretical calculations (circles, triangles), strain determined from XRD (diamonds) and transition temperature Tₘ (squares) versus Ba/Ti ratio. Markers are experimental or calculated values, solid line is a linear fit (y=−188+505x), dashed lines are for clarity.

FIG. 47 illustrates room-temperature Raman spectra for the stoichiometric thin film (Ba/Ti=1.01) with top electrodes before annealing.

FIG. 48 illustrates temperature dependences of the frequency, integrated intensity and FWHM of the 520cm⁻¹ peak for the Ti-rich sample (Ba/Ti=0.8).

FIGS. 49 illustrate temperature dependences of frequency, integrated intensity and FWHM of the 520 cm⁻¹ (a) and 620 cm⁻¹ (b) peaks for the Ba-rich sample (Ba/Ti=1.06).

FIG. 50 illustrates distribution of grain sizes beneath top Pt electrodes deposited before annealing step for samples with various Ba/Ti ratios: a) 0.8, b) 0.92, c) 1.01, d) 1.06. Solid red curves are fits to the histogram using a Gaussian.

FIG. 51 illustrates distribution of grain sizes beneath top Pt electrodes deposited after the annealing step for a stoichiometric sample (Ba/Ti=1.01). Red curves are two Gaussian functions and the blue curve is the sum of these fit functions to the histogram.

FIG. 52 illustrates grain size distribution from the TEM cross section between the uncovered area (between top electrodes) obtained for a stoichiometric sample (Ba/Ti=1.01). Solid red curve is the histogram fitting by a Gaussian function.

FIG. 53 illustrates experimental XPS Ti spectra collected for the films with Ba/Ti=0.8, 0.92, 1.01, 1.06 (a) and fitting of the experimental Ti 2p3/2 peak by a Voigt function.

FIG. 54 illustrates experimental XPS Ba spectra collected for the films with Ba/Ti=0.8, 0.92, 1.01, 1.06 (a) and fitting of the experimental Ba 3d5/2 spectrum for the film with Ba/Ti=1.06 by a Voigt function.

FIG. 55 illustrates room temperature current density as a function of electric field (a) and dielectric constant as a function of frequency (b) for the films with Ba/Ti=0.8, 0.92, 1.01 and 1.06.

FIG. 56 illustrates room temperature hysteresis loops collected at different maximum electric fields and different frequencies for the stoichiometric (Ba/Ti=1.01) film with Pt electrodes deposited after the annealing procedure.

FIG. 57 room temperature hysteresis loops collected at a maximum electric field of 0.65 MV/cm and at different frequencies for the stoichiometric (Ba/Ti=1.01) film with Pt electrodes deposited after the annealing procedure.

FIG. 58 illustrates temperature dependences of the integrated intensity, frequency, and FWHM of the Raman mode at 620 cm⁻¹ for the Ti-rich sample (Ba/Ti=0.8).

FIG. 59 illustrates grazing incidence X-ray diffraction scans of the 32 nm thick BTO films on Pt after the deposition and annealing steps.

FIG. 60 illustrates Raman spectra of the 32 nm thick BTO films on Pt after different processing steps. The position of the most prominent modes corresponding to the perovskite (t) and the hexagonal (h) BTO polymorphs are indicated. For comparison a Raman spectrum collected for a 50 nm thick BTO film is included.

FIG. 61(a)-(d) illustrate AFM height image of the topography of the 32 nm thick BTO films a) after the deposition, b) after annealing at 700° C. in O₂ flow, c) after annealing at 700° C. in N₂ flow and depositing 4 nm Al₂O₃, d) and at 750° C. in N₂ flow and depositing 4 nm Al₂O₃ for an area of 5×5 μm² each.

FIG. 62(a)-(b) illustrate a) HR-TEM image of a 50 nm thick BTO film with Ba/Ti-ratio of 1.06 after annealing at 750° C. in O₂, and b) a 50 nm thick BTO film with Ba/Ti-ratio of 0.80 after annealing at 750° C. in O₂.

FIG. 63(a)-(b) illustrate a) dielectric constant and loss as a function of frequency for ˜55 nm thick BTO films with varying Ba/Ti-ratio. b) Normalized dielectric constants as a function of applied electric field for the same films. The tunability, n, is provided for a field of 1 MV/cm.⁴

FIG. 64(a)-(b) illustrate temperature dependence (cooling and heating cycles) of a) normalized dielectric constant and b) dielectric loss as a function of the Ba/Ti ratio.

FIG. 65(a)-(b) illustrate a) current density (CD) as a function of applied electric field (E) for MIM-capacitors after different processing conditions for positive bias, b) Dielectric constant as a function of applied electric field for MIM-capacitors with different processing conditions for positive bias. The inset shows the scheme of the MIM-stack under measurement conditions.

### DETAILED DESCRIPTION OF ILLUSTRATIVE EMBODIMENTS

The present disclosure may be understood more readily by reference to the following detailed description taken in connection with the accompanying figures and examples, which form a part of this disclosure. It is to be understood that this invention is not limited to the specific devices, methods, applications, conditions or parameters described and/or shown herein, and that the terminology used herein is for the purpose of describing particular embodiments by way of example only and is not intended to be limiting of the claimed invention.

Also, as used in the specification including the appended claims, the singular forms “a,” “an,” and “the” include the plural, and reference to a particular numerical value includes at least that particular value, unless the context clearly dictates otherwise. The term “plurality”, as used herein, means more than one. When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable, and it should be understood that steps may be performed in any order.

It is to be appreciated that certain features of the invention which are, for clarity, described herein in the context of separate embodiments, may also be provided in combination in a single embodiment. Conversely, various features of the invention that are, for brevity, described in the context of a single embodiment, may also be provided separately or in any subcombination. All documents cited herein are incorporated herein in their entireties for any and all purposes.

Further, reference to values stated in ranges include each and every value within that range. In addition, the term “comprising” should be understood as having its standard, open-ended meaning, but also as encompassing “consisting” as well. For example, a device that comprises Part A and Part B may include parts in addition to Part A and Part B, but may also be formed only from Part A and Part B.

High-k materials are widely used in a variety of integrated circuits, including FETs, DRAM and FeRAM devices, input/output coupling circuitry. Metal-insulator-metal (MIM) capacitors with different high-k individual binary and ternary oxide insulators, e.g. HfO₂ (k»20), Ta₂O₅ (k»25), TiO₂ (k»100), ZrO₂ (k»19-30), BaHfO₃ (k»38), BaZrO₃ (k»40), SrTiO₃ (k»180), BaTiO₃ (k»70-165), (Ba,Sr)TiO₃ (k»200-750) have been fabricated. For capacitor applications, the key functional parameters are high capacitance and low leakage current.

Significant efforts have been undertaken to decrease the leakage current of MIM-capacitors. One approach is to combine two or more dielectrics into multilayer stacks, e.g., HfO₂—Ta₂O₅, TiO₂—ZrO₂, Al₂O₃—HfO₂—Al₂O₃, SrTiO₃—Al₂O₃, (Ba,Sr)TiO₃—Al₂O₃, ZrO₂—Al₂O₃—ZrO₂, and ZrO₂/(Ta/Nb)Oₓ—Al₂O₃/ZrO₂. Use of Al₂O₃ in the stacking structure was shown as an effective way to reduce leakage current. As Al₂O₃ has a relatively low dielectric constant (k»10), the other material can have a relatively higher k to maintain a high dielectric constant of the stack, and candidates include SrTiO₃ (STO), BaTiO₃ (BTO) or (Ba,Sr)TiO₃ (BST).

Atomic Layer Deposition (ALD) is advantageous for fabrication of a nanoscale-conformal insulating thin-film capacitor materials. An excellent conformal step coverage is useful for extreme three-dimensional (3D) structures having a high aspect ratio, e.g., trench structures.

ALD allows precise stoichiometry control for ternary oxides, high thickness control and good doping control. In addition, ALD utilizes low growth and processing temperatures. In thin-film MIM-capacitors of thickness below 50 nm, interfacial and grain boundary-induced strains in polycrystalline films can drive defect formation, in turn affecting film insulator material electrical properties. While k»280 in bulk STO, it exhibits a smaller k (»100-180) in thin films. The effects of post-deposition annealing conditions and doping were explored to control oxygen vacancies formation in ALD-grown thin films.

By varying the stoichiometry, electrical performance can also be tuned. A thin seed layer can be used to help the overlying film to be crystallized more easily. This approach allows to reduce leakage current as well. For instance, a 5-nm thick STO seed layer annealed at 650° C. for 1 min with rapid thermal annealing (RTA) resulted in an improvement in the capacitance (2.7 μF cm⁻² without a seed layer vs. 4.5 μF cm⁻² with a seed layer) and a decrease in the leakage current density (10⁻¹ A cm⁻² without a seed layer vs. 10⁻⁵ A cm⁻² with a seed layer at 1 V) of the main STO layer.

Also, a 3-nm thick STO seed layer annealed at 700° C. for 1 min with RTA resulted in capacitance increase of a 17 nm thick main STO layer by a factor of 5 and a low leakage current density, 10⁻⁷ A/cm² at 0.8 V. As mentioned above, reduced leakage current was present in layered structures when Al₂O₃ was employed. While STO has been studied more widely, the potential of ALD-grown BTO thin films has not been fully explored.

Here, we utilize seed layering for nanocrystalline and polymorphic BTO (NP/BTO) growth and bi-layering with Al₂O₃ aiming to achieve the combination of high dielectric constant and low leakage current for NP/BTO-based planar MIM capacitors. The present disclosure provides, inter alia, the growth and properties of, e.g., a bi-layer BTO-Al₂O₃ stack, with Al₂O₃ layer between the BTO film and the top electrode. The thickness of the Al₂O₃ layer can influence leakage current. It is further demonstrated that the NP/BTO film thickness and morphology, in particular grain sizes, can affect leakage current. The findings show that ALD-grown and annealed BTO-Al₂O₃ MIM-stacks simultaneously exhibit a combination of high dielectric constant and low leakage that is superior to other high-k polycrystalline thin-film materials.

Experimental

Atomic layer depositions of BTO thin films and BTO-Al₂O₃ bi-layer structures were performed in a Picosun R200 Advanced Reactor on (100)-oriented Si substrates with native oxide layer and Pt(111)/Ti/SiO₂/Si(100) substrates (Gmek Inc.). N₂ gas of 6N purity was used as carrier gas.

ALD Growth of Ultrathin Al₂O₃ Layers

We performed ALD-growth of thin Al₂O₃ layers at T=350° C. using TMA (Trimethylaluminum, Sigma-Aldrich 97%) precursor and ozone as a reactant for the deposition. The thickness of the Al₂O₃ layer and corresponding growth per cycle (GPC) vary as the pulses number increases. The pronounced deviation from the linear growth behavior was observed below 40 pulses. The saturation of GPC occurs at 40 pulses as well and produces ˜0.92 Å. The uniformity of the Al₂O₃ layers over 100 mm² remains above 99%.

ALD-Growth of BTO-Al₂O₃ Bi-Layers

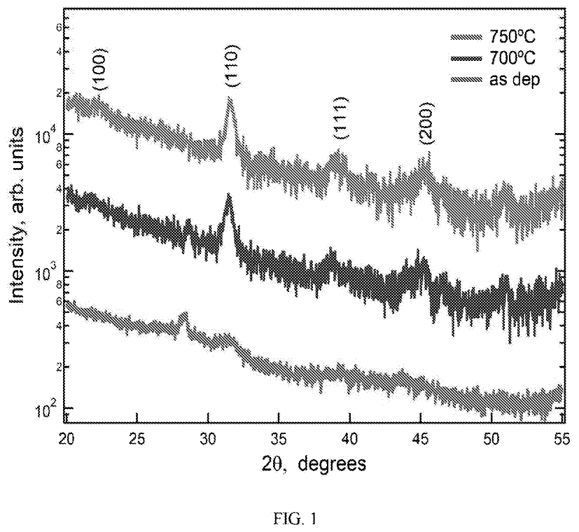

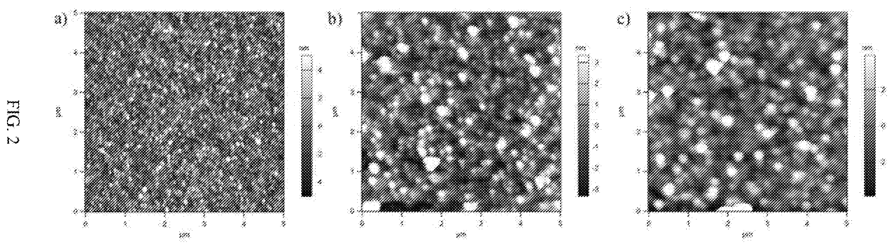

Absolut-Ba (Air Liquide, bis(1,2,4 triisopropylcyclopentadienyl)Ba, Ba(Cp)₂), high-temperature stable Ti (IV) methoxide (TMO, Ti(OCH₃)₄, Alfa Aesar 95%) were used as precursors for Ba and Ti, respectively, and ozone (O₃) as a reactant. For the first set of films a seed layer approach was employed, and »4-5 nm BTO seed layers were annealed at 700° C. for 5 min. before depositing a thicker BTO film at 350° C. Due to the lattice mismatch to Pt, a small amount of crystalline BTO forms during the ALD-process, as shown in the X-ray diffraction (XRD) scan revealed by a weak peak at »32° in 2θ (FIG. 1) and atomic force microscopy (AFM) height image by small crystallites (FIG. 2a).

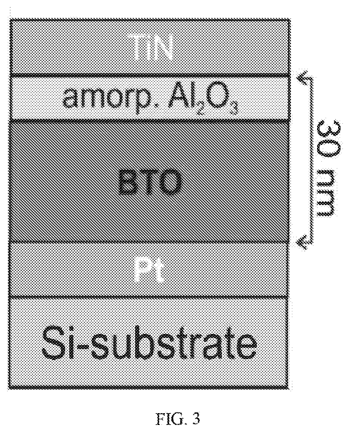

The properties of MIM-capacitors using a stacking sequence according to FIG. 3a were investigated. In one series we studied the influence of the top Al₂O₃ layer on the crystallization behavior of the BTO film. Al₂O₃ films of 4 nm in thickness were deposited onto amorphous BTO films grown on Si-substrates. Subsequently, two films were annealed in air, one at 700° C. for 1 hour and the second film at 800° C. for 1 hour. In both cases XRD showed no sign of crystallization of the BTO layer, which is consistent with reports in literature for STO thin films. This eliminates the option to deposit aluminum oxide before the annealing step. Therefore, the BTO films deposited on Pt/Si were annealed at 700° C. and at 750° C. for 10 min. in air prior to depositing 4 nm thick Al₂O₃ on the crystalline BTO. The polycrystalline nature of the BTO films after the annealing step was confirmed by XRD (FIG. 1).

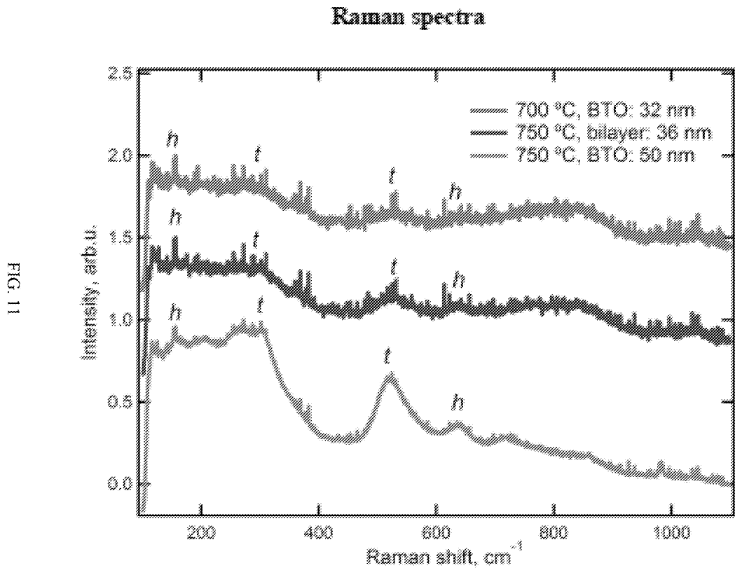

Raman spectra (FIG. 11) confirm the polymorphism in all of the ALD-deposited and annealed BTO thin films, where signature modes of tetragonal as well as hexagonal BTO were clearly observed. These characteristics for polymorphism in these nanocrystalline BTO films are independent of the cation ratio.

The surfaces for this set of films were examined after the deposition, after annealing at 700° C. and at 750° C. in N₂ flow, and depositing 4-nm Al₂O₃. Confirming the XRD-results the as-deposited film reveals only small grains on the surface, while annealing results in grain growth and crystallization. That the Al₂O₃ layers in FIGS. 2b and 2c cannot be seen as a conformal growth should preserve the topology of the BTO. Interestingly, the average roughness (RMS) does not increase significantly, being »2 nm for all films. An increase of the grain size with annealing temperature is visible, which results in a locally increased variation in film thickness.

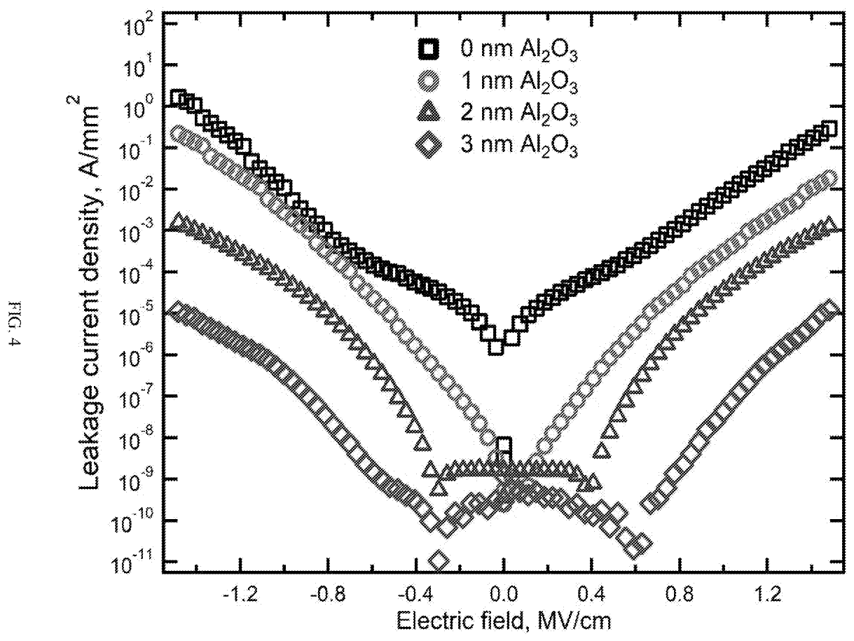

For MIM-capacitors, TiN top electrodes of »45 nm thickness, a resistivity of 300-400 μΩcm, and a square base area of 90×90 μm² were deposited at a power of 450 W utilizing a standard photolithography process and sputtering at room temperature for the »30 nm thick BTO films and BTO-Al₂O₃ bi-layer structures of stacking sequence shown in FIG. 4 grown on Pt(111)/Ti/SiO₂/Si(100) substrates after annealing.

Structural and Property Characterization

Grazing incidence X-ray diffraction (GI-XRD) and X-ray reflectivity (XRR) measurements were performed using a Rigaku Smartlab equipped with a Cu-source. Film thicknesses were extracted from XRR data by least squares fits to the modified Bragg equation. Raman spectra were collected in backscattering configuration z(x,x+y)z⁻ using a single monochromator (XploRA, Horiba Jobin-Yvon, Edison, N.J.) and a laser (4 mW, λ=532 nm) focused to a spot diameter of ≈10 μm at an intensity of 1.6×103 W*cm⁻². Light was dispersed using a 2400 gr per mm grating and collected using a Peltier-cooled array detector. Surface morphology was probed using an Asylum Research MFP-3D atomic force microscope. The transmittance was measured using a Shimadzu UV-2501 PC spectrometer.

Electrical properties were measured in a metal-insulator-metal (MIM) configuration on the samples grown on Pt(111)/Ti/SiO₂/Si(100) substrates. The bottom electrode was contacted using Ag-paste. The MIM-structured samples were placed in a probe station (Lakeshore Cryotronics TTP4) and measured in air at room temperature and 125° C. utilizing a Keithley SCS-4200 electrometer.

XPS measurements were performed using a Physical Electronics VersaProbe 5000 under a base-pressure of ˜10⁻⁶ Pa. An Al-Kα source provided incident photons with an energy of 1486.6 eV at 10 kW mm⁻². XPS spectra were collected with the pass energy of 23.5 eV. An electron neutralizer was used to neutralize the surface. Linear energy correction was applied in reference to the carbon spectra. The energy of the C1s peak of non-oxidized carbon was set at 284.8 eV. The detector was placed at the angle of 87.2° relative to the surface of the films.

Exemplary Results and Discussion

BTO Films and BTO-Al₂O₃ Stacks

To investigate the influence of the Al₂O₃ layer thickness on the leakage current, layers of Al₂O₃ of 1 nm, 2 nm, and 3 nm in thickness were deposited on the BTO film as described above. The thicknesses of the layers were confirmed by XRR. The results of leakage current measurements at room temperature for slightly Ba-rich films after annealing at 500° C. are displayed in FIG. 4. The voltage was first ramped up to +4V in 0.1 increments and then from 0 to −4V. Compared to the individual (without Al₂O₃) BTO film, a 2-nm thick Al₂O₃ allows one to decrease the leakage current by »2 orders of magnitude at 1 MV/cm, while a 3-nm thick Al₂O₃ layer reduces leakage current by »5 orders (FIG. 4). In subsequent experiments, a 4-nm thick Al₂O₃ layer was used.

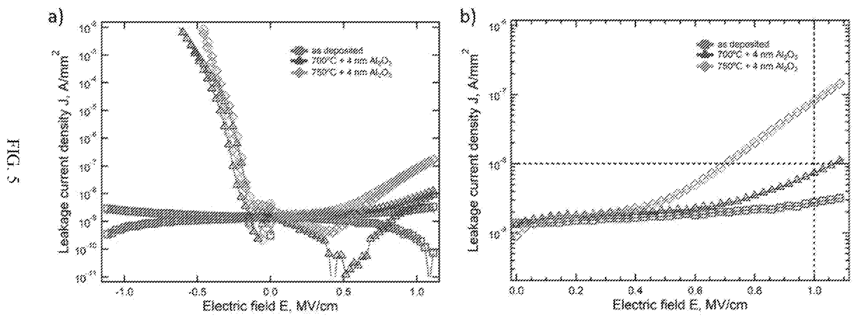

FIG. 5 provides the room-temperature leakage current density as a function of process conditions for these films. The different processing and annealing steps were: i) as deposited: after the ALD-growth of the film, ii) 700° C.+4-nm Al₂O₃ and iii) 750° C.+4-nm Al₂O₃: subsequent annealing for 10 min under N₂ flow, followed by the growth of 4-nm Al₂O₃.

It can be seen in FIG. 5a that the as-deposited film exhibits a low current density, 3×10⁻¹⁰ A/mm² at 1 MV/cm, in agreement with the amorphous state determined by XRD. After annealing, the leakage current increases and becomes asymmetric. This asymmetry may arise due to two-step ALD-growth, as first the BTO film was deposited and annealed and then the Al₂O₃ layer was deposited. As a result, interface defects and contamination layer introduced at the film surface, lead to the bigger difference in the Schottky barrier heights at the Pt-BTO and TiN—Al₂O₃ interfaces as will be shown below. However, the data for positive bias are expected to be representative for the properties of the MIM-stacks. In FIG. 5b the positive bias is shown along with the minimum ITRS requirement (10⁻⁸ A/mm², at higher voltages).

Comparing the films annealed at 700° C. with and without Al₂O₃ layer, one sees that a 4-nm amorphous Al₂O₃ layer reduces the current density by one order of magnitude below this value. Annealing at 750° C. increases the leakage current again by one order of magnitude. Without being bound to any particular theory, one can attribute this increase to the larger grains observed by AFM (see FIGS. 2b and 2c), which results to locally increased electric fields due to variations in the film thickness.

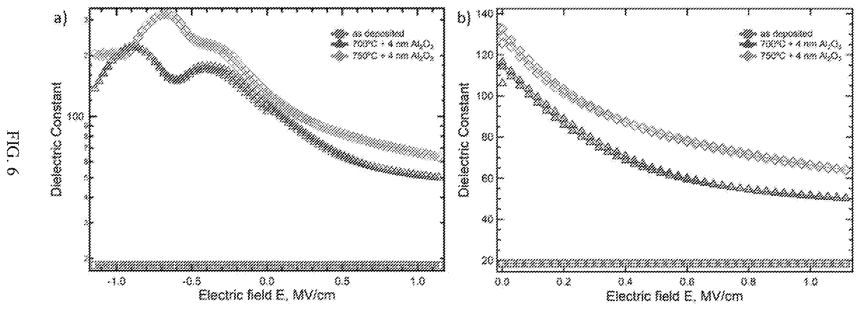

The dielectric constant as a function of electric field for the same MIM-capacitors is shown in FIG. 6. We calculated the dielectric constant of the BTO-Al₂O₃ stacks using the standard model for two parallel-plate capacitors in series. Similar to the leakage current a strong asymmetry is observed for the dielectric constant. Under negative bias also the dielectric loss (not shown) increases dramatically (by at least 3 orders). The measured dielectric constant has a large contribution from space charge, i.e., charge carriers leaking through the device, and cannot be considered as a reliable value (FIG. 6a). On the other hand, under positive bias the dielectric losses remain below 10⁻² and the contribution to the dielectric constant can (again without being bound to any particular theory) be attributed to the insulating BTO-Al₂O₃ stack.

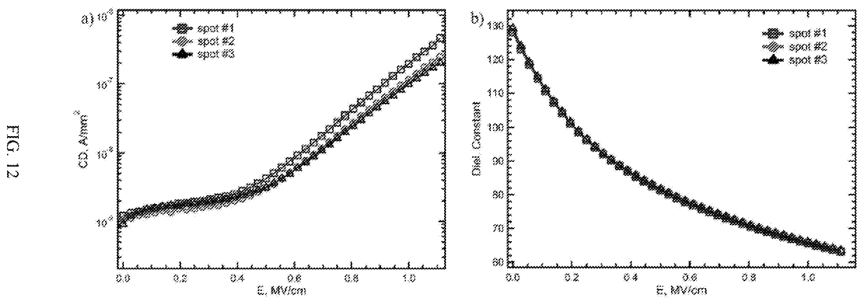

The as-deposited MIM-structure has a very low field independent dielectric constant of 18 as expected for an amorphous film. After annealing, the dielectric constant for all MIM-devices shows a similar field-dependence with the film annealed at 700° C. exhibiting a value of 108 at electric field E=0 and the film annealed at 750° C. exhibiting a value of 130 at E=0, respectively. Both MIM-capacitor stacks exceed a value of 100. One can notice a good reproducibility between different Pt-BTO-Al₂O₃-TiN capacitors (FIG. 12).

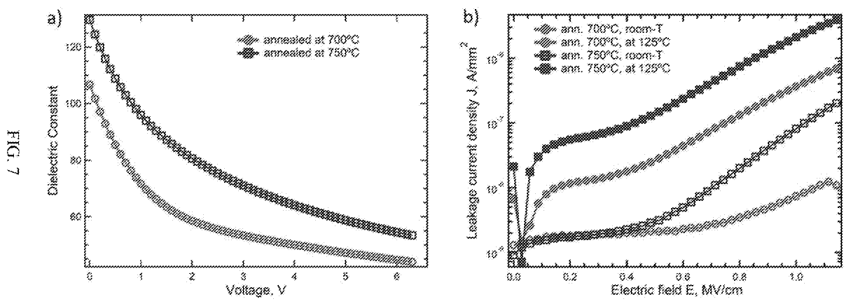

To test these devices for capacitance and leakage current, we performed additional testing under the defined conditions for the two MIM-structures with Al₂O₃ layer of 4 nm annealed at 700° C. and 750° C. (FIG. 7). The relevant performance parameters for these 2 structures are provided in Table 1.

To test these devices for capacitance and leakage current, we performed additional testing under the defined conditions for the two MIM-structures with Al₂O₃ layer of 4 nm annealed at 700° C. and 750° C. (FIG. 7). The dielectric constant at 6.3V drops below 50 for the BTO-Al₂O₃ stack annealed at 700° C., while it remains at 55 at 6.3 V for the BTO-Al₂O₃ stack annealed at 750° C. meeting the defined range (FIG. 7a). In testing different top electrode spots, while for the BTO-Al₂O₃ structure annealed at 700° C.»80-90% of the MIM-capacitors were able to withstand 6.3V bias, for the BTO-Al₂O₃ structure annealed at 750° C. this rate dropped below 50%. A similar observation was made for the leakage current tests at 125° C. showing that annealing at 750° C. results in less stable films with larger fluctuations of the properties. The current density for both films increases by one order of magnitude between room temperature and 125° C. with higher values than 10⁻⁸ A/mm². The relevant performance parameters for these 2 structures are provided in Table 1, below.

TABLE 1
Total thickness, dielectric constant at 6.3 V and leakage
current density at room temperature and 125° C. for two most
promising BTO—Al₂O₃ bi-layer stacks.

| | | Dielectric | Leakage Current |
|---|---|---|---|
| | Thickness | Constant | density |
| Annealed at 700° C., | 36 | 44 | 2.2 × 10⁻⁸ A/mm² |
| Pt—BTO—Al₂O₃—TiN | | | at RT |
| | | | 5 × 10⁻⁷ A/mm² |
| | | | at 125° C. |
| Annealed at 750° C., | 36 | 53 | 1.3 × 10⁻⁷ A/mm² |
| Pt—BTO—Al₂O₃—TiN | | | at RT |
| | | | 2.5 × 10⁻⁶ A/mm² |
| | | | at 125° C. |

Band Alignment for the Pt-BTO-Al₂O₃—TiN Structure

To gain a deeper insight into the nature of the leakage current in the bi-layered stack, an effort was made to reconstruct a band alignment from the study of barrier heights for the Pt-BTOAl₂O₃—TiN structure. For collecting experimental data, we applied XPS technique which has been widely used for many years to explore the metal/dielectric interface formation and band alignment.

For this study, six samples were prepared: 1) commercially available metallized substrate with a 20-nm TiN film sputtered on SiO₂/Si<100>; 2) as-deposited 10-nm thick Al₂O₃ film grown on the TiN/SiO₂/Si substrate; 3) 10-nm thick BTO film grown on the TiN/SiO₂/Si substrate; this film was annealed at 700° C. for 3 min in air; 4) 10-nm thick BTO film grown over Al₂O₃/TiN/SiO₂/Si film; this film was annealed at 700° C. for 3 min in air; 5) commercially available metallized substrate with a 150-nm Pt film sputtered on SiO₂/Si<100>; 6) 10-nm thick BTO film grown on the Pt/SiO₂/Si substrate; this film was annealed at 700° C. for 3 min in air. In addition, we used magnetron-sputtered TiN as top electrodes to ensure that the process identically works for both bottom and top TiN/dielectric contact interfaces. The film thickness has been obtained from the XRR scans.

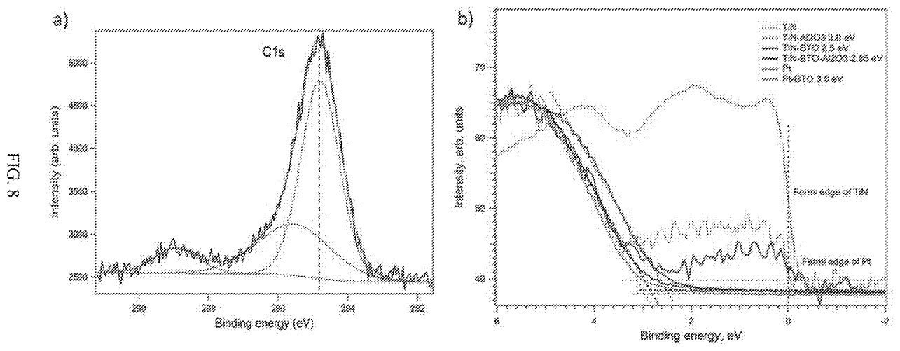

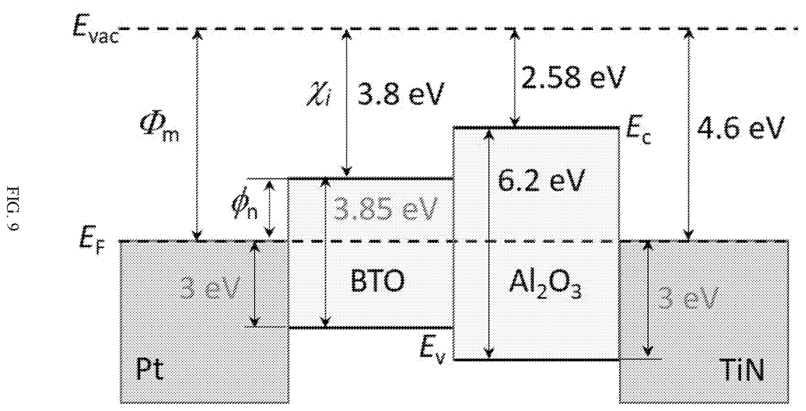

Stoichiometry and crystallinity for BTO films were confirmed from SEM/EDS and XRD data. For each sample, the XPS spectrum of C1s as well as the valence band and/or Fermi energy band spectra have been collected. The presence of carbon is due to unavoidable surface contamination. As we take the C1s lines as a standard for a linear calibration, the C1s spectra was fitted by three Voigt (Gaussian/Lorentzian=70/30) functions. The XPS C1s spectra for the sample Al₂O₃—TiN is presented in FIG. 8a. The Fermi energy position for the samples TiN, Pt and TiNAl₂O₃ was defined as the middle of the first slope at a low-energy edge of binding energy scale. The valence band maximum (VBM) for the samples TiN-Al₂O₃, TiN-BTO, TiN-Al₂O₃-BTO and Pt-BTO is determined by the intercept of the base line and the leading edge of valence band spectrum, as depicted in FIG. 8b. For clarity, the Fermi edges of TiN and Pt were set at 0 eV and the other XPS spectra were shifted accordingly. Therefore, the energy offset between the TiN Fermi energy and VBM extracted from these spectra is 3.0 eV and 2.5 eV for BTO and Al₂O₃, respectively. Note that the energy offset is 2.85 eV for the sample TiN—Al₂O₃-BTO. However, because the thickness of BTO layer is ˜10 nm, we can get the XPS response mainly from BTO and slightly from Al₂O₃. As a result, we observe the shift of VBM at 0.15 eV for the sample TiNAl₂O₃-BTO compared to the sample TiN-BTO. The energy offset between the Pt Fermi energy and VBM of the BTO is 3.0 eV. Using these XPS results, we reconstructed the band alignment for the structure Pt-BTO-Al₂O₃—TiN, shown in FIG. 9.

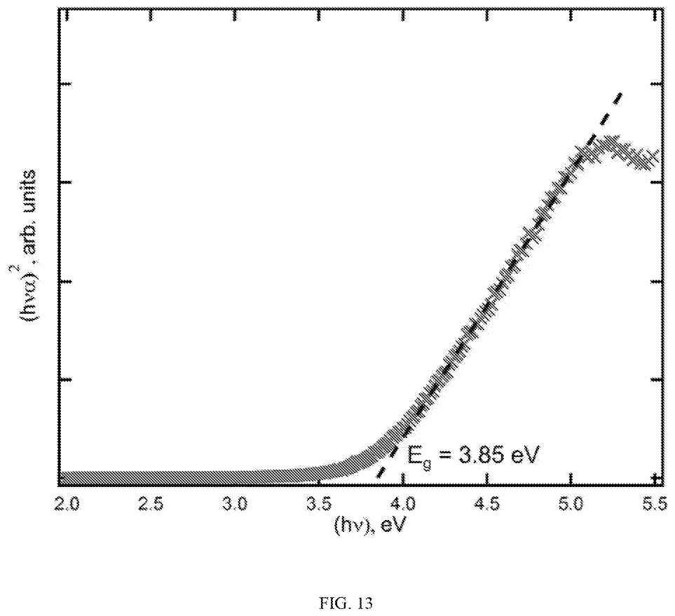

The Schottky barrier height (SBH), fₙ, which is determined as the difference between the conduction band minimum (CBM) of a dielectric, E_{c}, and the Fermi energy position of metal, E_{F}, can be obtained using the band gaps 3.85 eV for BTO, determined experimentally (FIGS. 13), and 6.2 eV for ALD-grown Al₂O₃, taken from the literature.

The values of SBH can be thus estimated as fₙ=0.85 eV for Pt-BTO interface and fₙ=3.2 eV for TiN—Al₂O₃ interface. Also, we notice the difference between the CBM of BTO and Al₂O₃ at the BTO-Al₂O₃ interface, that amounts 0.6 eV. The SBH values determined from the experimental data differs from the values of ideal Schottky barrier which is formed at an interface in the Schottky limit and can be estimated from the Schottky-Mott rule, ϕ_{B}=Fₘ−χᵢ, where Fₘ is the work function of the metal contact and χᵢ is the electron affinity of the dielectric. Based on the reported work functions of TiN (Fₘ=4.6 eV) and Pt (Fₘ=5.6 eV) and the electron affinity of BTO (3.8 eV) and Al₂O₃ (2.58 eV), the SBH is 1.8 eV and 2.02 eV for Pt-BTO and TiN—Al₂O₃ interfaces, respectively. The presence of the surface contamination layer and point defects introduced at the film surface during fabrication are usually considered as the causes for the difference between experimentally observed and ideal Schottky barriers. The difference between experimental values of the SBH for Pt-BTO interface (fₙ=0.85 eV) and for TiN—Al₂O₃ interface (fₙ=3.2 eV) can explain the asymmetry in the electric-field dependences of leakage current and dielectric constant (FIGS. 5a and 6a, respectively).

Comparison of Different High-K Oxide Thin Films

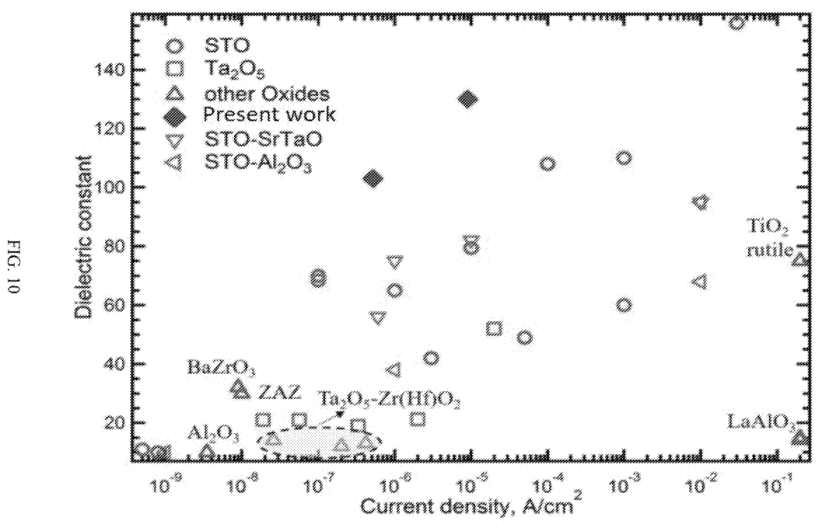

Comparing our results to a variety of other high-k oxides, both individual materials and multilayered structures, reveals the remarkable performance for the nanocrystalline polymorphic BTOAl₂O₃ thin film stacks (FIG. 10) in terms of the combination of leakage current and dielectric constant. In this respect the nanocrystalline polymorphic BTO-Al₂O₃ thin-film stacks produced in present work are well separated from other reported materials. In particular, the comparison to STO-Al₂O₃ stacks with STO thickness of 50 nm and Al₂O₃ of up to 4 nm demonstrates the superior performance of the disclosed materials.

Conclusions

Compared to the individual (without Al₂O₃) BTO film, a 2-nm thick Al₂O₃ allows one to decrease the leakage current by »2 orders of magnitude at 1 MV/cm, while a 3-nm thick Al₂O₃ layer reduces leakage current by »5 orders. A 4-nm thick Al₂O₃ layer thus provides substantially reduced leakage current, while it still preserves a high effective dielectric constant of the stack.

A bilayer stack that encompasses a 32-nm thick BTO film annealed at 700° C. and a 4-nm thick Al₂O₃ layer deposited over the BTO film exhibited dielectric constant 108 at 0V and 44 at 6.3V, respectively, while leakage current is 5×10⁻⁷ A/mm² and 2.2×10⁻⁸ A/mm² at 125° C. and room temperature, respectively.

A bilayer stack that encompasses a 32-nm thick BTO film annealed at 750° C. and a 4-nm thick Al₂O₃ layer deposited over the BTO film exhibits dielectric constant 130 at 0V and 53 at 6.3V, respectively, while leakage current is 2.5×10⁻⁶ A/mm² and 1.3×10⁻⁷ A/mm² at 125° C. and room temperature, respectively. Higher leakage current is attributed to the greater grain sizes in BTO film due to annealing at higher temperature.

Reconstruction of a band alignment for the Pt-BTO-Al₂O₃—TiN structure shows that Al₂O₃ layers located between TiN electrode and BTO can substantially reduce leakage current. In addition, the quality of BTO-Al₂O₃ interface should be taken into consideration.

Compared to common high-k materials the films presented in this work demonstrate a better overall performance considering both key parameters, dielectric constant and current density.

Additional Disclosure

Characterization and Electrical Testing of the BTO Films on TiN-Coated Substrates

BTO films were grown using Absolut-Ba (Air Liquide, bis(1,2,4 triisopropylcyclopentadienyl) Ba, Ba(Cp)2) and high-temperature stable Ti (IV) methoxide (TMO, Ti(OCH₃)₄, Alfa Aesar 95%) as precursors for Ba and Ti, respectively, and ozone (O₃) as a reactant. The deposition was carried out at 350° C.

The first set of samples we investigated involved 28-nm thick BTO films grown on TiN-coated substrates. Taking the aforementioned RTA approach in mind, we performed RTP annealing at 700° C., 800° C., 850° C., and 900° C. Annealing time was varied from 1 to 30 sec. In all cases, N₂ flow was used. Samples were investigated using XRD and SEM/EDS to identify the onset of BTO crystallization and to control the stoichiometry.

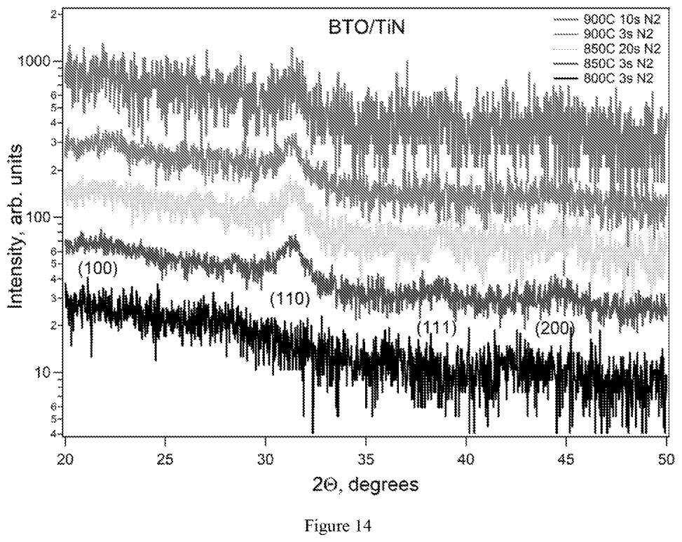

The representative XRD scans are presented in FIG. 14. No evidence of the BTO phase is observed for the film annealed at 800° C. However, crystallization of BTO appears in the films annealed at 850° C. for 3 sec, at 850° C. for 20 sec, and at 900° C. for 3 sec. This is reflected in the XRD scans with a (110) peak at ˜32° in 2θ and weak (111) and (200) peaks at ˜38° and 44°, respectively.

The XRD scan for the BTO film annealed at 900° C. for 10 sec shows a weaker (110) peak than that for the samples annealed at 900° C. for 3 sec. This result indicates that longer annealing time at 900° C. leads to the partial degradation of the BTO phase. Annealing at 850° C. for 20 sec results in the (110) peak of the same intensity compared to that for sample annealed at 850° C. for 3 sec. On the other hand, the (111) and (200) peaks are almost unseen in the XRD scan for the sample annealed at 850° C. for 20 sec. Based on XRD data, crystallization of the BTO thin film on TiN-coated substrate occurs after RTP annealing at 850° C. and at 900° C. both for 3 sec in N₂ flow.

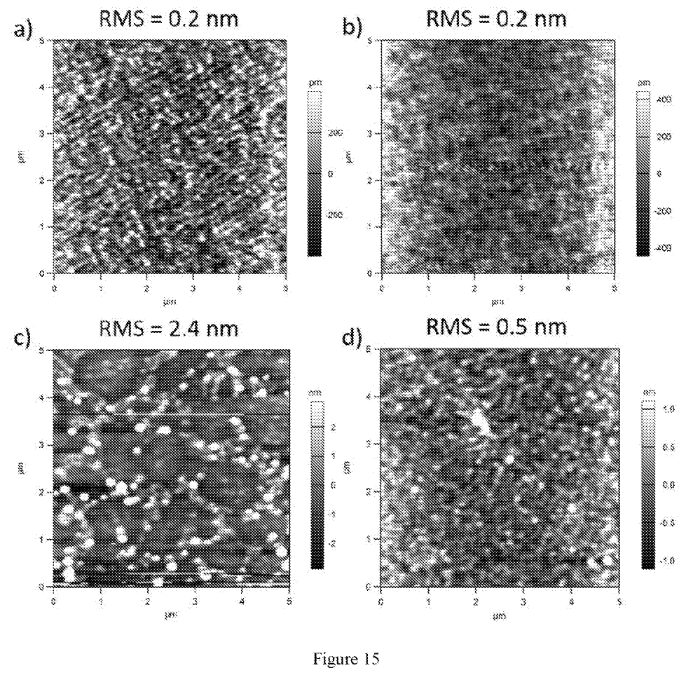

The surfaces for this set of films were examined after annealing at 850° C. for 3 sec and for 20 sec, and after annealing at 900° C. for 3 sec and for 10 sec. The AFM data are presented in FIG. 15. Examining the XRD results for the film annealed at 850° C. for 3 sec reveals tiny grains on the surface, while annealing at the same temperature for longer time appears to result in partial deterioration of the BTO phase.

The average roughness (RMS) is small, around 0.2 nm, for the two films. An increase of the grain size with annealing temperature is clearly visible in FIG. 15c. However, the surface is not uniformly covered by grains, resulting in a locally increased variation in film thickness and in an increased RMS up to 2.5 nm. The BTO surface in FIG. 15d again shows partial degradation of the BTO phase. The average roughness decreases with phase deterioration and becomes ≈0.5 nm for the film annealed for 10 sec. at 900° C.

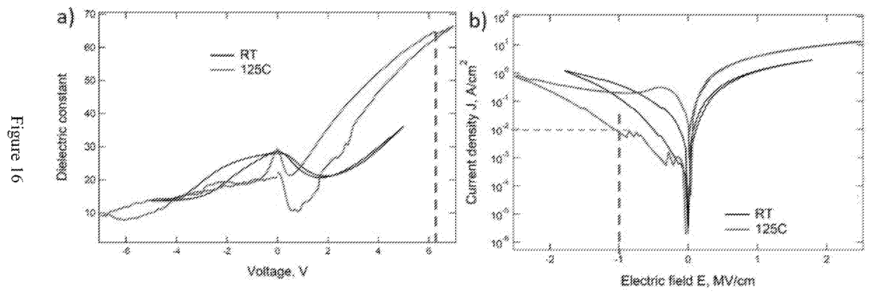

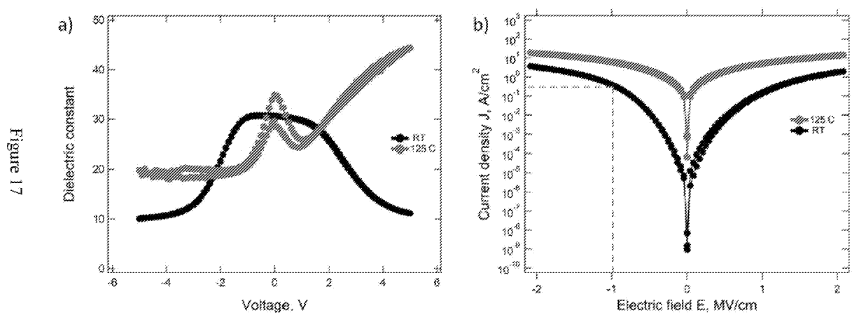

For MIM-capacitors, TiN top electrodes of ≈45 nm thickness and a square base area of 90×90 μm2 were deposited at a power of 450 W utilizing standard photolithography and sputtering at room temperature on the 28 nm thick BTO films annealed at 850° C. and at 900° C. that are crystallized or partially crystallized as determined by the XRD and AFM data. The electrical properties under applied electric field for two representative films are shown in FIGS. 16 and 17.

The relative dielectric constant at E=0 is ≈30 for both films. This result corroborates the XRD and AFM data that the films are partially amorphous. The TiN-BTO-TiN MIM-capacitors based on these films were tested for dielectric constant and leakage current at RT and 125° C. It can be seen from FIGS. 16a and 17a that the relative dielectric constant >50 under positive bias at 6.3V at 125° C. for both films.

To gain insight into the nature of leakage current, we considered different conduction mechanisms for the BTO film annealed at 900° C. Because the E-field dependence is symmetric in positive and negative bias directions, the analysis can be conducted for the positive upward bias. We consider Schottky emission, Poole-Frenkel (PF) emission and space-charge limited conduction (SCLC) mechanisms, which are commonly observed in perovskite oxides.

The relation between current density, J (or conductivity s), and voltage, V, for each of these mechanisms is:

$$\begin{matrix}\text{Schottky emission:} {J}_{s} = {AT}^{2} exp - [ \frac{Φ}{{k}_{B} T} - \frac{1}{{k}_{B} T} \sqrt{\frac{{q}^{3} V}{4 {πɛ}_{0} Kd}} ] & ( 1 ) \\ \text{Poole-Frenkel emission:} {σ}_{PF} = c exp - [ \frac{{E}_{l}}{{k}_{B} T} = \frac{1}{{k}_{B} T} \sqrt{( \frac{{q}^{3} V}{{πɛ}_{0} Kd} )} ] & ( 2 ) \\ SCLC \text{mechanism:} {J}_{Ohm} = \frac{{qn}_{0} μ V}{d} , {J}_{TFL} = \frac{9}{8} μɛΘ \frac{{V}^{2}}{{d}^{3}} , {J}_{Child} = \frac{9}{8} μɛ \frac{{V}^{2}}{{d}^{3}} & ( 3 )\end{matrix}$$

In equations (1)-(3), A is the Richardson constant, T is the temperature, Φ is the height of the Schottky barrier, k_{B} is the Boltzmann constant, q is the elementary charge, V is the applied voltage, £0 is the permittivity of free space, K is the optical dielectric constant, d is the sample thickness, c is a constant, E₁ is the trap ionization energy, n₀ is the concentration of the free charge carriers in thermal equilibrium, μ is the mobility of charge carriers, ϑ is the static dielectric constant and θ is the ratio of the free carrier density to total carrier (free and trapped) density.

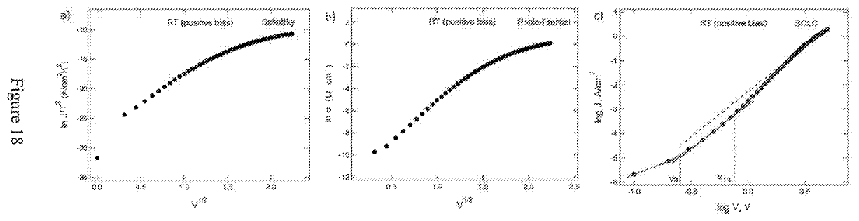

As equations (1) and (2) show, Schottky and Poole-Frenkel emission are similar in terms of current-voltage relationship, but the first one is interface-limited, while the second one is bulk-limited. Representative dependences for these different mechanisms are shown in FIG. 18. In general, each mechanism contributes to the electrical conductivity, so that strictly speaking, one can identify only the dominating mechanism. As can be clearly seen from the fitting in FIG. 18, the SCLC mechanism is dominant in the film. For this mechanism, the log J-log V dependence is comprised of three distinct regions, namely, Ohm's law, traps-filled limit (TFL) current, and Child's law with the points Vₜᵣ and V_{TFL} which are the transition voltages between the regions. In the film, the transition voltage Vₜᵣ is 0.25 V. Note that Vₜᵣ is the voltage at which the transition from Ohm's law to SCLC takes place. At this point, the traps are filled up and a space charge appears. V_{TFL} defined as the voltage required to fill the traps is 0.75 V for this film.

Formation of the BTO over the post-deposition annealing occurs in accordance with the reaction: BaO+TiO₂═BaTiO₃. It means that crystallization implies 3 steps: 1) breaking of the Ba—O and O—Ti—O bonds, 2) diffusion of the Ba, Ti and O atoms, 3) formation of the BaTiO₃ perovskite structure.

Characterization and Properties of BTO-Al₂O₃ Stacks with Al₂O₃ Layer Between BTO and TiN Top Electrode

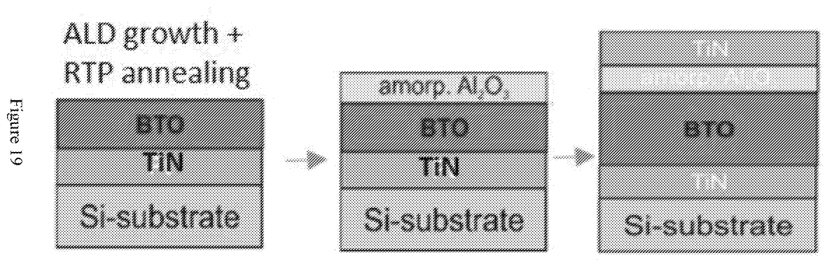

Fabrication of the TiN-BTO-Al₂O₃—TiN MIM-capacitors with an Al₂O₃ layer located between the BTO film and TiN top electrodes follows the steps presented in FIG. 19. First, we deposited the 25-nm thick Ba—Ti—O on TiN substrate and cut as-deposited film into four pieces. Two of the four pieces were RTP annealed at 850° C. for 3 sec and other two at 900° C. for 3 sec.

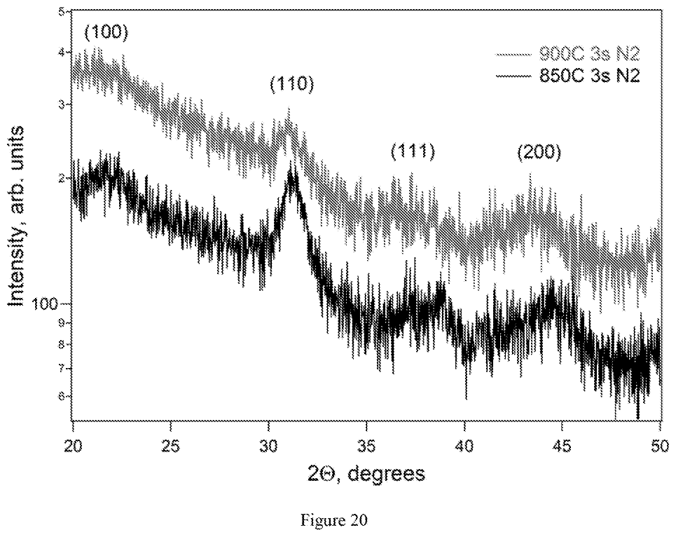

Before depositing top Al₂O₃ layer, the XRD scans were collected to ensure that the BTO phase has been formed (FIG. 20). While all four peaks are very well defined in the XRD-pattern for the film annealed at 850° C., (100) and (110) peaks are much weaker for the film annealed at 900° C. It indicates that the BTO phase is well crystallized already at 850° C., while it is partially decomposed at 900° C. temperature. This is quite reasonable, as a thinner film can be expected to require a reduced annealing temperature for crystallization.

In order to show the influence of the thickness of the Al₂O₃ layer, we deposited 2-nm and alternately 3-nm thick Al₂O₃ layers on the annealed 25-nm thick BTO/TiN films.

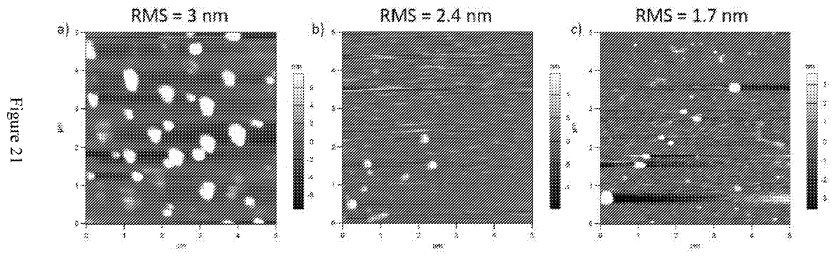

FIG. 21 shows the topographical AFM images of these films and their roughness mean square (RMS) values for an area of 5×5 μm². The BTO phase crystallites can be clearly seen in FIG. 21a. This topology becomes almost indiscernible for the films with top Al₂O₃ layer. The top Al₂O₃ layer also impacts the surface smoothness. The RMS value decreases from 3 nm for the film without Al₂O₃ layer, to 2.4 nm with the 2-nm thick Al₂O₃ layer and to 1.7 nm with 3-nm thick Al₂O₃ layer.

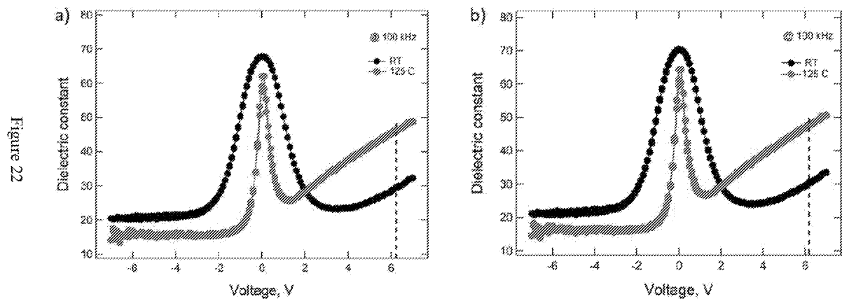

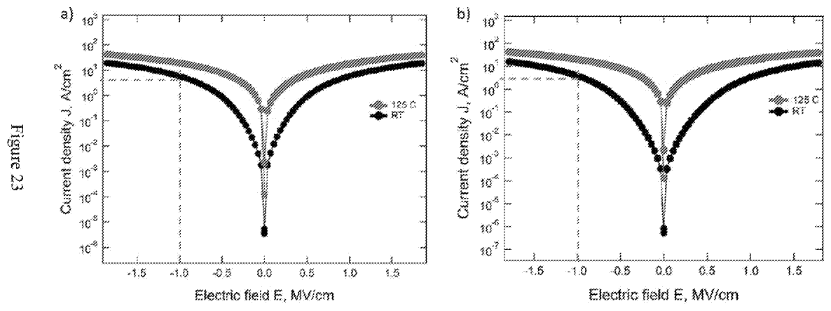

The electrical properties under applied electric field for two representative BTO-Al₂O₃ films with 2-nm and 3-nm thick Al₂O₃ layer are shown in FIGS. 22 and 23. We notice that dielectric constant at E=0 is around 70 for both films. This value is higher than that for the 28-nm thick BTO films without Al₂O₃ layer (see previous section). This result is in agreement with XRD and AFM data, and evidences a better level of crystallization of the 24-nm thick BTO film annealed at 850° C. for 3 sec compared to the 28-nm thick BTO annealed at 900° C. for 3 sec. At positive bias of 6.3V, dielectric constant of the BTO-Al₂O₃ stack is 30 at RT and ˜50 at 125° C. for both, 2-nm and 3-nm thick, Al₂O₃ layers.

The TiN-BTO-Al₂O₃—TiN MIM-capacitors were also tested at RT and 125° C. Representative data collected for the BTO-Al₂O₃ stacks that contain BTO films annealed at 850° C. are shown in FIG. 23. It can be seen that 3-nm thick Al₂O₃ layer allows to decrease leakage current in 1 order of magnitude compared to the 2-nm thick Al₂O₃ layer at E=0 at RT. However, leakage current is the same at 1 MV/cm at RT and 125° C. for both, 2-nm and 3-nm thick Al₂O₃ layer.

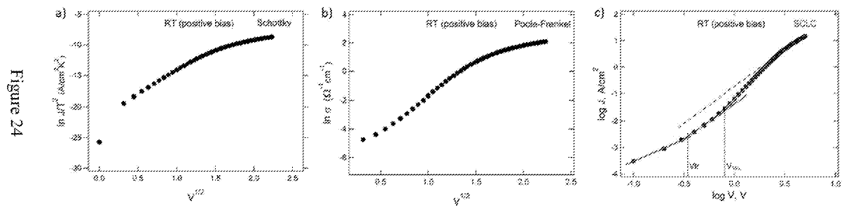

Again, we considered different conduction mechanisms in order to identify possible reasons for high leakage current. The analysis of three conduction mechanisms was made as described above. The comparison of the results presented in FIG. 24 for the TiN-BTO-Al₂O₃—TiN MIM-capacitors with the results obtained for the TiN-BTO-TiN MIM-capacitors shown in FIG. 18 demonstrates that the nature of the leakage current is identical and comes predominantly from the space charges formed in the BTO layer.

The transition voltage Vₜᵣ is 0.35 V in the TiN-BTOAl₂O₃—TiN MIM-capacitor, that is a little higher than Vₜᵣ=0.25 V in the TiN-BTO-TiN MlMcapacitor. The voltage required to fill the traps V_{TFL} is 0.75 V for the TiN-BTO-Al₂O₃—TiN structure, which is the same as for the TiN-BTO-TiN film.

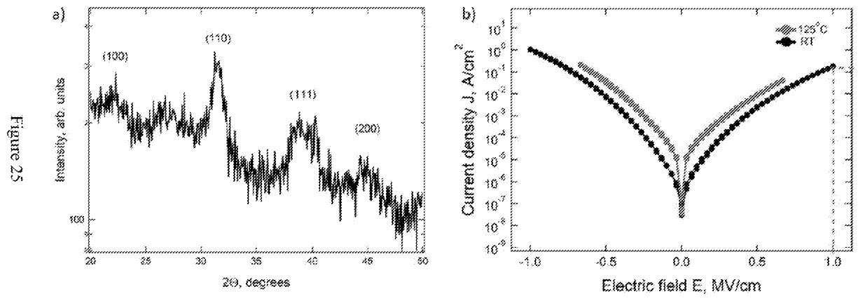

To investigate the bottom electrode's contribution to leakage current, we produced and tested the BTO-Al₂O₃ stacks on Pt-substrates. For this structure, the 28-nm thick BTO film was annealed at 950° C. for 2 min in N₂ flow to have the sigh of BTO phase in XRD scan (FIG. 25a).

The 3.5 nm thick Al₂O₃ layer was deposited on the top of the annealed BTO film. For this BTO-Al₂O₃ stack, relative dielectric constant is 50 at E=0 at RT. Leakage current is as low as ˜10⁻⁸ A/cm² at E=0 at RT and 125° C.

ALD-Growth of the BTO on TiN-Substrates Using a Seed BTO Layer

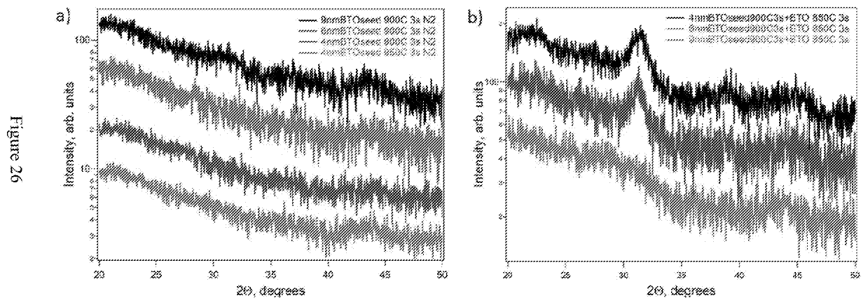

For seed layering, a thin BTO-seed layer of three different thicknesses (4 nm, 6 nm, 9 nm) was deposited on the TiN-coated substrates and annealed at a 900° C. or 950° C. for 3 sec. Short annealing time was intentionally applied to avoid the oxidation of TiN bottom electrode. While there is no sign of crystallization of the 4-nm and 6-nm BTO-seed layers even after annealing at 950° C. in their XRD scans, weak (110) and (200) peaks indicate the onset of crystallization of the 9-nm thick BTO-seed layer after annealing at 900° C. for 3 sec (FIG. 26a). Indeed, well defined (110) peak in the XRD scans for the main BTO film deposited on the top of the 4-nm and 6-nm thick layers demonstrates the formation of the BTO phase in the film after annealing at 850° C. for 3 sec (FIG. 26b).

We also deposited BTO-Al₂O₃ stacks over the annealed BTO-seed layers. Two stacking sequences for the BTO-Al₂O₃ structure were used: 1) bottom 3-nm Al₂O₃+ top 17-nm BTO layer; 2) bottom 17-nm BTO layer+top 3-nm Al₂O₃ layer. All BTO-Al₂O₃ stacks were deposited in one-step ALD growth procedure. After the deposition, whole structure was RTP annealed at 900° C. for 3 sec in N2 flow. The XRD scans is clearly demonstrate well defined (100), (110), (111) and (200) peaks for both stacking sequences, indicating the formation of the BTO phase. Crystallization happens in the film with top Al₂O₃ layer. This is unexpected result, as typically XRD shows no sign of crystallization of the BTO layer with top Al₂O₃ layer.

Characterization and Electrical Testing of the Al₂O₃-BTO-Al₂O₃ Tri-Layer Composite Stacks on TiN-Substrates

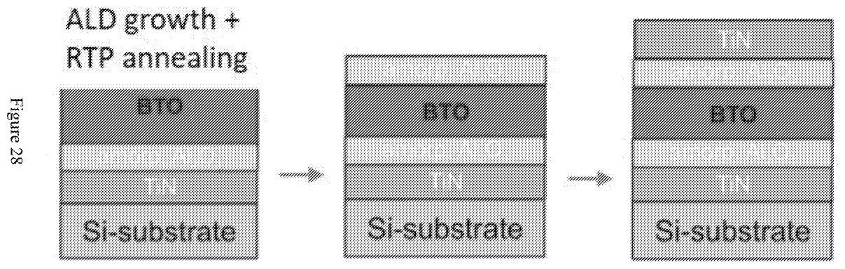

Fabrication of the TiN-Al₂O₃-BTO-Al₂O₃—TiN MIM-capacitors proceeds according to the steps presented in FIG. 28. First, we deposited a 2.5-nm thick Al₂O₃ layer and ˜26-nm thick Ba—Ti—O on TiN substrate and cleaved the as-deposited film into four pieces. The four pieces were RTP annealed at 850° C. for 1 min, at 900° C. for 10 sec, for 1 min and for 2 min, respectively. In all cases, a heating rate was 10° C./sec. After the annealing step, another 2.5-nm thick Al₂O₃ layer was deposited. For MIM-capacitors, TiN top electrodes of ˜45 nm thickness and a square base area of 90×90 μm2 were deposited utilizing a standard photolithography process and sputtering at room temperature.

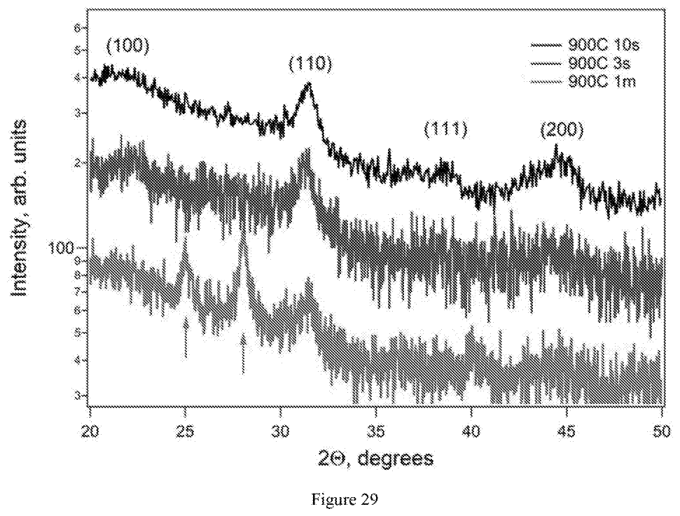

The XRD data show a pure BTO phase on the Al₂O₃-BTO-Al₂O₃ structures annealed at 850° C. for 1 min and at 900° C. for 10 sec, while it demonstrates the presence of additional phases in the structures annealed at 900° C. for 1 min and at 900° C. for 2 min. The representative Grazing Incidence XRD (GIXRD) scans are presented in FIG. 29.

Crystallization of BTO is shown in the trilayer structure annealed at 900° C. for 10 sec. This is reflected in the XRD scan (in black color) with a strong (110) peak at ˜32° in 2θ and weak (100), (111) and (200) peaks at ˜23°, ˜38° and 44°, respectively. The XRD scan for the structure annealed at 900° C. for 1 min (in red color) shows a weak (110) peak from BTO phase and two peaks at 25° and ˜28° (denoted with arrows) from the secondary phase(s).

Annealing at 900° C. for 10 sec at a heating rate of 10° C./sec results in the XRD peaks of higher intensity (accounting for signal-to-noise) compared to that for sample annealed at 900° C. for 3 sec at a heating rate 50° C./sec (XRD scan in blue color). Without being bound to any particular theory, a lower heating rate and a longer annealing time at 900° C. may improve crystallization of the BTO phase.

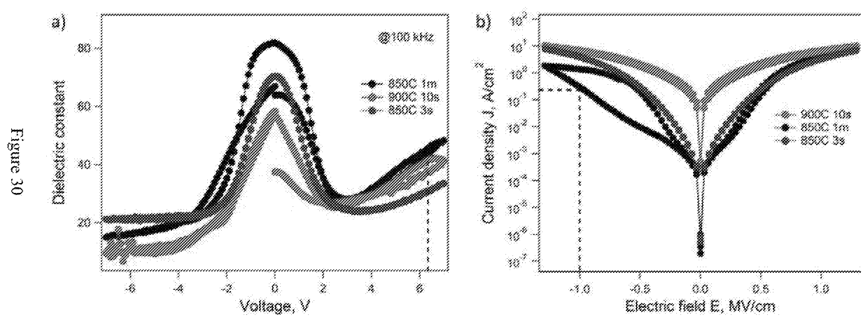

The electrical properties under applied electric field for two representative Al₂O₃-BTO-Al₂O₃ structures are shown in FIG. 30. We notice that dielectric constant at E=0 is ˜70 for the structure annealed at 850° C. for 1 min, while it is ˜60 for the structure annealed at 900° C. for 10 sec. For comparison, data for the 28-nm thick BTO-Al₂O₃ stack annealed at 850° C. for 3 sec at a heating rate 50° C./sec are also shown. It can be seen that at 6.3V the structure annealed at 850° C. for 1 min exhibits the highest dielectric constant which is 45. Leakage current was quite low at E=0. It should be noticed that leakage current is one order of magnitude lower at a magnitude of 1 MV/cm for the Al₂O₃-BTO-Al₂O₃ tri-layer stack annealed at 850° C. for 1 min at a heating rate 10° C./sec.

The asymmetric shape of the J-E dependence in this case reveals the effect of the interface between TiN top electrodes and the Al₂O₃-BTO-Al₂O₃ structure. On the positive bias side, the leakage current is practically the same for this structure and for the 28-nm thick BTO-Al₂O₃ stack annealed at 850° C. for 3 sec at a heating rate 50° C./sec. Thus, the lower heating rate and longer annealing does not reduce leakage current. On the other hand, we observe the influence of the metal-dielectric interface that results in reduction of leakage current at a factor of 10. Moreover, contraindicated tendency of the dielectric constant and leakage current behavior (dielectric constant goes down while current goes up) for the Al₂O₃-BTO-Al₂O₃ structure annealed at 900° C. for 10 sec. compared to the Al₂O₃-BTO-Al₂O₃ structure annealed at 850° C. for 1 min. indicates on the contribution of both internal interfaces, TiN-Al₂O₃ and Al₂O₃-BTO.

TEM Study of the BTO-Al₂O₃ Stacks with Al₂O₃ Layer Between BTO and TiN-Substrate

Previous measurement revealed that the BTO film on TiN-substrate (which has a 20-nm thick TiN sub-layer over Si-substrate) has higher thickness than expected according to the XRR measurement of the BTO film on pure Si-substrate. The additional thickness could arise from penetration of oxygen atoms into TiN-substrate with sequential formation of TiO₂ phase with the higher unit cell volume than TiN. We performed TEM measurement in order to check the presence of TiO₂ phase and the quality of TiN—Al₂O₃ interface.

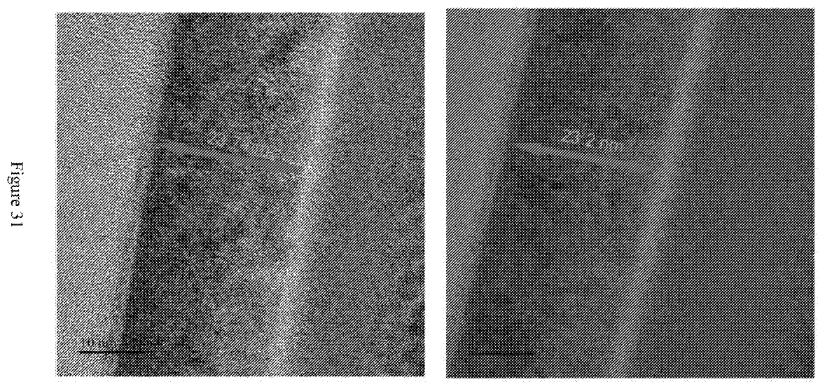

Shown in FIG. 31 are bright-field (BF) images of amorphous Ba—Ti—O films on TiN-substrates with Al₂O₃ layer between TiN-substrate and BTO. Two samples were prepared, by one-step and two step deposition process. As seen from FIG. 31, a two-step prepared film has a thicker (23.7 nm vs 23.2 nm) TiN sub-layer. This can be explained by the higher degradation degree of this film during the two-step process, as a total exposure time at elevated temperature (350° C.) is longer. We note that in the case of a one-step process, the Al₂O₃ layer has much sharper interfaces with both TiN sub-layer and BTO film with little interdiffusion of Al₂O₃ into the BTO film and TiN sub-layer. Without being bound to any particular theory, this may help to preserve properties of both materials.

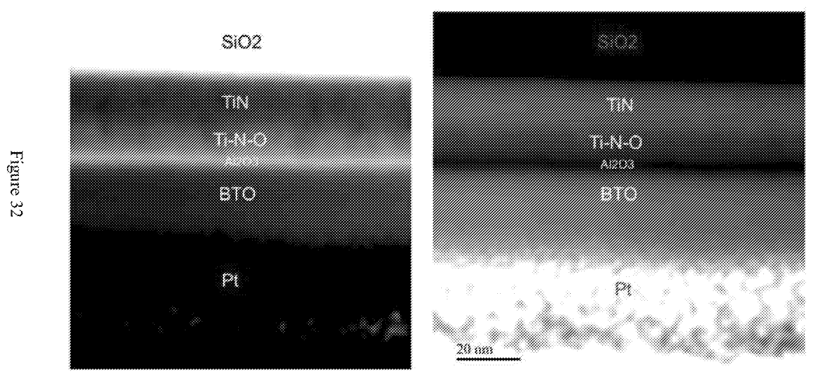

FIG. 32 represents STEM high-angle annular dark field (HAADF) and BF images of BTO films. High Z-contrast of this type of imagining reveals that the top area (denoted as Ti—N—O) amounting to ˜40% of the total thickness of the TiN sub-layer has a lower electron density than the bottom area. This result can be explained by the fact that the average distance between relatively heavy Ti ions is increased because of penetration of oxygen atoms into interstitial spaces of TiN lattice.

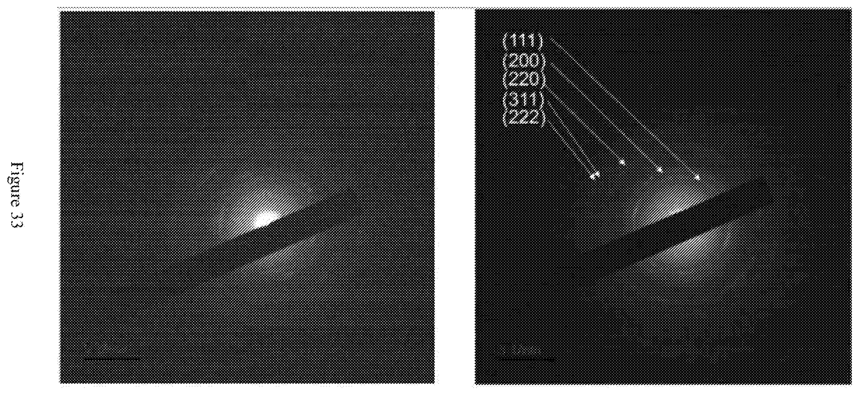

We performed selected area electron diffraction (SAED) of TiN sub-layer in order to clarify phase composition of this layer. The electron diffractograms displayed (FIG. 33) reveal only crystalline TiN phase, and no TiO2 phase was found. The quality of diffraction pattern is practically the same for one-step and two-step process, but close inspection reveals that the TiN lattice reflections in one-step prepared film have a somewhat better defined shape indicating on better overall quality of the TiN sub-layer.

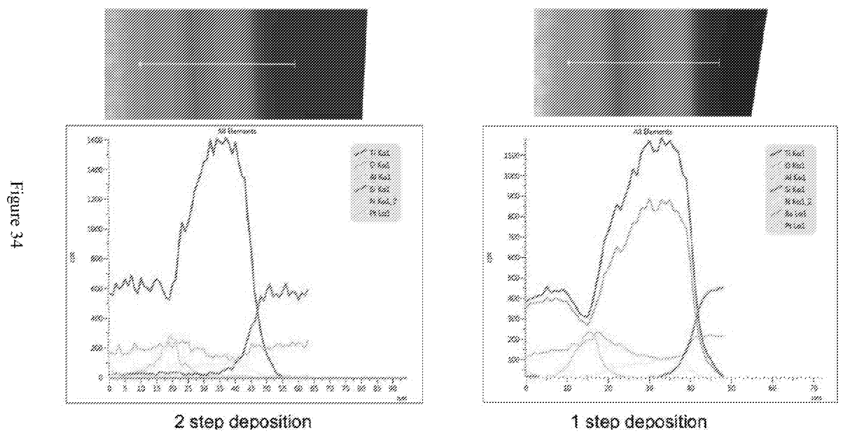

We also collected EDS line scans in the direction perpendicular to the interfaces (FIG. 34). This line scans clearly show that oxygen penetrates into TiN sub-layer in both samples from the side of Al₂O₃-BTO stack almost up to half of the thickness of TiN film. Aluminum spectrum shows a tighter shape for the case of one-step deposition process which is consistent with our previous observations.

Briefly summarizing results, the combined effects of lower heating rate and longer annealing time in the RTA procedure improves the crystallization of the BTO phase. Due to better crystallization, dielectric constant increases to some extent. Analysis of the electrical tests and TEM data allow us to conclude that the quality of the interface between TiN substrate and BTO-Al₂O₃ stack has a primary effect on the leakage current.

Specifically, a substantial fraction of oxidized area (˜40%) of the TiN-substrate that evolves during the ALD deposition process at 350° C. Interfacial defect states formed in this area reduce the quality of the interface and prevent a decrease in leakage current. Thus, while the lower heating rate and longer RTP annealing time together improve BTO crystallization, it appears that they lead to even more oxidization of the TiN-substrate, and therefore leakage current remains unchanged.

Characterization and Electrical Testing of the BTO Films and Al₂O₃-BTO Stacks with a Seed BTO Layer on TiN-Substrates

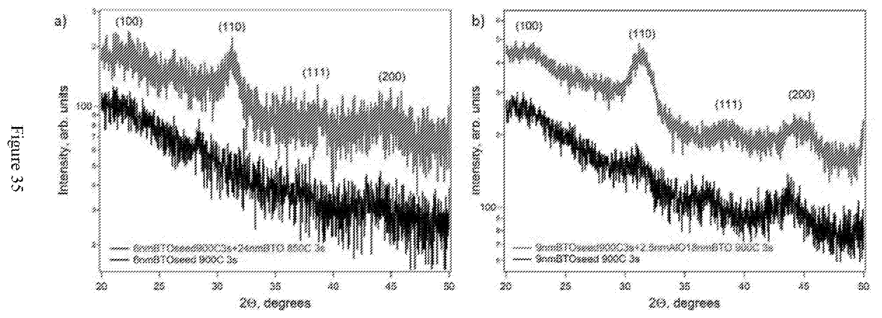

For seed layering, a thin BTO-seed layer of two thicknesses, 6 nm and 9 nm, was deposited on the TiN substrates and RTP annealed at 900° C. for 3 sec. Short annealing time and a heating rate 50° C./sec were intentionally applied to avoid the oxidation of TiN bottom electrode. While there is no sign of crystallization of a 6-nm BTO-seed layer, weak (110), (111) and (200) peaks indicate the onset of crystallization of the 9-nm thick BTO-seed layer after annealing at 900° C. for 3 sec (black scans in FIG. 35). A weak (110) peak in the XRD scan for the main 24-nm thick BTO film deposited on the top of the 6-nm seed layer demonstrates a partial formation of the BTO phase in the film after annealing at 850° C. for 3 sec (red scan in FIG. 35a).

We also deposited BTO-Al₂O₃ stacks over the annealed BTO-seed layers. Two stacking sequences for the BTO-Al₂O₃ structure were used: 1) bottom 2.5-nm Al₂O₃+top 18-nm BTO layer; 2) bottom 18-nm BTO layer+top 2.5-nm Al₂O₃ layer. All BTO-Al₂O₃ stacks were deposited by one-step process. After the deposition, the whole structure was RTP annealed at 900° C. for 3 sec in N₂ flow. The representative XRD scan (red in FIG. 35b) clearly demonstrates well defined (100), (110), (111) and (200) peaks for the stacking sequence with the Al₂O₃ layer located between bottom TiN electrode and the BTO film, indicating a well crystallized BTO phase. Interestingly, this crystallization also occurred in the film with Al₂O₃ layer located between BTO film and the top TiN electrode. This is an unexpected result, as typically XRD shows no sign of crystallization of the BTO layer with top Al₂O₃ layer.

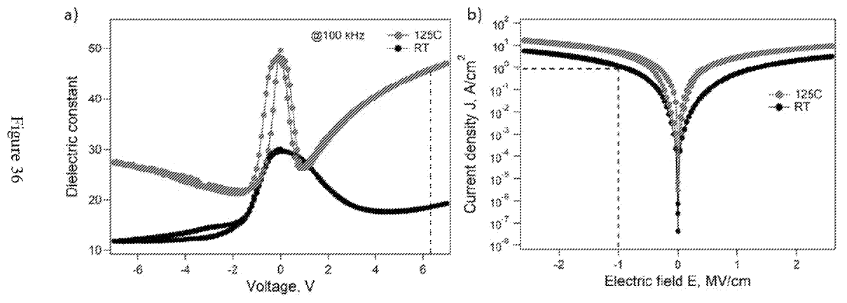

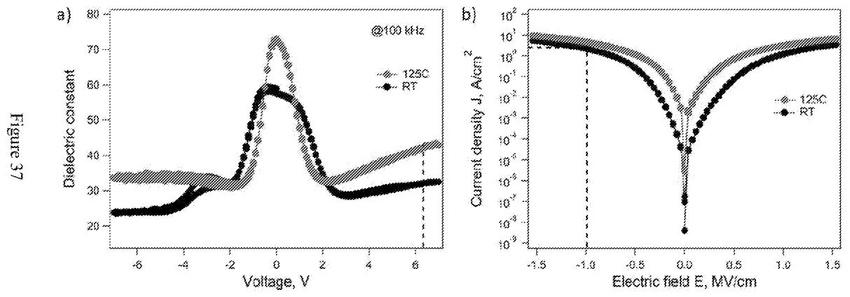

The TiN-BTO-TiN and TiN—Al₂O₃-BTO-TiN MIM-capacitors based on the films using seed layering were tested for dielectric constant and leakage current at RT and 125° C. Representative data are displayed in FIGS. 36 and 37. First, we notice that dielectric constant near E=0 is higher for the TiN—Al₂O₃-BTO-TiN MIM-capacitor (60 vs 30 at RT and 75 vs 50 at 125° C.). This results reflects better BTO crystallization for the TiN—Al₂O₃-BTO-TiN structure. The dielectric constant is almost the same for both MIM-capacitors, 43 and 47, under positive bias 6.3V at 125° C. The leakage current is excessively large.

Further Testing Results and Analysis

Additional device-to-device variation testing has been performed for two most promising MIM structures that showed good results. The characteristic parameters initially identified for both structures and correspondent specifications are summarized in Table 2 below. The results are obtained using data collected on 3 devices for each structure.

| | | Dielectric | Leakage Current |
|---|---|---|---|
| | Thickness | Constant | density |
| Annealed at 700° C., | 36 | 44 | 2.2 × 10⁻⁸ A/mm² |
| Pt—BTO—Al₂O₃—TiN | | | at RT |
| | | | 5 × 10⁻⁷ A/mm² |
| | | | at 125° C. |
| Annealed at 750° C., | 36 | 53 | 1.3 × 10⁻⁷ A/mm² |
| Pt—BTO—Al₂O₃—TiN | | | at RT |
| | | | 2.5 × 10⁻⁶ A/mm² |
| | | | at 125° C. |

We collected electrical data on a statistically significant number of MIM-capacitors, specifically on 20 and 22 devices for BTO-Al₂O₃ composite structure annealed at 700° C. and 750° C., respectively. For all MIM-structures the bottom electrode is Pt and the top electrode is TiN. These data are displayed in FIGS. 11-13. Analyzing statistical data for dielectric constant (E) and losses (tan δ) collected at 100 kHz (FIG. 11), the Average±Standard Deviation values have been determined as following: e=90±7 and e=116.6±5, (tan δ)=0.15±0.03 and (tan δ)=0.0288±0.0044 for structures annealed at 700° C. and 750° C., respectively.

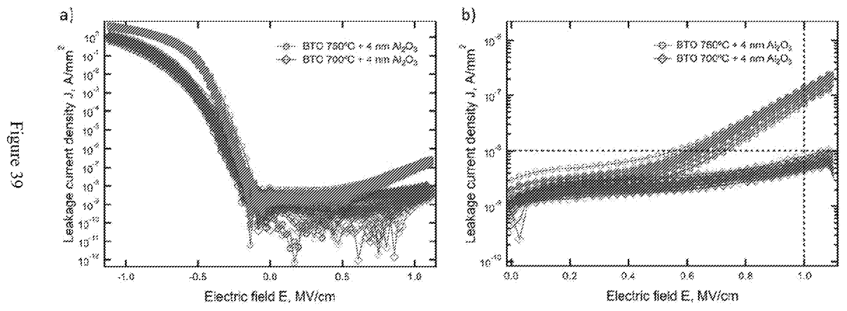

In FIG. 12 the room-temperature leakage current density as a function of process conditions for these MIM-capacitors are displayed. The different annealing conditions were: i) 700° C.+4-nm Al₂O₃ and ii) 750° C.+4-nm Al₂O₃: subsequent annealing for 10 min under N₂ flow in tube furnace, followed by the growth of 4-nm Al₂O₃. It can be clearly seen in FIG. 39a that the leakage current is asymmetric. This asymmetry most likely arises due to two-step ALD-growth, as first the BTO film was deposited and annealed and then Al₂O₃ layer was deposited. As a result, interface defects and contamination layer introduced at the film surface. However, the data for positive bias are expected to be representative for the properties of the MIM-stacks. In FIG. 39b the positive bias is shown. Analyzing statistical data for leakage current density at 1 MV/cm under positive bias (FIG. 39), the Average±Standard Deviation values have been determined to be 5.58*10⁻⁷±10-7 A/cm² and 1.07*10⁻⁵±2*10⁻⁶ A/cm² for the MIM-structures annealed at 700° C. and 750° C., respectively.

Device-to-device reproducibility was present. Specifically, dielectric constant varies at 7.7% and 4.3%, and leakage current density (at 1 MV/cm) varies at 17.9% and 18.7% for Pt-BTO-Al₂O₃—TiN MIM-capacitors annealed at 700° C. and 750° C., respectively. Significantly, even with this variation the MIM caps annealed at 700° C. yield results that are better than the 10⁻⁸ A/mm². These results are not only the best reported combination of low-leakage and high dielectric permittivity for a thin-film polycrystalline ceramic; further, variation in their properties is not unreasonable given that the data are collected on initial laboratory-scale devices.

Our results demonstrate that several factors can be important for minimizing increases in leakage that arise during annealing, including, e.g., preserving the integrity of the BTO-metal interface, and limiting annealing to a single step. We expect that leakage involving all TiN-electroded BTO-Al₂O₃ capacitors can be reduced with additional investigation beyond the limited budget and scope of the present project (e.g., dielectric stoichiometry and phase, seed layer procedure, number of annealing steps, annealing atmosphere and flow rates, time-temperature profile, number of layers and respective thicknesses).

Additional Disclosure

Atomic layer depositions of semi-amorphous Ba(OH)₂—TiO₂ laminates of ˜50 nm total film thickness on Pt(111)/Ti/SiO₂/Si(100) substrates (Gmek Inc.) were conducted in a Picosun R200 Advanced Reactor. The cation-precursors were Absolut Ba (Air Liquide, Ba(iPr₃Cp)₂), kept at 473 K, and titanium-isopropoxide (Alfa Aesar, Ti(iOPr)₄), kept at 388 K. For both of them H₂O, kept at room temperature, served as reactant. High purity N₂ gas (99.9999%) was used as carrier gas and the growth temperature was 563 K. The pulse and purge times were 1.6/6 s for Ba(iPr₃Cp)₂ and 0.1/10 s for H₂O for the Ba—O subcycle, and 0.3/1 s for Ti(iOPr)₄ and 1/3 s for H₂O for the Ti—O subcycle. An initial 12 Å thick layer of TiO₂ was deposited on all substrates to improve uniformity.

In order to vary the overall composition of the films, the repeat number for the Ba-subcycle was kept constant, while the repeat number for the Ti-subcycle was varied between 42 and 55. A sequence of 10 total repeat units of alternating subcycles, as described previously, resulted in a total film thickness of ˜50 nm.

Metal-insulator-metal (MIM) capacitors were produced by depositing ˜80 nm thick 90×90 μm² squares of Pt before or after (for one stoichiometric sample) annealing, utilizing photolithography and sputtering at room temperature. Ex-situ annealing under an over-pressure of 5 psi O₂ was conducted using the following annealing sequence: the samples were heated to 1023 K with a rate of 4 K·min⁻¹, kept at 1023 K for 12 hours, cooled to 353 K at a rate of 1 K·min⁻¹. A subsequent step with heating to 433 K (3 K·min⁻¹) followed by cooling to 373 K at a slow rate of 0.5 K·min⁻¹ was applied to ensure a slow cooling through the Curie temperature of bulk BaTiO₃ (T_{C}=396 K).

The grazing incidence X-ray diffraction (GI-XRD) scans were performed on a Rigaku Smartlab using Cu-K_{α} radiation. The lattice parameters were extracted from least squares fits utilizing the WinCSD program package.

Cross-sections of the MIM-capacitors for high resolution transmission electron microscopy (HR-TEM) were prepared in a Helios Nanolab 600i (FEI, USA) Scanning Electron Microscope (SEM)/Focused Ion Beam (FIB) dual beam system equipped with gas injectors for W and Pt deposition and an Omniprobe micromanipulator (Omniprobe, USA). After depositing a 2 μm thick protective Pt layer, milling using a 30 keV Ga⁺ ion beam resulted in a cross-section area of 5×5 μm², which was subsequently polished with 5 keV and 2 keV Ga⁺ ion beams, respectively. These MIM-cross sections were investigated utilizing a Titan 80-300 operated at 300 kV, which is equipped with a high-angle annular dark-field (HAADF) detector (Fischione, USA), a spherical aberration (Cₛ) probe corrector and a post-column Gatan image filter (GIF). Digital Micrograph (Gatan, USA) and Tecnai Imaging and Analysis (FEI, USA) software were used for the image processing.

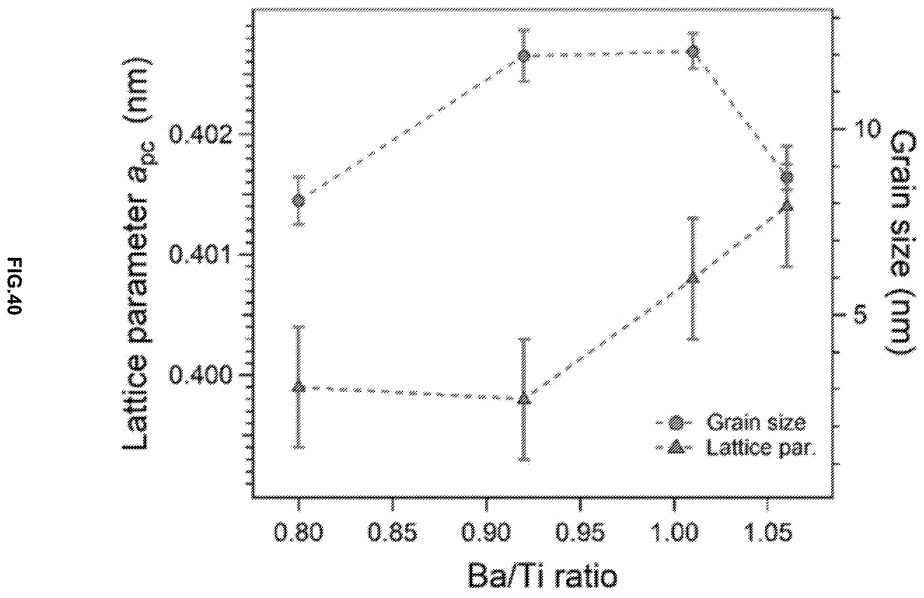

X-ray photoelectron spectroscopy (XPS) measurements were conducted using a Physical Electronics VersaProbe 5000 under a base-pressure of ˜10⁻⁶ Pa. An Al-Kα source provided incident photons with an energy of 1486.6 eV at 10 kW mm⁻². The XPS spectra were collected with the pass energy of 23 eV. An electron neutralizer was used to neutralize the surface. Linear energy correction was applied in reference to the carbon spectra. The energy of the C1s peak of non-oxidized carbon was set at 284.8 eV. The detector was placed at the angle of 87.2° relative to the surface in order to collect the XPS signal from a larger volume of the films. For MIM-capacitors, TiN top electrodes of 45 nm thickness, a resistivity of 300-400 μΩcm, and an area of 90×90 μm2 were deposited at a power of 450 W utilizing a standard photolithography process and sputtering at room temperature for the 30 nm thick NP/BTO films and NP/BTO-Al₂O₃ bi-layer structures of stacking sequence shown in FIG. 40, grown on Pt(111)/Ti/SiO2/Si(100) substrates after annealing

The electrical properties of the MIM-capacitors were measured in a probe station (Lakeshore Cryotronics TTP4) utilizing a Keithley SCS-4200 electrometer for collecting frequency dependences (10 kHz-1 MHz) of capacitance & loss tangent and a Precision Tester (Radiant Technologies, Inc.) for collecting polarization hysteresis loops. The measurements were performed in air at room temperature and under vacuum of ˜10⁻⁵ Torr over a temperature range of 190-420 K, on cooling and heating, at a constant rate of 5 K min⁻¹.

Raman spectra were collected in backscattering configuration z(x, x+y)z̅ using a single monochromator (XploRA, Horiba Jobin-Yvon, Edison, N.J.) and a laser (4 mW, λ=532 nm) focused to a spot diameter of ≈10 μm at an intensity of 1.6×10³ W cm⁻². Light was dispersed using a 2400 gr mm⁻¹ grating and collected using a Peltier-cooled array detector. The sample temperature was varied from 123 K to 473 K (Linkham THMS 600, instrumental precision±0.1 K) in increments of 5 K at a heating ramp rate of 5 K min⁻¹. The sample is also allowed to equilibrate for 1 min between consecutive Raman scans.

Material characterization

Four BTO thin films with varying Ba/Ti ratio were grown by ALD and were characterized by XRD, RBS, TEM, XPS, and Raman scattering techniques. Details on the structural characteristics of the samples are provided elsewhere.

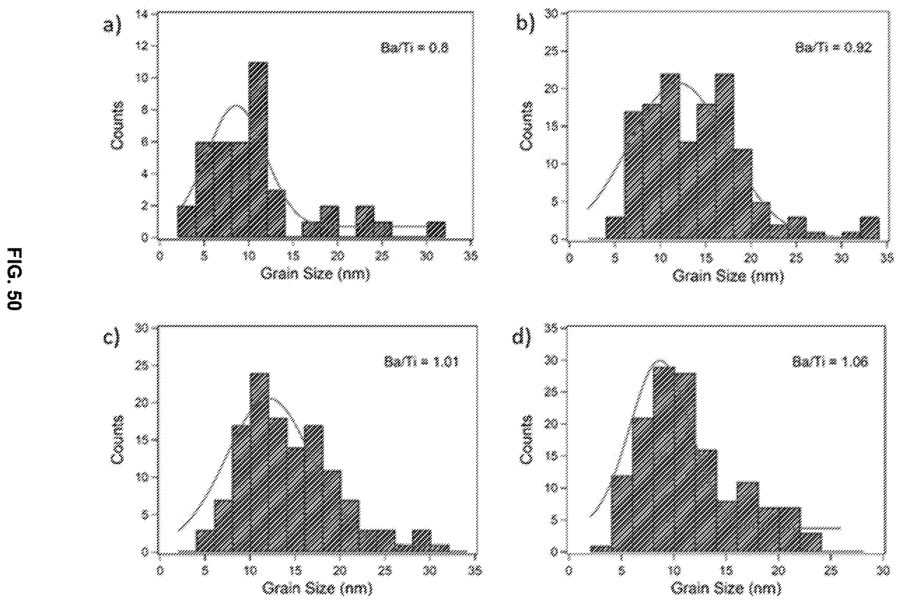

Room-temperature X-ray diffraction scans, collected after the annealing step reveal the presence of polycrystalline BTO in the perovskite structure for all samples and, independent of the composition, no additional peaks are detected. The GI-XRD patterns point towards a cubic symmetry or a marginal tetragonal distortion. However, Raman spectra clearly show the tetragonal symmetry for the perovskite in coexistence with the hexagonal BTO polymorph within all thin film samples. The Ba/Ti-ratio values have been determined using RBS measurements. The details of the RBS analysis are provided elsewhere. FIG. 40 shows the lattice parameters, which were extracted from least squares fits to the cubic perovskite structure (SG: Pm3̅m). A lattice expansion of 0.2% with increasing Ba/Ti-ratio is observed. The mean values and standard deviations of crystallite sizes determined from the Gaussian fittings (FIG. 50) of the distribution of sizes obtained from TEM images are also depicted in FIG. 40. Detailed TEM investigations have been performed for all films, which had top Pt electrodes deposited before the annealing procedure. The results of this study (see Ref 42 for details) imply that an extended metastable solubility range exists for the perovskite-phase on both sides of the stoichiometric composition. The absence of any additional secondary phases besides the hexagonal polymorph, together with the lack of cation segregation at the grain boundaries and film-substrate interfaces confirm that the off-stoichiometry is accommodated within the BTO crystallites. Moreover, the independence of the ratio of hexagonal to perovskite polymorph to the Ba/Ti-ratio and the systematic change of the lattice parameter indicate that cation defects are located in the perovskite phase.

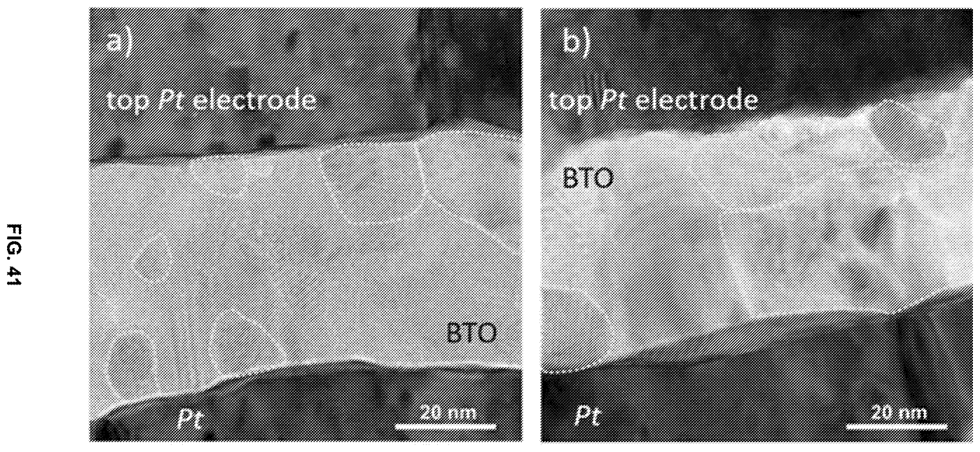

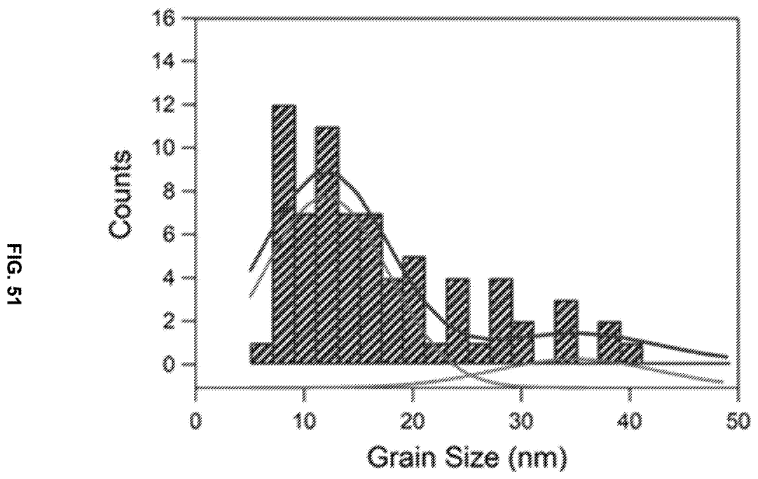

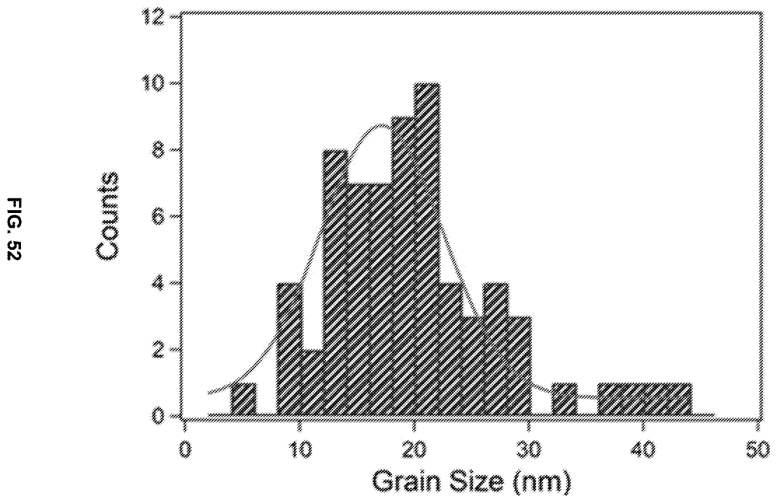

In the present work, we additionally investigated a stoichiometric (Ba/Ti=1.01) sample by TEM, where the top electrodes were deposited after the annealing process. A cross section of the MIM-capacitor was examined between the top and bottom Pt electrodes to unravel the influence of the presence/absence of a top electrode during the annealing process on the crystallite size and resulting physical properties. FIG. 41 shows representative BF-TEM images for two stoichiometric (Ba/Ti=1.01) samples, one with top electrodes deposited before annealing (FIG. 41a) and the other one with top electrodes deposited after annealing (FIG. 41b). The distribution of crystallite sizes obtained from the TEM images for each sample and their fitting are presented in FIGS. 50 and 51, respectively. As expected, the comparative analysis indicates that the crystallite growth is suppressed by the presence of a top electrode during the annealing process. While the distribution of crystallite sizes is fitted by one Gaussian function with a mean value of 12.1 nm for sample with electrodes before annealing, the size distribution is fitted by two Gaussians, with the mean values of 12.0 and 35.0 nm sizes for sample with electrodes after annealing. In addition, the cross section between the free area (no top electrodes) and bottom electrode obtained for a stoichiometric sample was also analysed. The distribution of grain sizes obtained from TEM images of this cross section and the fitting are presented in FIG. 52. For this case, the main value of crystallite size is 17.1 nm. Below is described how the difference in crystallite size affects the ferroelectric phase transition.

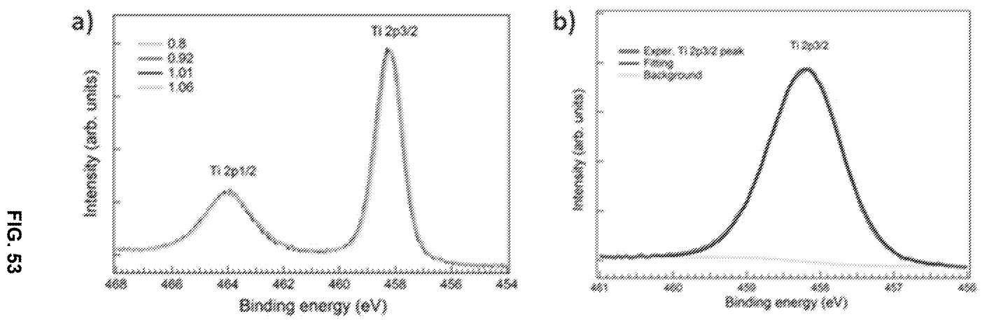

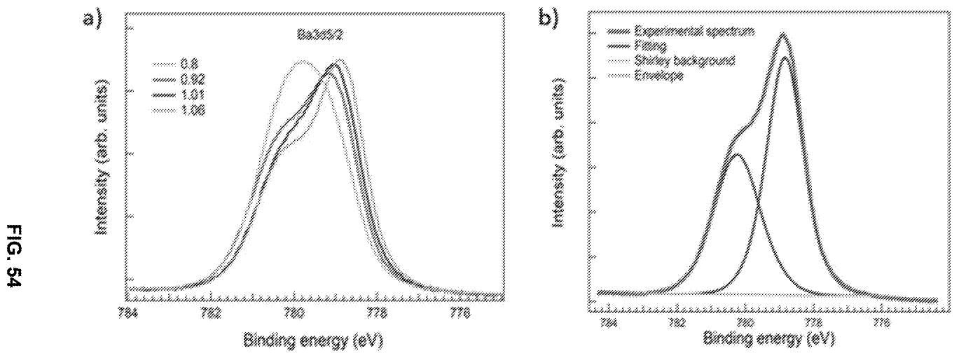

The valence states of Ti and Ba and their possible change with compositional variation have been probed by XPS. The Ti and Ba spectra and their fitting are presented in the Supporting Information. FIG. 53 unambiguously demonstrates that Ti in the oxidation state 4+ is present in all films independent of composition. The XPS Ba spectra collected for the films with various Ba/Ti ratios, displayed in FIG. 54, show that the Ba3d5/2 peak contains two lines, corresponding to the Ba²⁺ ions located in deeper layers of the films and on the surface with a shift to higher energy.

The intensity of the line originating from the Ba²⁺ ions from the bulk of the films monotonically increases, while the intensity of the line corresponding to the Ba²⁺ on the surface systematically decreases with increasing Ba/Ti ratio. Independent of the composition, no recharging effects of the cations is observed.

Dielectric study

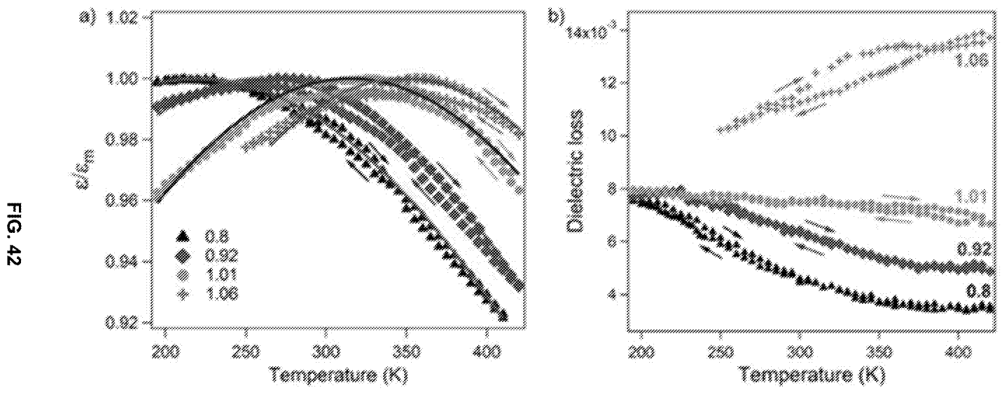

Frequency dependences (from 10 kHz to 1 MHz) of the capacitance and loss tangent were collected within temperature intervals of 190 K<T<420 K for the films with Ba/Ti ratios of 0.8, 0.92 and 1.01, and between 250 K and 420 K for the film with a Ba/Ti ratio of 1.06. First, the samples were cooled down from room temperature to 190 K/250 K, followed by heating up to 420 K and a subsequent cooling to room temperature. A negligible frequency dependence of the permittivity and loss tangent was observed within the investigated temperature intervals for all samples. Representative temperature dependent data obtained at 100 kHz for four samples with the top Pt electrodes deposited before the annealing procedure are depicted in FIG. 42. In all cases, the dielectric constant is normalized to its maximum value eₘ. The absolute maxima of the dielectric constant and temperature extracted from the cooling and heating cycle are summarized in Table 1. As displayed in FIG. 42a, the samples exhibit a broad non-monotonic dependence with hysteretic behaviour. The maximum permittivity shifts from 212 K to 350 K for cooling and from 230 K to 355 K for heating as the Ba/Ti ratio increases from 0.8 to 1.06, respectively. The temperature dependence of the dielectric loss (tan δ) reveals a distinctly different behaviour for each composition (FIG. 42b).

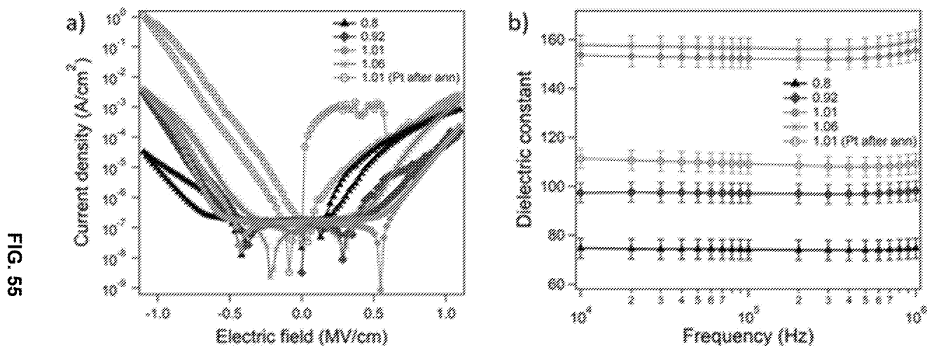

While a broad, but at the same time, rather pronounced maximum around 200 K for a Ba/Ti ratio of 0.8 is present, this maximum becomes smoother with increasing Ba-content and practically vanishes at the stoichiometric composition. However, in the Ba-rich sample the scenario is vastly different as the loss tangent not only increases with temperature, but is in general higher than for all other samples. This behaviour might indicate (without being bound to any particular theory) the segregation of space charges at grain boundaries. Considering the formation of Schottky defects as the main source for off-stoichiometry, the amount of oxygen vacancies is higher in Ba-rich than in Ti-rich sample (see equations (2) and (3) below), so space charges might form more readily in this case. To further consider the influence of the leakage current on the temperature behavior of losses, we provide the electric field dependences of current density (J-E) for the films with different Ba/Ti-ratio. The dependences depicted in FIG. 55a demonstrate that the films with different stoichiometry are basically identical in their J-E response, so there is no correlation between the J-E behavior and features in FIG. 42b for the film with Ba/Ti=1.06.

The maximum in EM is indicative of a phase transition in ferroelectric materials. The total shift of the peak temperature Tₘ over the studied frequency range cannot be clearly determined because of its broad occurrence. Nevertheless, it is worth mentioning that the weak frequency dispersion of Tₘ should still be present due to the diffuse type of the transition as described below. Since ε(T) exhibits thermal hysteresis, a first-order ferroelectric phase transition should be present, which is similar to bulk BTO. A progressive reduction of the hysteresis with increasing Ba/Ti ratio is observed. The hysteresis exhibits the largest value of 18 K for the most Ti-rich sample (Ba/Ti=0.8), continuously decreases to 10 K for the nearly stoichiometric sample (Ba/Ti=1.01) and ultimately shrinks to 5 K for the most Ba-rich sample. Compared to the single-crystal counterparts and larger grain ceramic specimens with stoichiometric composition, the transition temperature drops dramatically. This decrease of T_{C} may relate to the reduced crystallite sizes, as analogous shifts in the ferroelectric transition temperature were observed in a number of ceramic and thin film samples: e. g., the T_{C} was registered at 379 K for 50-nm and 30-nm ceramic samples and at 333 K for grain sizes of 22 nm. In analogy, the decrease of the Curie temperature was reported for polycrystalline BTO films as a function of the film thickness and grain size.

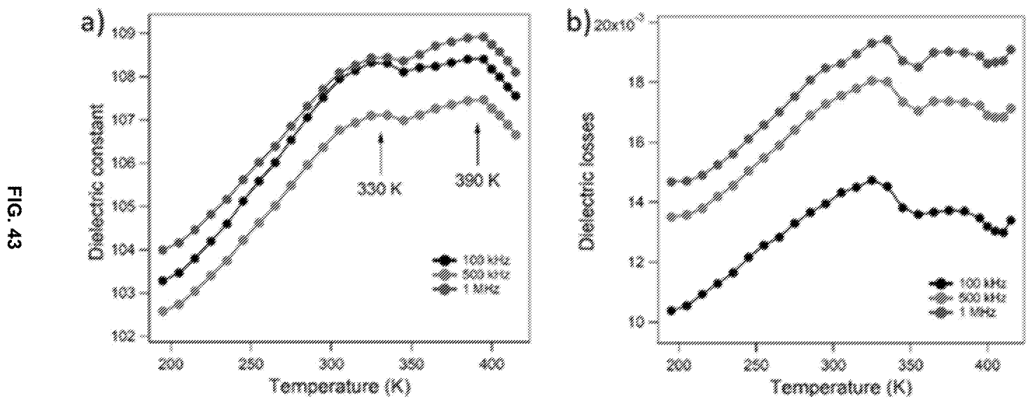

To probe how the crystallite size affects the temperature behaviour of dielectric parameters for the present thin films, and thereby disentangle the size effect from a compositional effect, we also investigated the stoichiometric (Ba/Ti=1.01) sample with the top electrodes deposited after the annealing step. In this case, the crystallites underneath the top electrodes are larger and the distribution of grain sizes is different from the sample, in which the top electrodes were deposited before the annealing procedure (see FIGS. 50c and 51). This difference clearly shows that an additional layer on top of the thin film effectively reduces the grain growth compared to an unconfined film surface. FIG. 43 reveals the presence of two peaks in in ε(T) and tan δ(T) dependences for the MIM-capacitor with the top electrodes deposited after the annealing step. The first peak is observed around Tₘ=330 K and the second one at Tₘ=390 K. The dependences can be considered as frequency independent, although they exhibit a very broad transition region and, therefore, a diffuse type phase transition. A comparison between the grain size distributions for the samples with top electrodes before and after annealing allows us to attribute these maxima to the phase transitions for crystallites of two groups, with smaller (average 12 nm) and bigger (average 35 nm) sizes.

The bigger grains are also clearly visible in the TEM image displayed in FIG. 41b and the wide grain size distribution results in the very broad phase transition region displayed in FIG. 43. It should be noted that the peak at higher temperature (Tₘ=390 K) is very close to the Curie temperature for bulk samples (T_{C}=396 K), and the peak at lower temperature (Tₘ=330 K) can be associated with a decreased T_{C} due to the crystallite size reduction and is very close to Tₘ=315-325 K for the sample with top electrodes deposited before the annealing step. This comparison allows us to independently discern the crystallite size effect and hereby confirm that the change of the transition temperature observed for the samples with different Ba/Ti ratio (see FIG. 42a and Table 1) is predominantly caused by the different compositions. Thus, we reveal a shift in the transition temperature of ΔT=138 K due to the variation in the cation ratio from 0.8 to 1.06.

Taking into account similar fabrication conditions, film thicknesses, and grain sizes (see FIG. 40) for all four samples, it may be that the deviation of the transition temperature is correlated to the variation of stoichiometry. Such an increase of the Curie point, ΔT=120 K, due to variation of the Li/Nb ratio from 0.96 to 1.04, has been observed earlier in LiNbO₃ crystals.⁴⁸ A smaller increase of T_{C}, about 10 K, due to variation of Ba/Ti ratio from 0.99 to 0.999 has been demonstrated in ceramic BTO samples. Compared to BST ceramics, this large shift in Curie temperature corresponds to a change in the Ba/Sr-ratio of more than 50%. Before discussing which microscopic mechanisms could provoke this effect, below is discussed the behaviour of the dielectric constant.

TABLE 1
Maximum temperature, Tₘ, and dielectric constant, εₘ,
extracted from experimental temperature dependence
for the four films with top electrodes deposited
before annealing. Parameters Δ and ξ from
least square fits to equation (1)

| | Tₘ on | | | |
|---|---|---|---|---|
| Ba/Ti ratio | cooling/heating (K) | εₘ on cooling/heating | Δ (K) | ξ |
| 0.8 | 212/230 | 84.6/84.6 | 650 ± 6 | 2 |
| 0.92 | 258/275 | 110.7/110.9 | 593 ± 5 | 2 |
| 1.01 | 315/325 | 168.6/169.3 | 588 ± 6 | 2 |
| 1.06 | 350/355 | 163/163.8 | 565 ± 10 | 2 |

The decrease of T_{C} because of grain size reduction is typically accompanied by the broadening of the maximum and decreasing of the dielectric constant. Table 1 shows how the maximum dielectric constant, εₘ, changes with composition variation. The room temperature dielectric constant as a function of frequency for the films with Ba/Ti=0.8, 0.92, 1.01 and for the film with Ba/Ti=1.01 with top electrodes after annealing is depicted in FIG. 55b. The room temperature dielectric constant depends on stoichiometry, especially on the Ti-rich side. It is reduced by 50% in the Ti-rich samples compared to the stoichiometric one, but remains almost unchanged upon further increasing the Ba/Ti ratio. In the present work, the same trend is observed for εₘ from the temperature dependence of the dielectric constant. As noted above, the phase transition in fine grained samples is very broad and is therefore coined a diffuse phase transition (DPT). A simple and explicit model qualitatively and quantitatively describing the temperature dependence of the dielectric permittivity at the DPT was suggested:

$$ɛ = \frac{{ɛ}_{m}}{1 + {( ( T - {T}_{m} ) / Δ )}^{ξ}} \qquad ( 1 )$$

where Δ and ξ are empirical parameters related to the transition diffuseness and to the character of the phase transition, respectively. The parameter ξ is the peak broadening that indicates the degree of diffuseness. The parameter ξ can take values between 1 for a typical ferroelectric behaviour and 2 for the so-called “complete” DPT. The solid curves depicted in FIG. 42a are fitting results to equation 1. All data are best fitted with a parameter ξ=2 and the parameters Δ shown in Table 1. A slight, gradual decrease of the diffuseness degree with increasing Ba/Ti ratio is seen.

Due to the wide distribution of grain sizes, there is a range for the T_{C} in a DPT, so the peak temperature Tₘ can be regarded as an average T_{C} (correlated to the average grain size). Keeping this in mind, we use the term phase transition temperature for the peak temperature.

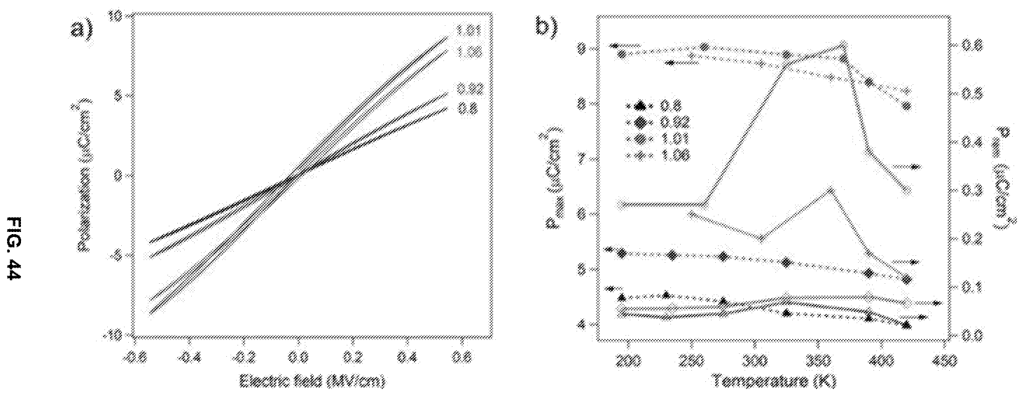

Accounting average grain sizes of 8-12 nm in all compositions (see FIG. 40), we approach the ferroelectricity limit. Indeed, FIG. 44a shows an extremely narrow hysteresis loop collected at 300 K at 500 Hz. We observe here that the polarization changes as a function of Ba/Ti ratio in a similar manner as the dielectric constant (see Table 1). The values of both, maximum polarization Pₘₐₓ (at E=0.545 MV/cm) and remnant polarization Pᵣₑₘ drop by almost 50% for the Ti-rich samples and only slightly decrease in the Ba-rich sample compared to the stoichiometric one. FIG. 44b presents the temperature behaviour (heating cycle) of the values of maximum and remnant polarization as a function of Ba/Ti ratio.

While Pₘₐₓ remains almost unchanged over the phase transition region for all compositions, Pᵣₑₘ exhibits a non-monotonic behaviour with a weak and wide hillock around Tₘ for the Ti-rich films (Ba/Ti=0.8, 0.92) and with more pronounced and narrower maxima for the stoichiometric and the Ba-rich (Ba/Ti=1.06) samples. Considering practically similar grain sizes for all compositions, such a difference indicates that the latter two films contain more crystallites with stable domains or domain structure, which contribute to the polarization in zero electric field. These crystallites are likely more strained and therefore should have a higher ratio of tetragonality (c/a) or lower symmetry.

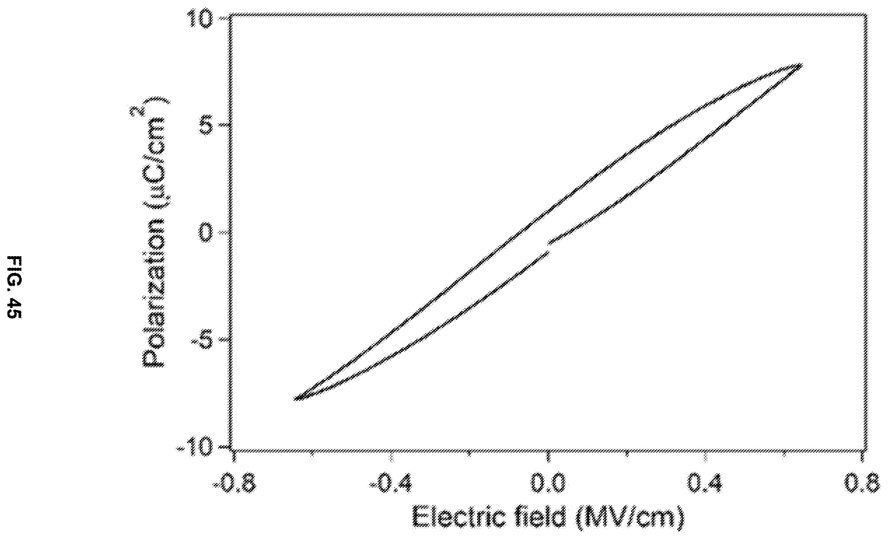

Furthermore, the remnant polarization, although approaching zero at elevated temperature, does not vanish above Tₘ for these two samples, implying that there are residual strains in the vicinity of the DPT on the high-temperature side that preserve the polarization within the grains. For Ti-rich samples, the remnant polarization remains almost zero over the entire temperature region. Therefore, the samples are expected to have more strain relaxed crystallites with minor or no distortion from cubic symmetry (c/a→1). The room-temperature hysteresis loop for the stoichiometric sample with top electrodes deposited after the annealing step is displayed in FIG. 45. While the maximum polarization for this film is similar, the remnant polarization is enhanced by a factor of 3 compared with the same sample with top electrodes deposited before annealing (FIG. 44). This difference most certainly arises from the presence of larger crystallites within this thin film.

We show the J-E response for the stoichiometric film (Ba/Ti=1.01) with top Pt electrodes deposited after the annealing step in FIG. 55a in the revised SI. This figure indicates that leakage current for this film is higher than that for the stoichiometric film with top Pt electrodes deposited before annealing.

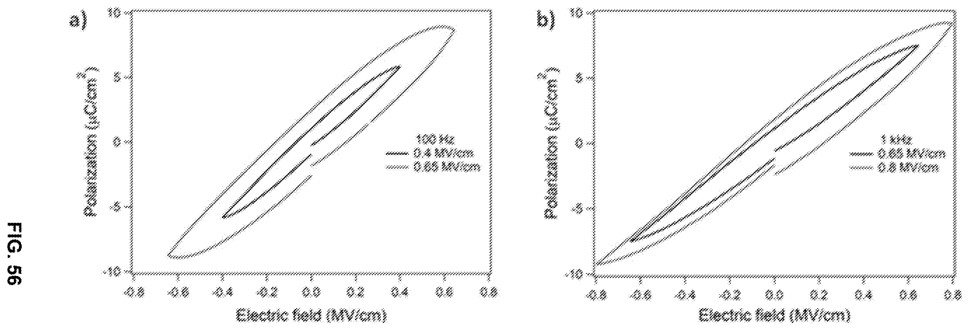

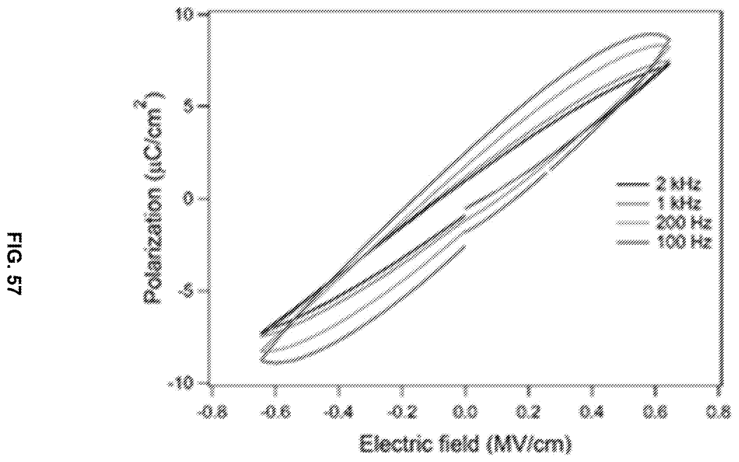

However, the difference between FIGS. 44 and 45 is not explained by the influence of leakage current. We provide the hysteresis loops collected at different electric fields and different frequencies depicted in FIGS. 56 and 57 and show that in the hysteresis loop presented in FIG. 45 is measured at optimal conditions when the influence of the leakage current is almost negligible. FIGS. 56 and 57 represent room temperature hysteresis loops collected for the stoichiometric (Ba/Ti=1.01) film with Pt electrodes deposited after the annealing step. The hysteresis loops were measured at different maximum electric fields and different measuring frequencies. The hysteresis loop measured at a maximum electric field of 0.65 MV/cm and a frequency of 1 kHz exhibits a maximum polarization of 7.5 μC/cm2, while the influence of the leakage current is negligible there. This representative hysteresis loop is shown in FIG. 45.

From a microscopic point of view, the shift of the ferroelectric transition temperature in BTO is a strain/stress mediated phenomenon for any kind of effect (including any interfacial and gradient effects). Contrary to epitaxial films, the strain due to the lattice mismatch between substrate and film has a negligible influence on the structure of polycrystalline BTO films. As TEM images show (see FIG. 41), the crystallites within all films are randomly oriented, so no preferential alignment occurs. This fact is further corroborated by XRD data that show the polycrystalline nature of all thin films. Moreover, as the growth and annealing conditions were kept identical for all samples, we assume that the strain induced by the thermal expansion mismatch between substrate and film is equivalent for all films. With respect to the compositional gradient effect, we refer again to the microstructure analysis and further note that no cation segregation at the grain boundaries is observed from TEM. Therefore, we focus on the impact of the composition hereafter.

For compositional effects within the lattice the strain arises from the defects formed during the crystallization of BTO, so called Vegard strain (or chemical pressure).

In off-stoichiometric BTO the following types of partial Schottky defects are typically considered

$$\begin{matrix}\text{Ti-rich side:} {TiO}_{2} {⇒}^{{BaTiO}_{3}} {Ti}_{Ti}^{X} + 2 {O}_{O}^{X} + {V}_{Ba}^{″} + {V}_{o}^{••} & ( 2 ) \\ \text{Ba-rich side:} BaO {⇒}^{{BaTiO}_{3}} {Ba}_{Ba}^{X} + {O}_{O}^{X} + {V}_{Ba}^{″″} + 2 {V}_{o}^{••} & ( 3 )\end{matrix}$$

Now we estimate the strain due to the presence of partial Schottky defects, with respect to stoichiometric deviations in the chemical formula. For this purpose, we use the results of calculations made by Freedman et al. for strontium titanate (STO).⁵² Since BTO is very similar to STO in terms of chemical bonding, the perovskite crystal structure, and lattice parameters, the estimation of the chemical strain in BTO using these results seems appropriate. The local strains imposed by different defects such as oxygen vacancies (V_{O}), strontium vacancies (V_{Sr}), titanium vacancies (V_{Ti}), strontium-oxygen divacancies (V_{Sr}-V_{O}), and titanium-oxygen divacancies (V_{Ti}-V_{O}) determined in the literature are provided in Table 2. Here, ε_{c} is the chemical strain (Δa/a), and δ denotes the deviation from stoichiometry that specifies the number of defects per chemical unit. Positive Vegard strain results in lattice expansion, and negative Vegard strain in lattice contraction.

TABLE 2
The ratio of the chemical strain to stoichiometric defect
deviation δ for Sr₁TiO_{3-δ}, Sr_{1-δ}TiO₃, SrTi_{1-δ}O₃,
Sr_{1-δ}TiO_{3-δ}, and SrTi_{1-δ}O_{3-δ} (D. A. Freedman,
D. Roundy and T. A. Arias, Phys. Rev. B, 2009, 80, 064108.)

| | V_{O} | V_{Sr} | v_{Ti} | V_{Sr}-V_{O} | V_{Ti}-V_{O} |
|---|---|---|---|---|---|
| ε_{c}/δ | +0.001 | +0.030 | +0.402 | −0.008 | +0.260 |

Our Ti-rich samples can be treated as Ba_{1-δ}TiO_{3-δ}, while Ba-rich samples as BaTi_{1-δ}O_{3-2δ} in accordance with equations (2) and (3), respectively. First we estimate the contribution of the partial Schottky defects to the strain. For this, we calculated the strain ε_{c} which should be created if a) only isolated vacancies are introduced, and b) if only divacancies (and additional V_{O} for Ti-deficient films to maintain charge balance) are introduced. For the stoichiometric composition (δ=0) we assume an unstrained state (ε_{c}=0).

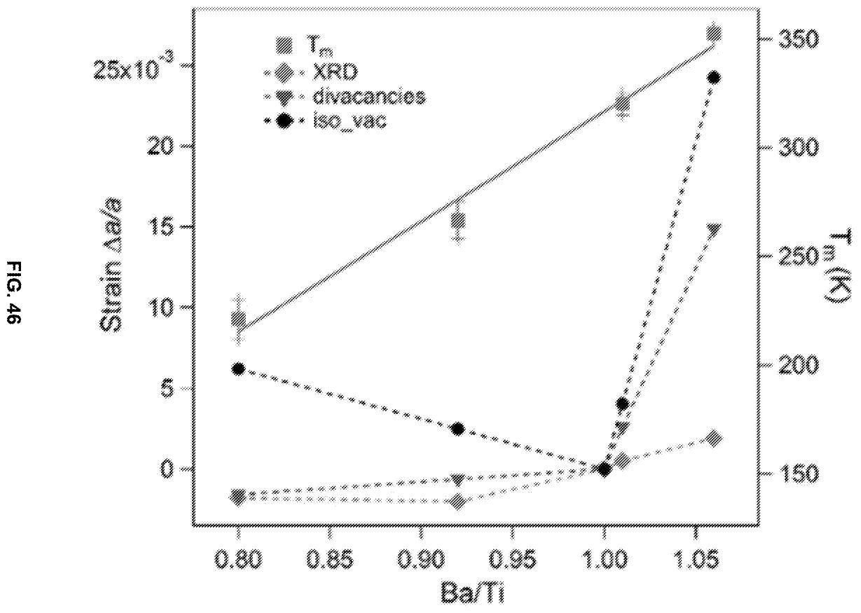

The calculated strain versus Ba/Ti ratio is displayed in FIG. 46. The strain determined using the lattice parameters from XRD data (see FIG. 40) is also depicted in FIG. 46. A pseudo-cubic lattice parameter for stoichiometric BTO, a_{pc}=4.007 Å (this is an average value for the tetragonal structure, where a=3.992 Å and c=4.036 Å) was used. In addition, the variation of the phase transition temperature (bars indicate the Tₘ values on cooling and heating taken from Table 1) as a function of the Ba/Ti ratio is presented in FIG. 46. The dependence for Tₘ follows a linear relation as indicated by a least-squares fit.

Comparison of the estimated values of the strain with experimental values allows us to conclude that the strain produced by divacancies exhibits a similar trend as the experimentally observed strain with negative strain on the Ti-rich side and positive strain on the Ba-rich side. However, the strain obtained using lattice parameters from XRD is smaller than the theoretically predicted strain arising from partial Schottky defects. For possible sources of strain relaxation, the following contributions could be considered: with respect to the internal stress at the grain boundaries, different mechanisms of its evolution were suggested, and there is not a consensus so far. Although many calculations show that the driving force for the internal tensile stress is surface energy reduction due to grain boundary formation, the measured value of this stress is much lower than that attributed to compressive stress due to insertion of additional atoms into the grain boundaries as a way to relax the tensile stress in the film.

We do not observe any segregation of cations at the boundaries from TEM, and therefore one can (without being bound to any particular theory) assume that quite high internal tensile stress is present in our samples. This suggestion is supported by the fact, that several polymorphs (cubic, tetragonal and hexagonal) are formed for all compositions due to the non-equilibrium state. This internal stress at the grain boundaries could facilitate the relaxation of the strain due to partial Schottky defects located inside crystallites. Regarding the second possible source, we observe compositional inhomogeneity from elemental mapping in TEM cross sections. This spatial off-stoichiometry likely occurs in order to lower the total energy and therefore might also relax the local strain induced by Schottky defects.

Raman Scattering Study

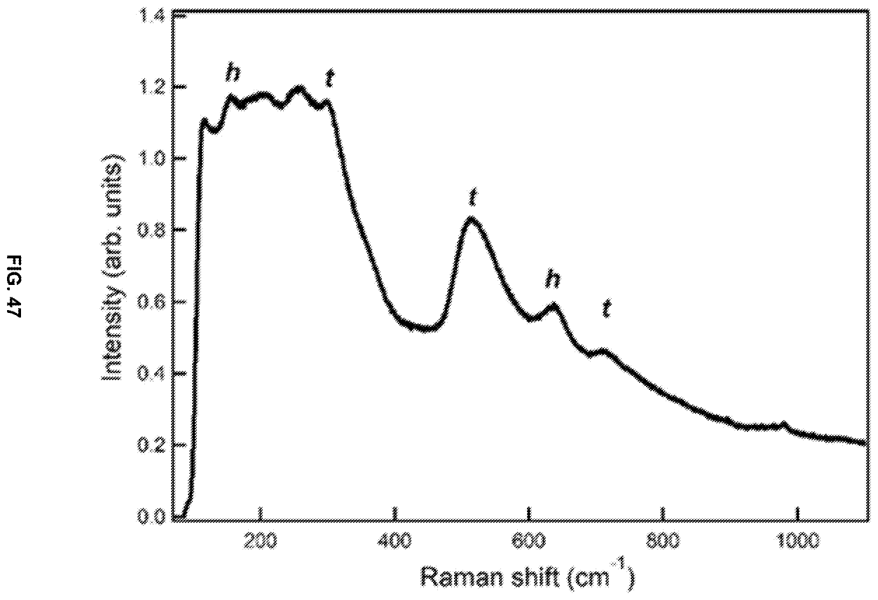

To complement the dielectric study, we conducted a detailed analysis of the Raman spectra collected in the temperature range from 123 K to 473 K (heating cycle) for the two thin films with lowest and highest Ba/Ti-ratio, 0.8 and 1.06, respectively. All spectra were collected in areas of the film surface between the top Pt electrodes. It should be mentioned that the Raman spectra for samples with top electrodes deposited before and after annealing are similar, which means that the microstructure between the top electrodes is basically identical independent of the top electrodes deposition procedure. FIG. 47 shows the room-temperature spectrum collected for the stoichiometric (Ba/Ti=1.01) sample which has top electrodes deposited before annealing. The spectrum demonstrates the presence of tetragonal (t-BTO) and hexagonal (h-BTO) polymorphs and is representative for all thin films used in this study. No peaks from impurity phases are visible. Note that a polymorphous mixture is frequently observed for polycrystalline BTO thin films and was also reported for nanoparticles with a size of 40 nm.

The temperature dependent Raman spectra collected for the samples with Ba/Ti-ratios of 0.8 and 1.06 qualitatively look similar to the room-temperature spectra displayed in FIG. 47. The wide band in the wavenumber range of 150-300 cm⁻¹ contains several overlapped modes including the ˜180 cm⁻¹ peak assigned to the E_{2g} mode of h-BTO⁵⁸ and the ˜280 cm⁻¹ peak assigned to the A₁(TO₂) mode of t-BTO. However, each of these peaks is not well isolated and has contributions of a few modes. Therefore, it is impossible to use these peaks for a meaningful analysis.

The 520 cm⁻¹ peak primarily represents the A₁(TO₃) component of the A₁(TO) spectrum of t-BTO. As was shown recently, the frequency of the 520 cm⁻¹ mode of t-BTO gradually decreases and its width broadens until the mode almost disappears above the ferroelectric transition in a polycrystalline BTO thin film. For the hexagonal polymorph a very prominent ˜620 cm⁻¹ peak is assigned to the A_{1g} mode. As seen in FIG. 47, the Raman spectra also contain a ˜720 cm⁻¹ peak, which represents the A₁(LO₃) mode of t-BTO. This peak is broad and has a low intensity. Moreover, its frequency remains practically constant throughout the tetragonal phase. According to different studies, the soft mode in the perovskite BTO has two components: a doubly degenerate overdamped component E(TO₁), the frequency of which varies within 35±5 cm⁻¹, and the half-width is 85-115 cm⁻¹ and the totally symmetric component A₁(TO₂) at a frequency of 280-308 cm⁻¹. While the overdamped component E(TO₁) condenses very fast and becomes invisible approaching the ferroelectric phase transition, the frequency of the A₁(TO₂) component remains almost unchanged with temperature in polycrystalline thin films.

In our Raman spectra, the situation is more complicated due to the presence of a polymorphous mixture in all samples. When a soft mode is overdamped or even unavailable in a material with structural disorder, it is appropriate to obtain information about the phase transformation by monitoring the temperature behaviour of the spectroscopic parameters of other modes, which are sensitive to the symmetry of the structure. Considering all these factors, we based the analysis on separately evaluating the temperature behaviour of the frequency, integrated intensity, and FWHM (full width at half maximum) for the 520 cm⁻¹ (t-BTO) and 620 cm⁻¹ (h-BTO) peaks. Bose-Einstein correction has been performed prior to the data analysis of structural phase transitions; in addition, fitting with a Lorentzian lineshape has been applied following the methodology described in detail previously.

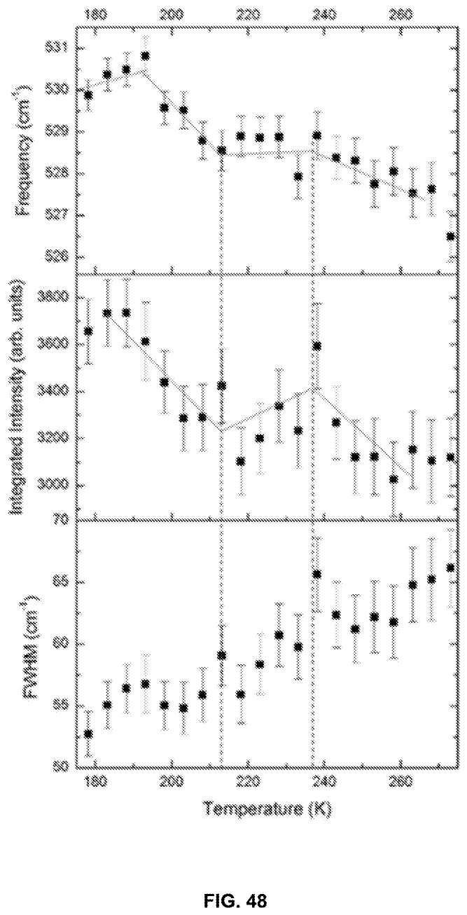

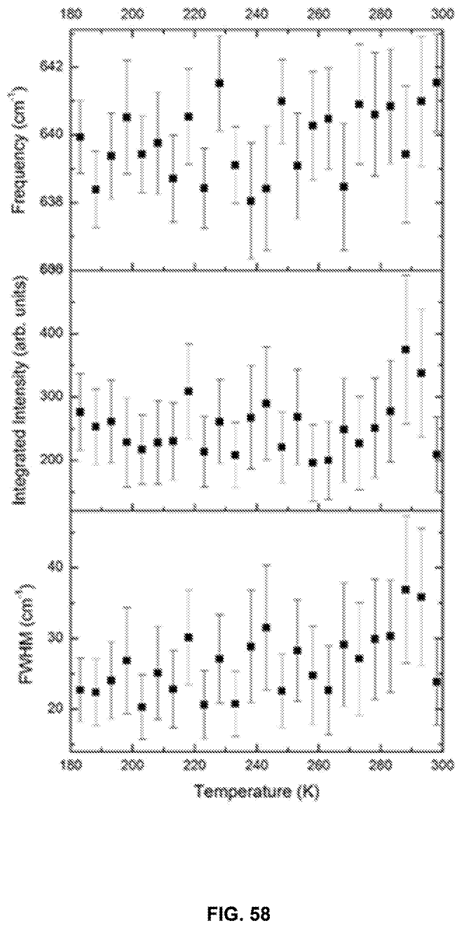

FIG. 48 shows the temperature dependences of the spectroscopic parameters of the 520 cm⁻¹ peak for the Ti-rich sample (Ba/Ti=0.8). As demonstrated, the frequency of the 520 cm⁻¹ peak decreases non-monotonically from 532 cm⁻¹ to 526 cm⁻¹ as the temperature increases from 100 K to 320 K. The reduction rate sharply changes at ˜212 K. Starting from this point, the frequency remains unchanged until ˜230 K and continues to gradually decrease above 230 K. The integrated intensity displays an anomaly in the same temperature range, while the FWHM consistently increases over the entire temperature interval. All the features occur in the same temperature interval as the phase transition observed in dielectric measurements for this film. The temperature behaviour of the 620 cm⁻¹ peak is not so distinct (see FIG. 58). Its frequency continuously increases and a slight change in the slope can be noticed in the interval from 212 K to 230 K. Other parameters, i.e. the width and integrated intensity, change marginally and monotonically, with no specific features detectable between 212 K and 230 K. Based on this analysis, one can conclude that the phase transition around 212-230 K revealed in the dielectric study is fully attributed to the structural transformation of the perovskite phase from tetragonal to cubic with increasing temperature, although the symmetry change marginally influences the dynamics of the h-BTO phase. Moreover, the extended temperature interval for this specific behaviour of the spectroscopic parameters for the 520 cm⁻¹ mode, confirms the diffuseness of the phase transition.

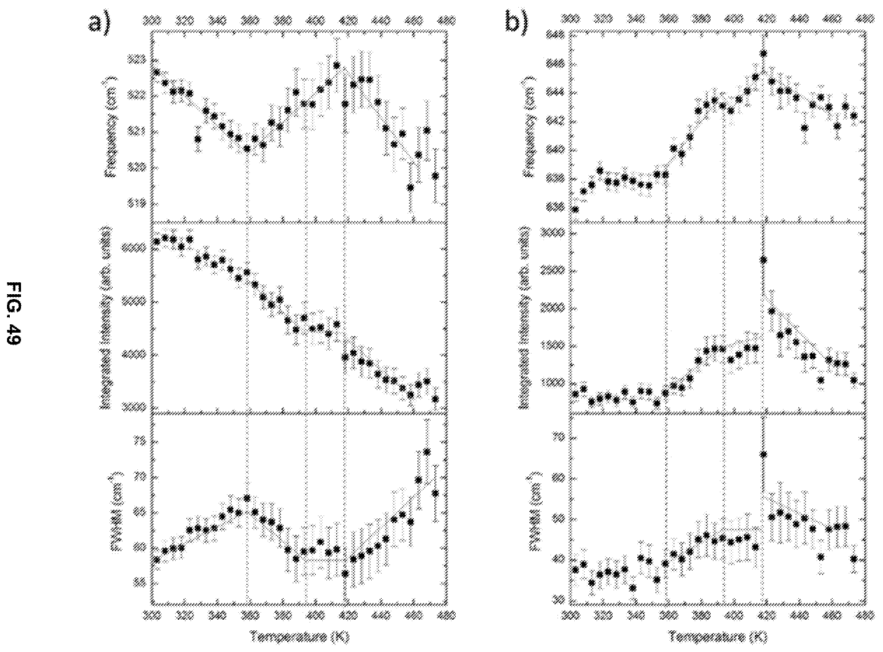

FIG. 49 displays the frequency, integrated intensity and FWHM as a function of temperature for the 520 cm⁻¹ and the 620 cm⁻¹ peaks for the most Ba-rich thin film (Ba/Ti=1.06). Here, a significant change in the frequency behavior of the 520 cm⁻¹ peak is observed over a wide temperature interval, from 350 K to 415 K. While the frequency decreases as temperature increases from 290 K to 350 K, it starts to raise at 350 K followed by a sharp drop at 415 K. The integral intensity and linewidth also experience non-monotonic changes in the same temperature range. While the decrease in the intensity slows down at 350 K and only drops a little between 350 K and 415 K, the FWHM sharply changes the behaviour, from increasing to decreasing, at 350 K and then changes the behaviour again, now from decreasing to increasing, at 415 K. The temperature behaviour of the 620 cm⁻¹ peak for the Ba-rich sample exhibits a behaviour strongly correlated to the 520 cm⁻¹ peak and even exhibits additional features. As one can see, all parameters have significant peculiarities in the interval of 350-420 K. An additional anomaly occurs within this range, at ˜400 K. This feature is observed for all spectroscopic parameters of the 620 cm⁻¹ peak.

Analysis of both peaks for the Ba-rich sample indicates that the structural transformation of both phases, t-BTO and h-BTO, occurs simultaneously and/or facilitates each other. The observation of the phase transition in the Raman study for the sample with a Ba/Ti-ratio of 1.06 allows a deeper insight into the nature of the structure transformation. Although the phase transition region observed in the Raman spectra includes the transition temperature obtained in dielectric measurements at 350 K to 355 K, the Raman study indicates that the transformation has an extended character and covers a wider temperature range up to 420 K.

Without being bound to any particular theory, there are two reasons that might cause such a difference: the sample location, at which the Raman spectra were collected (area between top electrodes) might have bigger crystallites in addition to the smaller ones below the electrodes, which are probed in dielectric measurements or the higher losses, which are detected in this sample, could mask additional features that occur during the phase transition for the dielectric measurements. This concerted phase transition of both polymorphs may contribute to the unprecedented increase of the Curie temperature compared to the stoichiometric composition.

In summary, provided is a novel route to manipulate a ferroelectric phase transition in nanograined ferroelectric thin films. The presented approach is based on the enhanced metastable cation solubility in nanograined polycrystalline BTO thin films, which results in the formation of Schottky defects. The present disclosure comprises a number of various, independent measurements investigating the structural as well as electrical properties, which rule out other possibilities and are all consistent with the formation of Schottky defects.

The presence of Schottky defects, in particular the cation ratios, in all our films were confirmed from Rutherford backscattering spectrometry (RBS). The Ba/Ti-ratio values have been determined using RBS measurements. The details of the RBS analysis are provided elsewhere. Also, the increase of lattice parameters on Ba-rich side indicates the increased number of vacancies. The latter is consistent with a twice higher number of oxygen vacancies in the Ba-rich samples compared to the Ti-rich samples in accordance with equations (2) and (3). The absence of any additional secondary phases besides the hexagonal polymorph, together with the lack of cation segregation at the grain boundaries and film-substrate interfaces confirm that the off-stoichiometry is accommodated within the BTO crystallites. Moreover, the independence of the ratio of hexagonal to perovskite polymorph to the Ba/Ti-ratio and the systematic change of the lattice parameter indicate that cation defects are located in the perovskite phase.

Measurements of the temperature dependence of the dielectric constant reveal that the transition temperature changes linearly from 212 K to 350 K as the Ba/Ti ratio increases from 0.8 to 1.06 for films with average grain sizes of 8-12 nm. A significant reduction in the temperature dependence of the dielectric permittivity that can be desired for some practical applications is observed and arises from a completely diffuse phase transition for all compositions. However, the degree of diffuseness slightly decreases from ˜650 for a Ba/Ti-ratio of 0.8 sample to ˜565 for 1.06. For two nearly stoichiometric films (Ba/Ti=1.01) with different processing sequences, a size effect manifests itself in the decrease of the Curie point from 390 K for crystallites with average size of 35 nm to 330 K for crystallites with average size of 12 nm. This allows to disentangle the contribution of the size effect to the transition temperature change from compositional effects. We propose (without being bound to any particular theory) that partial Schottky defects forming mostly divacancies (V_{Ba}-V_{O}, V_{Ti}-V_{O}) are created to accommodate the off-stoichiometry. However, the estimates show that internally imposed strain via chemical pressure should be higher than that registered by XRD. Therefore, the internal stress evolving at the grain boundaries during the crystallization process of the thin films in conjunction with a locally varying composition throughout the film are suggested to partially relax the local strain induced by Schottky defects inside the crystallites.

Temperature dependent Raman experiments confirm the transition temperature obtained from dielectric measurements. Monitoring the temperature behaviour of different modes corresponding to the hexagonal and perovskite BTO phases reveals that the presence of the hexagonal polymorph in addition to the perovskite phase influences the structural transformation on the Ba-rich side, while it is ineffective on the Ti-rich side. For the Ba-rich thin film, the Raman study indicates that although the phase transition region includes the transition temperature of 350 K determined from the dielectric measurements, structural reconstructions exhibit an extended character and occur over a wider temperature range up to 420 K.

Grain Sizes

The distribution of grain sizes was obtained from the TEM images for four samples with various Ba/Ti ratios. All evaluated samples had top Pt electrodes deposited before the annealing step. FIG. 50 shows the distribution for each sample. The solid red curves are the histogram fitting by a Gaussian function. The mean values and standard deviations obtained from the fitting for each composition are as follows (in nm): 8.066±0.643, 11.970±0.694, 12.094±0.481, and 8.697±0.344 for films with Ba/Ti-ratio equals 0.8, 0.92, 1.01, and 1.06, respectively. In addition, TEM images for a stoichiometric sample (Ba/Ti=1.01) with top Pt electrodes deposited after the annealing step have been analyzed. The distribution of grain sizes for this sample is presented in FIG. 51.

A TEM cross section beneath uncovered area (between top electrodes) was also examined in a similar way. The distribution of grain sizes obtained from this area and the histogram fitting by a Gaussian function are depicted in FIG. 52. The mean value and standard deviation obtained from the fitting is 17.067±0.765 nm.

It is noted that top Pt electrodes deposited before annealing cause a mechanical clamping of the film (“sandwiched” between bottom- and top-Pt) and thereby suppress the grain growth during the annealing step. The grain growth is not suppressed as the film has an “open” surface, if Pt top electrodes are deposited after annealing.

XPS Data

The XPS Ti spectra for the films with Ba/Ti ratio of 0.8, 0.92, 1.01 and 1.06 and corresponding fits are presented in FIG. 53a. The two peaks at 458.21 eV and 464 eV originate from the Ti2p3/2 and Ti2p1/2 lines, respectively, and do not shift in energy as a function of composition. The Ti2p3/2 peak is fitted by one Voigt (Gaussian/Lorentzian=50/50) function at 458.19 eV (FIG. 53b), which corresponds to the valence state of Ti⁴⁺. The FWHM of the Ti2p3/2 peak is 1.15 eV in all cases.

The XPS Ba spectra for the films with Ba/Ti=0.8, 0.92, 1.01 and 1.06 are displayed in FIG. 54a. The small shift of the Ba spectra is in the range of instrumental error, when we take the C1s lines as a standard for a linear calibration. The Ba3d5/2 spectrum contains two maxima. The Ba3d5/2 peak for the film with Ba/Ti=1.06 is fitted by two Voigt (Gaussian/Lorentzian=50/50) functions: at 778.84 eV and 780.24 eV, the FWHM of which are 1.3 eV and 1.63 eV, respectively (FIG. 54b). The peak at lower binding energy originates from the barium in deeper layers, and the peak at higher binding energy from the barium on the surface that could arise due to residual unavoidable amount of BaCO₃ or Ba(OH)₂. The intensity of the line of the barium in deeper layers monotonically increases, while the intensity of the line corresponding to the barium on the surface systematically decreases with increasing Ba/Ti ratio.

Electrical Data

FIG. 55 shows the electric field dependence of current density and frequency dependence of dielectric constant for all films studied. The data have been collected at room temperature. FIG. 55a demonstrates that the films with different stoichiometry with top Pt electrodes deposited before the annealing step are basically identical in their J-E response. However, the stoichiometric film (Ba/Ti=1.01) with Pt electrodes deposited after annealing experiences higher leakage current than the stoichiometric film with electrodes deposited before annealing. The error bars in FIG. 55b were evaluated using 5 independently collected data sets for each MIM-capacitor. Considering the films with Pt electrodes deposited before the annealing step, one can state that the room temperature dielectric constant strongly depends on stoichiometry, especially on the Ti-rich side. It is reduced by 50% in the Ti-rich samples compared to the stoichiometric one (Ba/Ti=1.01), but remains almost unchanged upon further increasing the Ba/Ti ratio. It should also be noted that dielectric constant is ˜110 for the stoichiometric film (Ba/Ti=1.01) with top Pt electrodes deposited after the annealing procedure, and this is significantly lower than the dielectric constant ˜160 for the film with Pt electrodes deposited before annealing.

The I-V response for the films with different Ba/Ti ratio was shown in (Nanoscale, 2018, 10, 12515). However, in order to explicitly show that there is no correlation between conductivity and features in FIG. 42b for the film with Ba/Ti=1.06, FIG. 55a is shown to demonstrate that the films with different stoichiometry with top Pt electrodes deposited before the annealing step are basically identical in their J-E response. However, the stoichiometric film (Ba/Ti=1.01) with Pt electrodes deposited after annealing experiences higher leakage current than the stoichiometric film with electrodes deposited before annealing. To further consider the influence of the leakage current on the temperature behavior of losses, we provide the electric field dependences of current density (J-E) for the films with different Ba/Ti-ratio. The dependences depicted in FIG. 55a demonstrate that the films with different stoichiometry are basically identical in their J-E response, so there is no correlation between the J-E behavior and features in FIG. 52b for the film with Ba/Ti=1.06.

The absolute value of the room temperature dielectric constant as a function of frequency has been presented in (Nanoscale, 2018, 10, 12515). In order to avoid the figure repetition in the present paper, we depicted this data in FIG. 55b. We also added the data collected for the film with top Pt electrodes deposited after annealing to this figure. The room temperature dielectric constant as a function of frequency for the films with Ba/Ti=0.8, 0.92, 1.01 and for the film with Ba/Ti=1.01 with top electrodes after annealing is depicted in FIG. 55b. The error bars in FIG. 55b were estimated using 5 independently collected data sets for each MIM-capacitor. Considering the films with Pt electrodes deposited before the annealing step, one can state that the room temperature dielectric constant strongly depends on stoichiometry, especially on the Ti-rich side. It is reduced by 50% in the Ti-rich samples compared to the stoichiometric one (Ba/Ti=1.01), but remains almost unchanged upon further increasing the Ba/Ti ratio. It should also be noted that dielectric constant is ˜110 for the stoichiometric film (Ba/Ti=1.01) with top Pt electrodes deposited after the annealing procedure, and this is significantly lower than the dielectric constant ˜160 for the film with Pt electrodes deposited before annealing.

Although Pt electrodes are described in some example embodiments, it should be understood that other electrode materials can be used, e.g., TiN, copper, graphite, titanium, brass, silver, and other conductive materials. Likewise, it should be understood that materials can be annealed before deposition of electrodes, but materials can also be annealed after deposition of electrodes.

Polarization Loops

FIGS. 56 and 57 represent room temperature hysteresis loops collected for the stoichiometric (Ba/Ti=1.01) film with Pt electrodes deposited after the annealing step. The hysteresis loops were measured at different maximum electric fields and different measuring frequencies. The hysteresis loop measured at a maximum electric field of 0.65 MV/cm and a frequency of 1 kHz exhibits a maximum polarization of 7.5 μC/cm², while the influence of the leakage current is negligible there. This representative hysteresis loop is shown in FIG. 45.

Properties of ALD-Grown Nanocrystalline BaTiO₃-Including Bilayer Structrues with Al₂O₃ Thin Films

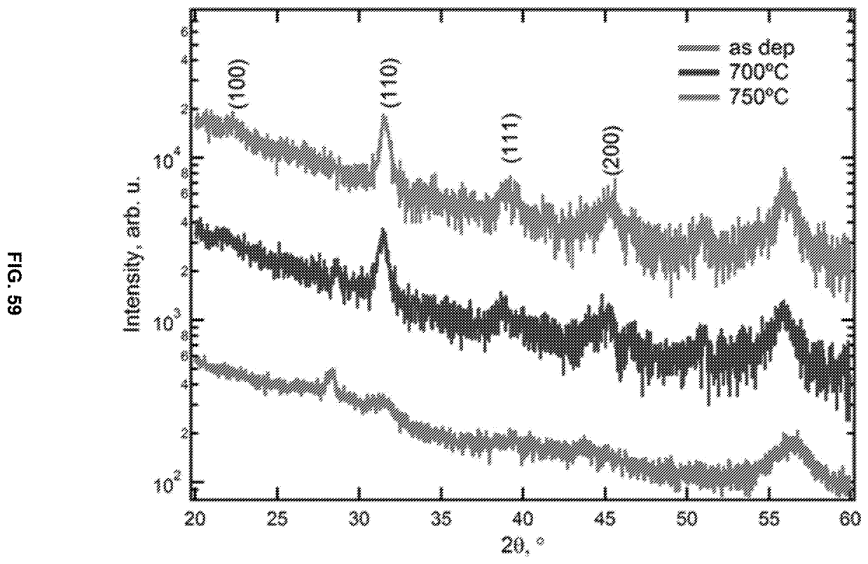

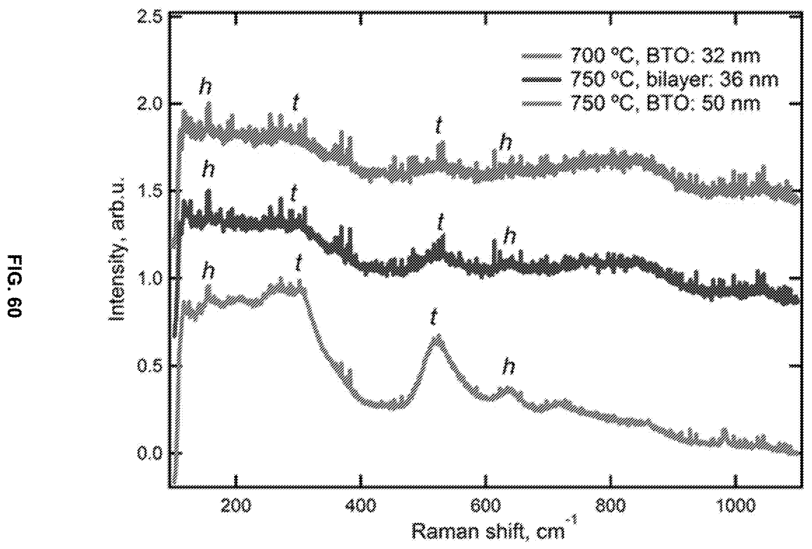

For the deposition of the nanocrystalline BaTiO₃ (BTO) thin films we used a seed-layer approach with ˜4-5 nm BTO seed layers annealed at 700° C. for 5 mins before depositing a thicker BTO film at 350° C. A seed-layer approach is known to provide improved crystallinity and resulting dielectric properties for SrTiO₃ (STO) thin films. The precursors used for BTO and Al₂O₃ deposition were: Absolut-Ba, Ti-methoxide, Trimethyl-Al, and O₃. All annealing steps were conducted before depositing the Al₂O₃ layers. Due to the larger lattice mismatch to Pt compared to STO only a small amount of crystalline BTO forms during the ALD-process (see FIG. 59) with a weak peak at ˜32° in 2θ. This is also reflected in the AFM height image (FIG. 60a) and measured properties with a field independent dielectric constant of 18 and a leakage current of 3×10⁻¹⁰ A/mm² at 1 MV/cm. For these films we investigated properties of MIM capacitors with the following stacking sequence: (111)-Pt bottom electrode|32 nm BTO|4 nm Al₂O₃|40 nm TiN top electrode. The TiN top electrodes were deposited using Magnetron sputtering at room temperature at a power of 450 W utilizing a standard photolithography process. The BTO on (111)-Pt substrates was annealed at 700° C. and at 750° C. for 10 mins prior to depositing 4 nm thick Al₂O₃ on top of the crystalline BTO. The crystallinity of the BTO films after the annealing step was confirmed by XRD (FIG. 59).

The Raman spectra in FIG. 60 reveal the polymorphism in all thin films. Independent of the annealing conditions, signature modes of perovskite as well as hexagonal BTO are clearly observed. These characteristics for polymorphism in these nanocrystalline BTO films are independent of the cation ratio.

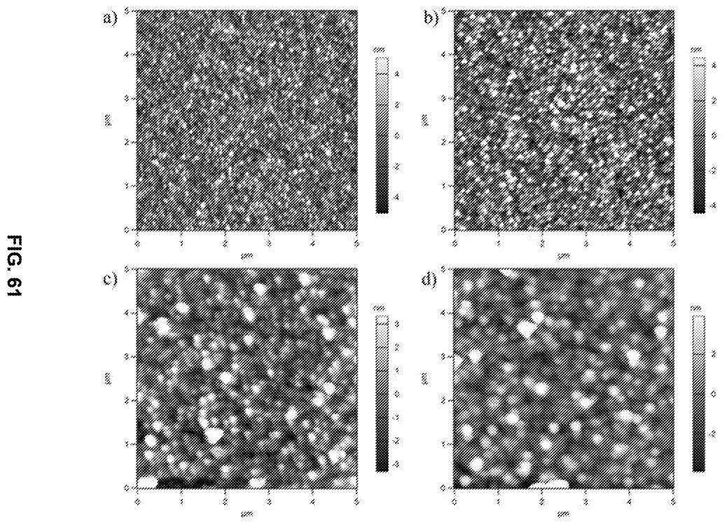

The surfaces for this set of films were examined after the deposition, after annealing at 700° C. in O₂ flow, after annealing at 700° C. and at 750° C. in N₂ flow followed by ALD-growth of 4 nm Al₂O₃. The as deposited partially/slightly crystallized film reveals only small grains on the surface corroborating the XRD-data in FIG. 59, while post-deposition annealing step results in all cases in grain growth and full crystallization of BTO. The Al₂O₃ layers in FIG. 61c) and FIG. 61d) cannot be recognized from the AFM images as a conformal growth should preserve the topology of the BTO layer. Interestingly, the average roughness does not increase significantly and is for all films around 2 nm for an area of 5×5 μm². Nevertheless, an increase of the grain size with annealing temperature is clearly visible, which results in a locally increased variation in film thickness.

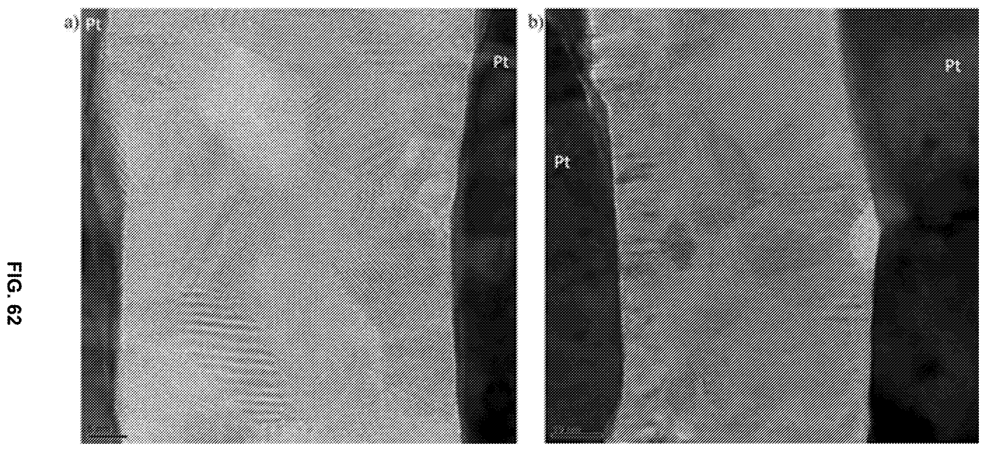

FIG. 62 displays high-resolution transmission electron microscopy (HR-TEM) images of two films with varying Ba/Ti-ratio after annealing at 750° C. in O₂. On the left side a Ba-rich film (Ba/Ti: 1.06) and on the right side a Ti-rich film (Ba/Ti: 0.80) exhibit very similar microstructures. In both cases, hexagonal and tetragonal BTO crystallites are randomly distributed throughout the film and the average grain sizes are 11.5 nm and 11.1 nm, respectively.

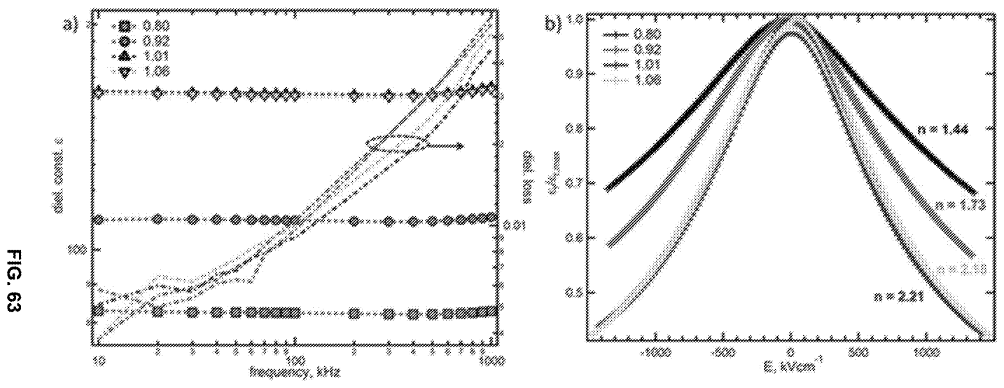

Importantly, the dielectric properties of these nanocrystalline thin films are very sensitive to the Ba/Ti-ratio. This is shown in FIGS. 63. a and b, where in particular for the Ti-rich side the permittivity rapidly declines and also the tunability (response to electric field) is drastically reduced.

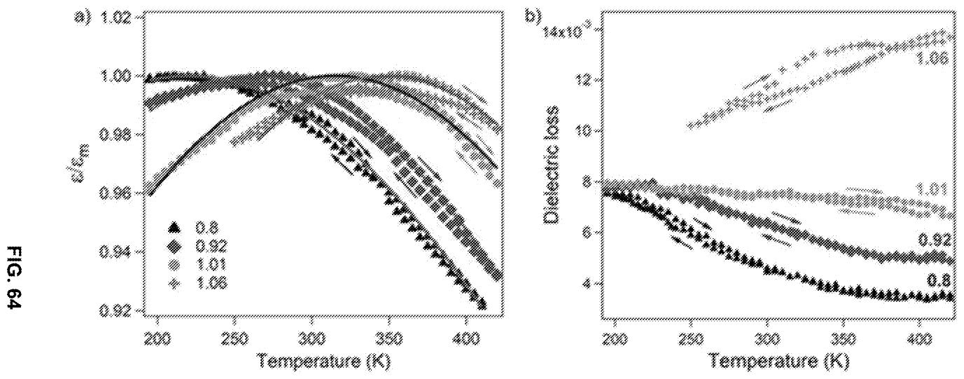

Interestingly, the Ba/Ti-ratio also influences the ferroelectric transition temperature of these thin films as shown in FIG. 64. A significant shift in temperature of 130 K can be achieved by changing the cation composition. This new approach to tune the transition temperature is important for applications in specific temperature ranges. Another important difference to bulk BaTiO₃ is the relative temperature insensitivity of the dielectric constant, which is achieved by polymorphism as well as nanocrystallinity. Both features introduce additional strain at the grain boundaries of these thin films.

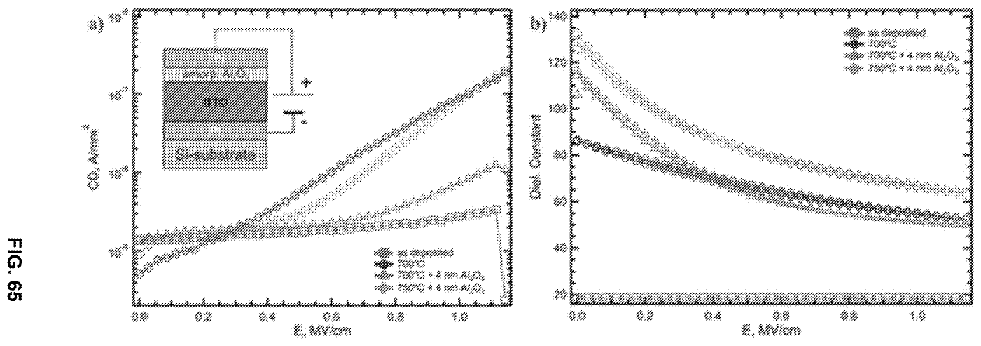

Based on these properties, we developed bilayers of these nanocrystalline BTO with thin amorphous Al₂O₃ layers to further reduce the leakage current and make them appealing candidates for high-k materials. The leakage current and dielectric parameters/characteristics were evaluated from MIM-capacitors produced as described above. In FIG. 65 the leakage current and dielectric constant (at 100 kHz) measured at room temperature for a positive bias are displayed as a function of process conditions. The different processing and annealing steps were: i) as deposited: after the ALD-growth of the film, ii) 700° C.: subsequent annealing for 10 mins under O₂ flow, iii) 700° C.+4 nm Al₂O₃ and iv) 750° C.+4 nm Al₂O₃: subsequent annealing for 10 mins under N₂ flow, followed by the growth of 4 nm Al₂O₃ at 350° C. In all cases the top electrodes were produced as described above at the end of the MIM-capacitor processing.

It can be clearly seen from FIG. 65a that the as deposited film exhibits a very low current density in agreement with the mostly amorphous state of the BTO layer as determined by XRD. Comparing the films annealed at 700° C. with and without Al₂O₃ layer, we can see that a 4 nm thick layer of amorphous Al₂O₃ reduces the current density by one order of magnitude. Annealing at 750° C. increases the leakage current again by one order of magnitude, which can be attributed to the larger grains observed by AFM (see FIGS. 61c and d) resulting in less conformal coverage by Al₂O₃ and in locally increased electric fields due to variations in the film thickness.

The dielectric constant as a function of positive electric field for the same MIM-capacitors is shown in FIG. 65b. We calculated the overall dielectric constant of the BTO-Al₂O₃ stacks of 36 nm thickness using the standard model for two parallel-plate capacitors in series. The as deposited MIM-structure has a very low field independent dielectric constant of 18 as expected for an amorphous film. After annealing, the dielectric constant for all MIM-devices shows a similar field-dependence with the film annealed at 700° C. exhibiting a value of 103 at E=0 and the film annealed at 750° C. exhibiting a value of 130 at E=0, respectively. Both MIM-capacitor stacks exceed the benchmark value of 100, which is mandatory for further downscaling of electronic devices.

FIG. 10 shows a comparison of the dielectric constant at 0 MV/cm and leakage current at 1 MV/cm (or highest electric field measured if below 1 MV/cm) for BTO-Al₂O₃ dielectric stacks to various other high-k thin films and thin film stacks. The ideal material should be located in the top left corner.

Comparing these results to a variety of other high-k materials reveals the outstanding performance based on the combination of leakage current and dielectric constant for the BTO-Al₂O₃ thin film stacks (see FIG. 10). For high-k materials it is most desirable to simultaneously exhibit high dielectric constants and low leakage currents, which corresponds to the top left corner in FIG. 65. In this respect the BTO-Al₂O₃ thin-film stacks are well separated from competitor materials. In particular, the comparison to STO-Al₂O₃ stacks with STO thickness of 50 nm and Al₂O₃ of up to 4 nm demonstrates the superior performance exhibited by the BTO-Al₂O₃ thin-film stacks. The large potential for up-scaling this process as well as integration into existing semiconductor industry platforms deems this approach highly appealing for industrial applications.

### Embodiments

The following embodiments are illustrative only and do not serve to limit the scope of the present disclosure or the appended claims.

Embodiment 1. A capacitive component, comprising: a plurality of films, the plurality of films comprising: a first grained film component, the first grained film component comprising at least one of SrTiO₃, BaTiO₃, and (Ba, Sr)TiO₃, and the first grained film component optionally being characterized as being at least partially polymorphic crystalline in nature; a second film component contacting the first grained film component, the second film component optionally comprising Al₂O₃, and the first grained film component optionally defining an average grain size of less than about 10 micrometers, optionally less than about 9 micrometers, optionally less than about 8 micrometers, optionally less than about 7 micrometers. optionally less than about 6 micrometers, optionally less than about 5 micrometers, optionally less than about 4 micrometers, optionally less than about 3 micrometers, optionally less than about 2 micrometers, or optionally less than about 1 micrometer.

The first grained film component can comprise one of SrTiO₃, BaTiO₃, and (Ba, Sr)TiO₃. BaTiO₃ is considered particularly suitable. The first grained film component can be partially crystallized or even completely crystallized.

Embodiment 2. The capacitive component of Embodiment 1, wherein the first grained film component defines a grain size in the range of from about 0.01 to about 9 micrometers. The grain size can be from about 0.6 to about 7 micrometers, from about 0.8 to about 6 nm, from about 1 to about 4 micrometers, or even from about 1.3 to about 3.5 micrometers. The grain size can also be on the order of nanometers, tens of nanometers, or even hundreds of nanometers.

Embodiment 3. The capacitive component of any one of Embodiments 1-2, wherein the first grained film component defines a thickness in the range of from about 1 nm to about 50 nm. Thicknesses of about 1 to about 50 nm, or from about 3 to about 43 nm, or from about 5 to about 38 nm, or from about 8 to about 33 nm, or even from about 10 to about 27 nm are all considered suitable.

Embodiment 4. The capacitive component of any one of Embodiments 1-3, wherein the second film component defines a thickness in the range of from about 1 nm to about 50 nm. Thicknesses of about 1 to about 50 nm, or from about 3 to about 43 nm, or from about 5 to about 38 nm, or from about 8 to about 33 nm, or even from about 10 to about 27 nm are all considered suitable.

The total thickness of the first grained film component and the second film component can be, e.g., from about 5 to about 100 nm, from about 10 to about 90 nm, from about 15 to about 80 nm, from about 20 to about 75 nm, from about 25 to about 70 nm, from about 30 to about 65 nm, or even from about 35 to about 55 nm. The total thickness of the capacitive component can be less than about 75 nm, or less than about 70 nm, or less than about 65 nm, or less than about 60 nm, or less than about 55 nm, or even less than about 50 nm or less than about 45 nm.

Embodiment 5. The capacitive component of any one of Embodiments 1-4, wherein the first grained film component defines a thickness, the second film component defines a thickness, and wherein the ratio of the thickness of the first grained film component to the thickness of the second film component is from about 50:1 to about 1:5.

Embodiment 6. The capacitive component of any one of Embodiments 1-5, wherein the plurality of films is characterized as having a dielectric constant, at 0 V, of greater than about 40. The dielectric constant can be, e.g., from about 40 to about 140, from about 45 to about 140, from about 50 to about 135, from about 55 to about 130, from about 50 to about 125, from about 55 to about 120, from about 60 to about 115, from about 65 to about 110, from about 70 to about 105, or even from about 80 to about 100. Dielectric constants between 50 and about 100, or between 50 and about 95, or between 50 and about 90, or between 50 and about 85, or between 50 and about 80, or between 50 and about 75, or between 50 and about 70, or between 50 and about 65, or between 50 and about 55 are all considered suitable.

Embodiment 7. The capacitive component of any one of Embodiments 1-6, wherein the plurality of films is characterized as having a dielectric constant, at 0 V, of from about 40 to about 100 or even to about 120.

Embodiment 8. The capacitive component of any one of Embodiments 1-7, wherein the plurality of films is characterized as having a leakage current, measured at 1 MV/cm and at 125 deg C., in the range of from about 1×10⁻⁷ A/mm² to about 1×10⁻⁸ A/mm².

Embodiment 9. The capacitive component of any one of Embodiments 1-8, wherein the plurality of films comprises a third film component. As one example, a component can include films layered as, e.g., Al₂O₃—BaTiO₃—Al₂O₃.

Embodiment 10. The capacitive component of Embodiment 9, wherein the third film component comprises Al₂O₃.

Embodiment 11. The capacitive component of any one of Embodiments 9-10, wherein the third film component defines a thickness in the range of from about 1 nm to about 20 nm. The third film component can contact the first film component on a side other than a side where the first film component contacts the second film component.

Embodiment 12. The capacitive component of any one of Embodiments 1-11, wherein the plurality of films is disposed between a first electrode and a second electrode. One or both of the first electrode and the second electrode can comprise, for example, Ag, Cu, Au, Al, Be, Ca, Mg, Rh, Na, Ir, Cu, Zn, Pb, Ni, brass, bronze, TiN, a conductive polymer (e.g., polyfluorines, polyphenylenes, polypyrenes, polyazulenes, polynaphthalenes, polyacetylenes, poly(p-phenylene vinylene), polypyrroles, polycarbazoles, polyindoles, polyazepines, polyanilenes, polythiopenes, poly(3,4-ethylenedioxythiophene), poly(p-phenylene sulfide), carbonaceous materials (e.g., graphite, graphene, carbon nanotubes), aluminum, LiF, Pd, brass, Pt, carbon steel, and the like.

As described elsewhere herein, a plurality of films can comprise three dielectric films stacked together, e.g., Al₂O₃—BaTiO₃—Al₂O₃.

Embodiment 13. The capacitive component of any one of Embodiments 1-12, wherein the first grained film component comprises BiTiO₃, and wherein the molar ratio of Ba to Ti is from about 0.80 to about 1.06.

Embodiment 14. A capacitive component, comprising: a plurality of films, the plurality of films optionally being disposed between a first electrode and a second electrode, and the plurality of films comprising: a first grained film component, the first grained film component being characterized as being at least partially crystalline polymorphic; a second film component contacting the first grained film component, the second film component optionally comprising Al₂O₃, and the plurality of films optionally having a dielectric constant, at 0 V, of from about 40 to about 140 and optionally a leakage current, measured at 1 MV/cm and 125 deg. C., of from about 10⁻⁷ A/mm² to about 10⁻⁸ A/mm².

The dielectric constant can be, e.g., from about 40 to about 140, from about 42 to about 135, from about 45 to about 120, from about 50 to about 110, from about 55 to about 105, from about 60 to about 100, from about 65 to about 95, from about 70 to about 90, or from about 75 to about 85.

As one example, a component can comprise (i) a first electrode that comprises one or more of Pt and TiN, (ii) a first grained film component that contacts the first electrode and that comprises at least one of SrTiO₃, BaTiO₃, and (Ba, Sr)TiO₃, a second film component that contacts the first grained film component and that comprises Al₂O₃ (e.g., in at least partially amorphous form), and a second electrode that contacts the second film component and that comprises one or more of Pt and TiN.

Embodiment 15. The capacitive component of Embodiment 14, wherein the first grained film component defines a thickness, the second film component defines a thickness, and wherein the ratio of the thickness of the first grained film component to the thickness of the second film component is from about 50:1 to about 1:5. The total (combined) thickness of the first grained film component and the second film component can be, e.g., from 10 to 50 nm, from 15 to 45 nm, from 20 to 40 nm, from 25 to 35, nm, or even about 30 nm.

Embodiment 16. The capacitive component of any one of Embodiments 14-15, wherein the first grained film component defines a grain size of less than about 10 micrometers, optionally less than about 9 micrometers, optionally less than about 8 micrometers, optionally less than about 7 micrometers. optionally less than about 6 micrometers, optionally less than about 5 micrometers, optionally less than about 4 micrometers, optionally less than about 3 micrometers, optionally less than about 2 micrometers, or optionally less than about 1 micrometer. Grain sizes can also be in the range of from about 10 to about 1000 nm, or from about 15 to about 800 nm, or from about 20 to about 700 nm, or from about 50 to about 500 nm, or even from about 75 to about 250 nm. Thus, grains can be in the sub-micrometer size.

Embodiment 17. An article, the article comprising a capacitive component according to any one of Embodiments 1-16.

Embodiment 18. A method, comprising discharging electrical energy from a capacitive component according to any one of Embodiments 1-16.

Embodiment 19. A method, comprising storing electrical energy in a capacitive component according to any one of Embodiments 1-16.

Embodiment 20. A method, comprising energizing an electrical load with energy discharged from a capacitive component according to any one of Embodiments 1-16. Example electrical loads include, e.g., mobile devices, memory devices, medical instruments, automotive components, aerospace components, and the like. Essentially any electrical load can be energized by energy discharged from a capacitive component according to the present disclosure.

Embodiment 21. A component, the component being made according to any methods described herein.

Embodiment 22. The component of Embodiment 21, wherein the component is a component according to any one of Embodiments 1-16.

Embodiment 23. A nano-grained film, comprising: a BaTiO3 film component comprising a Ba/Ti ratio of between about 0.8 and 1.06, a transition temperature of the nano-grained film being dependent on the Ba/Ti ratio, and the nano-grained film exhibiting a diffused phase transition, optionally whereby a temperature density of a dielectric constant of the nano-grained film is minimized.

A film according to the present disclosure can have a thickness of from about 1 to about 100 nm, or from about 2 to about 50 nm, or even from about 3 to about 25 nm.

Embodiment 24. The nano-grained film of claim 23, wherein the transition temperature is the Curie temperature of the nano-grained film.

Embodiment 25. The nano-grained film of claim 23, wherein the nano-grained film comprises a hexagonal phase associated with at least a Ba-rich portion of the nano-grained film.

Embodiment 26. The nano-grained film of any one of claims 23-25, comprising a perovskite phase.

Embodiment 27. The nano-grained film of any one of claims 23-26, wherein the nano-grained film exhibits a dielectric constant of from about 84 on cooling to about 163 on cooling. Dielectric constant value of from about 85 to about 162, or from about 90 to about 155, or from about 95 to about 145, or from about 100 to about 135, or even from about 110 to about 120 are all suitable. Such values can depend on the stoichiometry of the Ba/Ti present in the film.

Embodiment 28. The nano-grained film of any one of claims 23-27, wherein the nano-grained film defines a thickness of from about 10 to about 100 nm.

Embodiment 29. The nano-grained film of claim 28, wherein the nano-grained film defines a thickness of from about 25 to about 75 nm,

Embodiment 30. The nano-grained film of claim 28, wherein the nano-grained film defines an average grain size of from about 5 to about 15 nm.

Embodiment 31. The nano-grained film of claim 30, wherein the nano-grained film defines an average grain size of from about 8 to about 12 nm.

Embodiment 32. The nano-grained film of any one of claims 23-31, wherein the Ba/Ti ratio is less than 1.00.

Embodiment 33. The nano-grained film of any one of claims 23-32, wherein the Ba/Ti ratio is greater than 1.00.

Embodiment 34. A nano-grained film configured to exhibit a diffused phase transition, whereby a temperature density of a dielectric constant of the nano-grained film is minimized, wherein a transition temperature and the temperature density of the dielectric constant of the nano-grained film is tuned based at least on stoichiometry of one or more materials forming the nano-grained film.

Embodiment 35. A method, comprising forming a nano-grained film according to any one of claims 22-34.

Embodiment 36. A device, comprising: one or more electrodes in electronic communication with a nano-grained film according to any one of claims 22-34.

Embodiment 37. The device of claim 36, wherein the device is characterized as a memory device, a power transfer device, a microwave device, or a surface acoustic wave resonator.

Embodiment 38. A method, comprising operating a device according to any one of claims 36-37.

Embodiment 39. The method of claim 38, further comprising operating the device such that the nano-grained film attains its Curie temperature.

Embodiment 40. The device of any one of claims 36-37, wherein an electrode comprises Pt.

Embodiment 41. The device of any one of claim 36-37, wherein an electrode comprises TiN.

Embodiment 42. A method, comprising: tuning a Curie transition temperature of a nano-grained film that comprises a BaTiO3 film component comprising a Ba/Ti ratio of between about 0.8 and 1.06, a transition temperature of the nano-grained film being dependent on the Ba/Ti ratio, and the nano-grained film exhibiting a diffused phase transition, optionally whereby a temperature density of a dielectric constant of the nano-grained film is minimized, the tuning comprising modulating the Ba/Ti ratio.

### REFERENCES

H. Hu, C. Zhu, Y. F. Lu, M. F. Li, A High Performance MIM Capacitor Using HfO₂ Dielectrics. IEEE Electron Device Letters 23 (9), 514-516 (2002).

F. El Kamel, P. Gonon, C. Vallee, and C. Jorel. Electrode effects on the conduction mechanisms in HfO₂-based metal-insulator-metal capacitors. J. Appl. Phys. 106, 064508 (2009).

P. C. Joshi and M. W. Cole. Influence of post deposition annealing on the enhanced structural and electrical properties of amorphous and crystalline Ta₂O₅ thin films for dynamic random access memory applications. Journal of Applied Physics 86, 871 (1999).

S. K. Kim, K. M. Kim, D. S. Jeong, W. Jeon, K. J. Yoon, C. S. Hwang, Titanium dioxide thin films for next-generation memory devices, J. Mater. Res. 28 (2013) 313-325.

S.-Y. Lee, H. Kim, C. McIntyre, K. C. Saraswat, J.-S. Byun. Atomic layer deposition of ZrO₂ on W for metal-insulator-metal capacitor application. Appl. Phys. Lett. 82(17), 2874-2876 (2003).

B.-E. Park, I.-K. Oh, C. Mahata, C. W. Lee, D. Thompson, H.-B.-Ram Lee, W. J. Maeng, H. Kim. Atomic layer deposition of Y-stabilized ZrO₂ for advanced DRAM capacitors Journal of Alloys and Compounds 722 (2017) 307-312.

G. Łupina,a G. Kozlowski, J. Da̧browski, Ch. Wenger, P. Dudek, P. Zaumseil, G. Lippert, Ch. Walczyk, and H.-J. Müssig. Thin BaHfO₃ high-k dielectric layers on TiN for memory capacitor applications. Appl. Phys. Lett. 92, 062906 (2008).

G. Łupina, J. Da̧browski, P. Dudek, G. Kozlowski, P. Zaumseil, G. Lippert, O. Fursenko, J. Bauer, C. Baristiran, I. Costina, H.-J. Müssig, L. Oberbeck, and U. Schröder. Dielectric constant and leakage of BaZrO₃ films. Appl. Phys. Lett. 94, 152903 (2009).

M. A. Pawlak, B. Kaczer, M.-S. Kim, M. Popovici, K. Tomida, J. Swerts, K. Opsomer, W. Polspoel, P. Favia, C. Vrancken, C. Demeurisse, W.-C. Wang, V. V. Afanas'ev, W. Vandervorst, H. Bender, I. Debusschere, L. Altimime, and J. A. Kittl. Impact of crystallization behavior of SrₓTi_{y}O_{z} films on electrical properties of metal-insulator-metal capacitors with TiN electrodes. Appl. Phys. Lett. 97, 162906 (2010).

N. Menou, M. Popovici, S. Clima, K. Opsomer, W. Polspoel, B. Kaczer, G. Rampelberg, K. Tomida, M. A. Pawlak, C. Detavernier, D. Pierreux, J. Swerts, J. W. Maes, D. Manger, M. Badylevich, V. Afanasiev, T. Conard, P. Favia, H. Bender, B. Brijs, W. Vandervorst, S. Van Elshocht, G. Pourtois, D. J. Wouters, S. Biesemans, and J. A. Kittl. Composition influence on the physical and electrical properties of SrₓTi₁₋ₓO_{y}-based metal-insulator-metal capacitors prepared by atomic layer deposition using TiN bottom electrodes. J. Appl. Phys. 106, 094101 (2009).

V. Longo, F. Roozeboom, W. M. M. Kessels and M. A. Verheijen. ALD of SrTiO₃ and Pt for Pt/SrTiO₃/Pt MIM structures: Growth and Crystallization study. ECS Transactions, 58 (10) 153162 (2013).

M. Vehkama\ddot{ }ki, T. Hatanpa\ddot{ }a\ddot{ }, T. Ha\ddot{ }nninen, M. Ritala and M. Leskela\ddot{ }, Growth of SrTiO₃ and BaTiO₃ Thin Films by Atomic Layer Deposition. Electrochem. Solid-State Lett. 2, 504-506 (1999).

M. Vehkama\ddot{ }ki, T. Hatanpa\ddot{ }a\ddot{ }, M. Ritala, M. Leskela\ddot{ }, S. Va\ddot{ }yrynen and E. Rauhala, Atomic Layer Deposition of BaTiO₃ Thin Films—Effect of Barium Hydroxide Formation. Chem. Vap. Deposition 13, 239-246 (2007).

M. W. Cole, E. Ngo, C. Hubbard, S. G. Hirsch, M. Ivill, W. L. Sarney, J. Zhang, and S. P. Alpay. Enhanced dielectric properties from barium strontium titanate films with strontium titanate buffer layers. J. Appl. Phys. 114, 164107 (2013).

K. P. Jayadevan, C. Y. Liu, and T. Y. Tseng. Dielectric characteristics of nanocrystalline Ag—Ba_{0.5}Sr_{0.5}TiO₃ composite thin films. Appl. Phys. Lett. 85, 1211 (2004).

L. Z. Cao, B. L. Cheng, S. Y. Wang, Y. L. Zhou, K. J. Jin, H. B. Lu, Z. H. Chen, and G. Z. Yang. Dielectric properties of Si—Ba_{0.5}Sr_{0.5}TiO₃ composite thin films elaborated by pulsed laser deposition. J. Appl. Phys. 98, 034106 (2005).

RF and Analog/Mixed-Signal Technologies for Wireless Communications, International Roadmap for Semiconductors (Semiconductor Industry Association, 2009 and 2011 updates).

Handbook of Electronic and Photonic Materials, edited by S. Kasap and P. Capper. Springer International Publishing AG, 2017.

K. Kukli, J, Ihanus, M. Ritala, and M. Leskela. Tailoring the dielectric properties of HfO₂—Ta₂O₅ nanolaminates. Appl. Phys. Lett. 68 (26), 3737-3739 (1996).

S. H. Lin, K. C. Chiang, Albert Chin, and F. S. Yeh. High-Density and Low-LeakageCurrent MIM Capacitor Using Stacked TiO₂/ZrO₂ Insulators. IEEE ELECTRON DEVICE LETTERS 30(7), 715-717 (2009).

S.-J. Ding, C. Zhu, M.-F., D. W. Zhang. Atomic-layer-deposited Al₂O₃—HfO₂—Al₂O₃ dielectrics for metal-insulator-metal capacitor applications. Appl. Phys. Lett. 87, 053501 (2005).

J.-H. Ahn, J.-Y. Kim, S.-J. Jeong, S.-H. Kwon. Effect of Al₂O₃ insertion on the electrical properties of SrTiO₃ thin films: A comparison between Al₂O₃-doped SrTiO₃ and SrTiO₃/Al₂O₃/SrTiO₃ sandwich structure. Materials Research Bulletin 64 (2015) 1-5.

M. Lukosius, C. Wenger, T. Blomberg, G. Ruhl. Properties of stacked SrTiO₃/Al₂O₃ metal-insulator-metal capacitors. J. Vac. Sci. Technol. B 31(1), 01A102-1-01A102-6 (2013).

S. Li, A. Wachau, R. Schafranek, A. Klein, Yu. Zheng, and R. Jakoby. Energy level alignment and electrical properties of (Ba,Sr)TiO₃—Al₂O₃ interfaces for tunable capacitors. J. Appl. Phys. 108, 014113 (2010).

M. Pešic', S. Knebel, K. Cho, C. Jung, J. Chang, H. Lim, N. Kolomiiets, V. V. Afanas'ev, T. Mikolajick, U. Schroeder. Conduction barrier offset engineering for DRAM capacitor scaling. Solid-State Electronics 115, 133-139 (2016).

Takashi Onaya, Toshihide Nabatame, Tomomi Sawada, Kazunori Kurishima, Naomi Sawamoto, Akihiko Ohi, Toyohiro Chikyow, Atsushi Ogura. Improved leakage current properties of ZrO₂/(Ta/Nb)Oₓ—Al₂O₃/ZrO₂ nanolaminate insulating stacks for dynamic random access memory capacitors. Thin Solid Films 655 48-53 (2018).

Richard W. Johnson, Adam Hultqvist, and Stacey F. Bent A brief review of atomic layer deposition: from fundamentals to applications. Materials Today 17(5), 236-246 (2014).

J. H. Shim, H. J. Choi, Y. Kim, J. Torgersen, J. An, M. H. Lee and F. B. Prinz. Process—property relationship in high-k ALD SrTiO₃ and BaTiO₃: a review. J. Mater. Chem. C, 2017, 5, 8000.

H. H. Sønsteby, H. Fjellvåg and O. Nilsen, Functional Perovskites by Atomic Layer Deposition—An Overview, Adv. Mater. Interfaces, 2017, 4, 1600903.

M. Falmbigl, I. A. Karateev, I. S. Golovina, A. V. Plokhikh, T. C. Parker, A. L. Vasiliev and J. E. Spanier. Evidence of extended cation solubility in atomic layer deposited nanocrystalline BaTiO₃ thin films and its strong impact on the electrical properties. Nanoscale, 2018, 10, 12515.

S. Rentrop, B. Abendroth, J. Walter, J. Rensberg, W. Münchgesang, R. Strohmeyer, H. Stöcker, C. Ronning, S. Gemming, D. C. Meyer. Stoichiometry variation for the atomic layer deposition of SrₓTi_{y}O_{z} from Sr(iPr3Cp)₂, Ti[N(CH3)₂]₄ and H₂O. Thin Solid Films 577 (2015) 134-142.

S. W. Lee, J. H. Han, S. Han, W. Lee, J. H. Jang, M. Seo, S. K. Kim, C. Dussarrat, J. Gatineau, Yo-Sep Min, and C. S. Hwang. Atomic Layer Deposition of SrTiO₃ Thin Films with Highly Enhanced Growth Rate for Ultrahigh Density Capacitors. Chem. Mater. 2011, 23, 2227-2236.

S. Rentrop, T. Moebus, B. Abendroth, R. Strohmeyer, A. Schmid, T. Weling, J. Hanzig, F. Hanzig, H. Stöcker, D. C. Meyer. Atomic layer deposition of strontium titanate films from Sr(iPr3Cp)₂, Ti[N(CH3)₂]₄ and H₂O. Thin Solid Films 550 (2014) 53-58.

W. Lee, S. Yoo, W. Jeon, Y. W. Yoo, C. H. An, M. J. Chung, H. J. Kim, S. W. Lee, C. S. Hwang. Reducing the nano-scale defect formation of atomic-layer-deposited SrTiO₃ films by adjusting the cooling rate of the crystallization annealing of the seed layer. Thin Solid Films 589 (2015) 723-729.

An, J.; Usui, T.; Logar, M.; Park, J.; Thian, D.; Kim, S.; Kim, K.; Prinz, F. B. Plasma Processing for Crystallization and Densification of ALD BaTiO₃ Thin Films. ACS Appl. Mater. Interfaces 2014, 6, 10656-10660.

Acharya, S.; Torgersen, J.; Kim, Y.; Park, J.; Schindler, P.; Dadlani, A. L.; Winterkorn, M.; Xu, S.; Walch, S. P.; Usui, T.; et al. Self-Limiting Atomic Layer Deposition of Barium Oxide and Barium Titanate Thin Films Using a Novel Pyrrole Based Precursor. J. Mater. Chem. C 2016, 4 (10), 1945-1952.

Schindler, P.; Kim, Y.; Thian, D.; An, J.; Prinz, F. B. Plasma-Enhanced Atomic Layer Deposition of BaTiO₃. Scr. Mater. 2016, 111, 106-109.

M. Falmbigl, I. S. Golovina, A. V. Plokhikh, D. Imbrenda, A. Podpirka, C. J. Hawley, G. Xiao, A. Gutierrez-Perez, I. A. Karateev, A. L. Vasiliev, T. C. Parker, and J. E. Spanier. BaTiO₃ Thin Films from Atomic Layer Deposition: A Superlattice Approach. J. Phys. Chem. C 2017, 121, 16911-16920.

M. Tyunina; M. Plekh; J. Levoska; M. VEHKAMÄKI; M. HATANPÄÄ; M. Ritala; M. LESKELÄ. Dielectric Properties of Atomic Layer Deposited Thin-Film Barium Strontium Titanate. Integrated Ferroelectrics 102: 29-36, 2008.

I. S. Golovina, M. Falmbigl, A. V. Plokhikh, T. C. Parker, C. Johnson and Jonathan E. Spanier. Effect of annealing conditions on the electrical properties of ALD-grown polycrystalline BiFeO₃ films. J. Mater. Chem. C, 2018, 6, 5462.

K. Lee, W. Jang, H. Kim, H. Lim, B. Kim, H. Seo, H. Jeon. Leakage current suppression in spatially controlled Si-doped ZrO₂ for capacitors using atomic layer deposition. Thin Solid Films 657 (2018) 1-7.

I. S. Golovina, M. Falmbigl, C. J. Hawley, A. J. Ruffino, A. V. Plokhikh, I. A. Karateev, T. C. Parker, A. Gutierrez-Perez, A. L. Vasiliev and J. E. Spanier. Controlling the phase transition in nanocrystalline ferroelectric thin films via cation ratio. Nanoscale, 2018, 10, 21798.

O. S. Kwon, S. W. Lee, J. H. Han and C. S. Hwang, Atomic Layer Deposition and Electrical Properties of SrTiO₃ Thin Films Grown Using Sr(C₁₁H₁₉O₂)₂, Ti(Oi-C₃H₇)₄, and H₂O. J. Electrochem. Soc., 2007, 154, G127.

S. W. Lee, O. S. Kwon, J. H. Han and C. S. Hwang. Enhanced electrical properties of SrTiO₃ thin films grown by atomic layer deposition at high temperature for dynamic random access memory applications. Appl. Phys. Lett., 2008, 92, 222903.

C. Baristiran Kaynak, M. Lukosius, B. Tillack, Ch. Wenger, T. Blomberg, G. Ruhl. Single SrTiO₃ and Al₂O₃/SrTiO₃/Al₂O₃ based MIM capacitors: Impact of the bottom electrode material. Microelectron. Eng. 88, 1521-1524 (2011).

M. Kurasawa and P. C. McIntyre, Surface passivation and electronic structure characterization of PbTiO₃ thin films and Pt/PbTiO₃ interfaces. J. Appl. Phys. 2005, 97, 104110.

Schafranek, R.; Payan, S.; Maglione, M.; Klein, A. Barrier Height at (Ba,Sr)TiO₃/Pt Interfaces Studied by Photoemission. Phys. Rev. B 2008, 77 (19), 195310.

Hillmann, S.; Rachut, K.; Bayer, T. J. M.; Li, S.; Klein, A. Application of Atomic Layer Deposited Al₂O₃ as Charge Injection Layer for High-Permittivity Dielectrics. Semicond. Sci. Technol. 2015, 30 (2), 024012.

Robertson, J. Band Offsets, Schottky Barrier Heights, and Their Effects on Electronic Devices. J. Vac. Sci. Technol. A Vacuum, Surfaces, Film. 2013, 31 (5), 050821.

Wang, S. Y.; Li, M.; Liu, W. F.; Gao, J. Resistive Switching Behavior of BaTiO₃/La_{0.8}Ca_{0.2}MnO₃ heterostructures. Phys. Lett. Sect. A Gen. At. Solid State Phys. 2015, 379 (18-19), 1288-1292.

Huang, M. L.; Chang, Y. C.; Chang, C. H.; Lin, T. D.; Kwo, J.; Wu, T. B.; Hong, M. Energy-Band Parameters of Atomic-Layer-Deposition Al₂O₃/InGaAs Heterostructure. Appl. Phys. Lett. 2006, 89 (1), 2006-2008.

Lee, S. W., Han, J. H., Kwon, O. S. and Hwang, C. S. Influences of a Crystalline Seed Layer during Atomic Layer Deposition of SrTiO₃ Thin Films Using Ti(O-iPr)₂(thd)₂, Sr(thd)₂, and H₂O. J. Electrochem. Soc. 155, G253 (2008).

Kadoshima, M., Hiratani, M., Shimamoto, Y., Torii, K. and Miki, H. Rutile-type TiO₂ thin film for high-k gate insulator. 424, 224-228 (2003).

Yan, L. et al. High quality, high-k gate dielectric: amorphous LaAlO₃ thin films grown on Si(100) without Si interfacial layer. Appl. Phys. A 77, 721-724 (2003).

Kittl, J. A. et al. High-k dielectrics for future generation memory devices (Invited Paper). Microelectron. Eng. 86, 1789-1795 (2009).

Garcia, H. et al. Influence of precursor chemistry and growth temperature on the electrical properties of SrTiO₃-based metal-insulator-metal capacitors grown by atomic layer deposition. J. Vac. Sci. Technol. B Microelectron. Nanom. Struct. 29, 01AC04 (2011).

Kishiro, K., Inoue, N., Chen, S.-C. and Yoshimaru, M. Structure and Electrical Properties of Thin Ta₂O₅ Deposited on Metal Electrodes. Jpn. J. Appl. Phys. 37, 1336-139 (1998). [56] Zhang, H., Solanki, R., Roberds, B., Bai, G. and Banerjee, I. High permittivity thin film nanolaminates. J Appl. Phys. 87, 1921-1924 (2000).

Jeong, C.-W., Lee, J.-S. and Joo, S.-K. Plasma-assisted atomic layer growth of high-quality aluminum oxide thin films. Jpn. J. Appl. Phys. 40, 285 (2001).

Lukosius, M. et al. Electrical and Morphological Properties of ALD and AVD Grown Perovskite-Type Dielectrics and Their Stacks for Metal-Insulator-Metal Applications. ECS1 Solid State Sci. Technol. 1, N1-N5 (2012).

1. A capacitive component, comprising:
a plurality of films, the plurality of films comprising:
a first grained film component,
the first grained film component comprising at least one of SrTiO₃, BaTiO₃, and (Ba, Sr)TiO₃, and
the first grained film component optionally being characterized as being at least partially polymorphic crystalline in nature;
a second film component contacting the first grained film component,
the second film component optionally comprising Al₂O₃, and
the first grained film component optionally defining an average grain size of less than about 10 micrometers.

2. The capacitive component of claim 1, wherein the first grained film component defines a grain size in the range of from about 0.01 to about 9 micrometers.

3. The capacitive component of claim 1, wherein the first grained film component defines a thickness in the range of from about 1 to about 50 nm.

4. The capacitive component of claim 1, wherein the second film component defines a thickness in the range of from about 1 to about 50 nm.

5. The capacitive component of claim 1, wherein the first grained film component defines a thickness, the second film component defines a thickness, and wherein the ratio of the thickness of the first grained film component to the thickness of the second film component is from about 50:1 to about 1:5.

6. The capacitive component of claim 1, wherein the plurality of films is characterized as having a dielectric constant, at 0 V, of greater than about 40.

7. The capacitive component of claim 1, wherein the plurality of films is characterized as having a dielectric constant, at 0 V, of from about 40 to about 120.

8. The capacitive component of claim 1, wherein the plurality of films is characterized as having a leakage current, measured at 1 MV/cm and at 125 deg C., in the range of from about 1×10⁻⁷ A/mm² to about 1×10⁻⁸ A/mm².

9. The capacitive component of claim 1, wherein the plurality of films comprises a third film component.

10. The capacitive component of claim 9, wherein the third film component comprises Al₂O₃.

11. The capacitive component of claim 9, wherein the third film component defines a thickness in the range of from about 1 to about 20 nm.

12. The capacitive component of claim 1, wherein the plurality of films is disposed between a first electrode and a second electrode.

13. The capacitive component of claim 1, wherein the first grained film component comprises BiTiO₃, and wherein the molar ratio of Ba to Ti is from about 0.80 to about 1.06.

14. A capacitive component, comprising:
a plurality of films, the plurality of films optionally being disposed between a first electrode and a second electrode, and the plurality of films comprising:
a first grained film component,
the first grained film component being characterized as being at least partially crystalline polymorphic;
a second film component contacting the first grained film component,
the second film component optionally comprising Al₂O₃, and
the plurality of films being characterized as optionally having a dielectric constant, at 0 V, of from about 40 to about 140 and optionally having a leakage current, measured at 1 MV/cm and 125 deg. C., of from about 10⁻⁷ A/mm² to about 10⁻⁸ A/mm².

15. The capacitive component of claim 14, wherein the first grained film component defines a thickness, the second film component defines a thickness, and wherein the ratio of the thickness of the first grained film component to the thickness of the second film component is from about 50:1 to about 1:5.

16. The capacitive component of claim 14, wherein the first grained film component defines a grain size of less than about 10 micrometers.

17. An article, the article comprising a capacitive component according to claim 1.

18. A method, comprising discharging electrical energy from a capacitive component according to claim 1.

19. A method, comprising storing electrical energy in a capacitive component according to claim 1.

20. (canceled)

21. (canceled)

22. (canceled)

23. An article, the article comprising a capacitive component according to claim 14.

24. A method, comprising discharging electrical energy from a capacitive component according to claim 14.

25. A method, comprising storing electrical energy in a capacitive component according to claim 14.
